(19) United States
(12) Patent Application Publication
(10) Pub. No.: US 2026/0038411 A1
(43) Pub. Date: Feb. 5, 2026

(54) DISPLAY DEVICE AND ELECTRONIC DEVICE INCLUDING THE SAME

(71) Applicant: LG Display Co., Ltd., Seoul (KR)

(72) Inventor: Yeonggwang YU, Paju-si (KR)

(73) Assignee: LG Display Co., Ltd., Seoul (KR)

(21) Appl. No.: 19/286,064

(22) Filed: Jul. 30, 2025

(30) Foreign Application Priority Data
Aug. 2, 2024 (KR) 10-2024-0103080

(51) Int. Cl. G09G 3/20; G09G 3/32; H10H 29/49

(52) U.S. Cl. CPC G09G 3/2007; G09G 3/32; H10H 29/49; G09G 2300/0426; G09G 2300/0819; G09G 2300/0861; G09G 2310/08; G09G 2320/0233; G09G 2330/08; G09G 2354/00

(57) ABSTRACT

A display device and an electronic device including the same are discussed. The display device can include a first light emitting device arranged in a display area and configured to emit a first color light, a second light emitting device arranged in the display area and configured to emit a second color light, a third light emitting device arranged in the display area and configured to emit a third color light, and a first driver configured to drive the first light emitting device, the second light emitting device, and the third light emitting device. The first driver can receive two or more input reset voltages for resetting each of a first electrode of the first light emitting device, a first electrode of the second light emitting device, and a first electrode of the third light emitting device. The two or more input reset voltages can have different voltage values.

### CROSS-REFERENCE TO RELATED APPLICATION

This application claims priority to Korean Patent Application No. 10-2024-0103080, filed in the Republic of Korea on Aug. 2, 2024, which is hereby expressly incorporated by reference for all purposes as if fully set forth herein into the present application.

### BACKGROUND

### Field

Embodiments of the present disclosure relate to a display device.

### Discussion of the Related Art

A display device is applied to various electronic devices such as televisions, mobile phones, laptops, and tablets. Display devices include organic light emitting displays (OLEDs) that emit light on their own, and liquid crystal displays (LCDs) that require a separate light source.

Recently, display devices with light emitting diodes (LED) are attracting attention as next-generation display devices. Since light emitting diodes are made of inorganic materials rather than organic materials, a display device with the light emitting diode has a characteristics of a faster lighting speed, superior light emitting efficiency, and can display high-luminance images compared to a liquid crystal display or an organic light emitting display.

### SUMMARY OF THE DISCLOSURE

A display device according to embodiments of the present disclosure can include a first light emitting device arranged in a display area and emitting a first color light, a second light emitting device arranged in the display area and emitting a second color light, a third light emitting device arranged in the display area and emitting a third color light, and a first driver configured to drive the first light emitting device, the second light emitting device, and the third light emitting device.

According to aspects of the present disclosure, the first driver can receive two or more input reset voltages for resetting each of a first electrode of the first light emitting device, a first electrode of the second light emitting device, and a first electrode of the third light emitting device. The two or more input reset voltages can have different voltage values.

A display device according to embodiments of the present disclosure can include a first light emitting device emitting a first color light, a second light emitting device emitting a second color light, a third light emitting device emitting a third color light, a first column line electrically connected to a first electrode of the first light emitting device, a second column line electrically connected to a first electrode of the second light emitting device, a third column line electrically connected to a first electrode of the third light emitting device, and a first row line electrically connected in common with a second electrode of the first light emitting device, a second electrode of the second light emitting device, and a second electrode of the third light emitting device.

According to aspects of the present disclosure, a first reset voltage can be applied to the first column line after the first light emitting device emits light. A second reset voltage can be applied to the second column line after the second light emitting device emits light. A third reset voltage can be applied to the third column line after the third light emitting device emits light. At least two of the first reset voltage, the second reset voltage, and the third reset voltage can be different from each other.

According to embodiments of the present disclosure, it is possible to provide a display device having a wiring structure arranged in a matrix form to effectively drive a plurality of light emitting devices.

According to embodiments of the present disclosure, it is possible to provide a display device capable of effectively driving a plurality of light emitting devices by using a plurality of column lines connecting first electrodes of two or more light emitting devices arranged in a column direction and a plurality of row lines connecting second electrodes of two or more light emitting devices arranged in a row direction.

According to embodiments of the present disclosure, it is possible to provide a display device that controls a reset voltage for resetting the voltage state of a first electrodes of light emitting devices emitting light of different colors to match the light emitting devices emitting light of different colors.

According to embodiments of the present disclosure, it is possible to provide a display device capable of enhancing image quality by improving a luminance ratio of light emitting devices emitting different color light in a balanced manner.

According to embodiments of the present disclosure, it is possible to provide a display device capable of reducing the number of driving components (e.g. drivers) connected to the outside of a display panel, thereby reducing the number of assembly processes in the manufacturing process and providing a structure capable of process optimization.

An electronic device according to embodiments of the present disclosure can include the display device according to embodiments of the present disclosure described above.

The effects of the embodiments of the present disclosure are not limited to the effects mentioned above, and other effects not mentioned will be clearly understood by those skilled in the art from the description below.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 illustrates a display device according to embodiments of the present disclosure.

FIG. 2 is a plan view of a display device according to embodiments of the present disclosure.

FIG. 3 is a plan view of a display panel according to embodiments of the present disclosure.

FIG. 4 is a plan view of a unit driving area of a display panel according to embodiments of the present disclosure.

FIG. 5 illustrates a subpixel of a display panel according to embodiments of the present disclosure.

FIG. 6 is an equivalent circuit diagram of a unit driving area of a display panel according to embodiments of the present disclosure.

FIG. 7 illustrates a driving timing diagram for n row lines and one column line included in a first sub-driving area of a display panel according to embodiments of the present disclosure.

FIG. 8 and FIG. 9 illustrate circuits for driving n light emitting devices connected to one column line included in a first sub-driving area of a display panel according to embodiments of the present disclosure.

FIG. 10 is a plan view of a display panel according to embodiments of the present disclosure.

FIG. 11 illustrates a unit driving area of a display panel according to embodiments of the present disclosure.

FIG. 12 and FIG. 13 are plan views of a portion of a display panel according to embodiments of the present disclosure.

FIG. 14 is a cross-sectional view of a display panel according to embodiments of the present disclosure.

FIG. 15 is a detailed cross-sectional view of a display panel according to embodiments of the present disclosure, taken along the A-B cutting line of FIG. 10.

FIG. 16 is an enlarged cross-sectional view of a first subpixel of a display panel according to embodiments of the present disclosure.

FIG. 17 briefly illustrates a touch sensing structure of a display device according to embodiments of the present disclosure.

FIG. 18 illustrates a touch sensing system of a display device according to embodiments of the present disclosure.

FIG. 19 illustrates a touch driving structure of a display panel according to embodiments of the present disclosure.

FIG. 20 is a plan view of a touch pixel area of a display panel according to embodiments of the present disclosure.

FIG. 21 illustrates a driving situation for one touch pixel area during a display driving period of a display device according to embodiments of the present disclosure.

FIG. 22 illustrates a driving situation for one touch pixel area during a touch driving period of a display device according to embodiments of the present disclosure.

FIG. 23 and FIG. 24 are driving timing diagrams of a display device according to embodiments of the present disclosure.

FIG. 25 is a display driving timing diagram for three subpixels of a display device according to embodiments of the present disclosure.

FIG. 26 is a driving timing diagram for a row line and a column line during a display driving period of a display device according to embodiments of the present disclosure.

FIG. 27 illustrates a unit driving area of a display device according to embodiments of the present disclosure and a first light emitting device column within the unit driving area.

FIG. 28 illustrates an arrangement of light emitting device and emission areas within a first sub-driving area included in a unit driving area of a display device according to embodiments of the present disclosure.

FIG. 29 is a plan view of a part of a unit driving area of a display device according to embodiments of the present disclosure.

FIG. 30 illustrates a common reset circuit structure of a display device according to embodiments of the present disclosure.

FIGS. 31 and 32 illustrate a dual reset circuit structure of a display device according to embodiments of the present disclosure and the corresponding reset voltages.

FIGS. 33 and 34 illustrate individual reset circuit structures of a display device according to embodiments of the present disclosure and the corresponding reset voltages.

FIGS. 35A, 35B, 35C and 35D illustrate graphs related to setting of optimal values of first to third reset voltages corresponding to first to third light emitting devices, respectively, in a display device according to embodiments of the present disclosure.

FIGS. 36 to 39 illustrate various devices with a display device according to embodiments of the present disclosure.

### DETAILED DESCRIPTION OF THE EMBODIMENTS

The advantages and features of the present disclosure and the method for achieving them will become clear with reference to the embodiments described in detail below together with the accompanying drawings. However, the present disclosure is not limited to the embodiments disclosed below, but can be implemented in various different forms, and these embodiments are provided only to make the disclosure of the present disclosure complete and to fully inform a person having ordinary skill in the art to which the present specification belongs of the scope of the invention.

The shapes, sizes, ratios, angles, numbers, etc. disclosed in the drawings for explaining the embodiments of this specification are examples, and therefore this specification is not limited to the matters illustrated. In assigning reference numerals to components of each drawing, the same components can be assigned the same numerals even when they are shown on different drawings. When determined to make the subject matter of the disclosure unclear, the detail of the known art or functions can be skipped. As used herein, when a component “includes,” “has,” or “is composed of” another component, other components can be added unless “only” is used. When a component is expressed in the singular, it includes cases where the plural is included unless otherwise explicitly stated.

In interpreting a component, even if there is no separate explicit description of the error range, it is interpreted as including the error range.

In the case of a description of a positional relationship, for example, if the positional relationship between two parts is described as “on,” “over,” “below,” “next to,” or “adjacent,” one or more other parts can be located between the two parts unless “directly,” “immediately,” or “nearly,” are used.

In describing a temporal relationship, if the temporal continuity is described as “after,” “following,” “next to,” or “before,”, it can also include cases where it is not continuous, unless “right away,” or “directly,” is used.

Although the terms first, second, etc. are used to describe various elements, these components are not limited by these terms. These terms are only used to distinguish one component from another. Therefore, the first element mentioned below can also be the second element within the technical scope of this specification.

In describing the components of this specification, terms such as first, second, A, B, (a), or (b) can be used. These terms are only intended to distinguish the components from other components, and the nature, order, sequence, or number of the components are not limited by the terms.

If a component is described as being “connected,” “coupled,” “linked,” or “attached,” to another component, it should be understood that the component can be directly connected, coupled, linked, or attached to the other component, and alternatively, other components can be interposed between each component that can be indirectly connected, coupled, linked, or attached unless otherwise explicitly stated.

When a component or layer is described as being “contacted,” or “overlapping,” to another component or layer, it should be understood that the component or layer can directly contact or overlap the other component or layer, and alternatively, other components can be interposed between each component that can be indirectly contacted or overlapped unless otherwise explicitly stated.

“At least one” should be understood to include any combination of one or more of the associated components. For example, “at least one of the first, second, and third components” can be interpreted to include not only the first, second, or third components, but also any combination of two or more of the first, second, and third components.

Here, “first direction,” “second direction,” “third direction,” “X-axis direction,” “Y-axis direction,” and “Z-axis direction” should not be interpreted as merely geometric relationships in which the relationship between them is perpendicular to each other, but can mean a wider directionality within the range in which the configuration of the present specification can function functionally. Further, the term “can” fully encompasses all the meanings and coverages of the term “may” and vice versa.

Each feature of the various embodiments of the present specification can be partially or wholly combined or combined with each other, and can be technically associated or operated with respect to each other in various way, and each embodiment can be implemented independently of each other or can be implemented together in a related relationship.

Hereinafter, various embodiments of the disclosure are described in detail with reference to the accompanying drawings. All the components of each display device or apparatus according to all embodiments of the present disclosure are operatively coupled and configured.

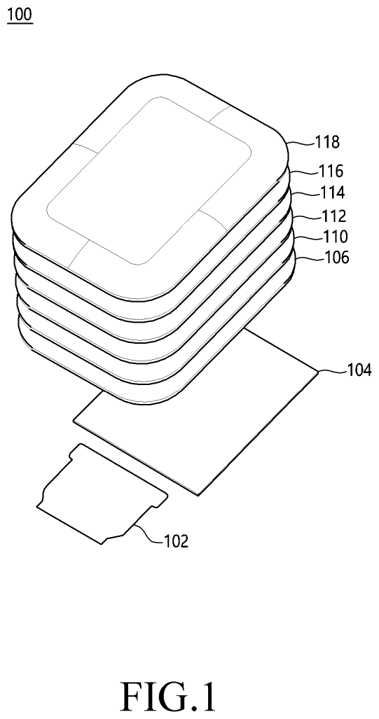

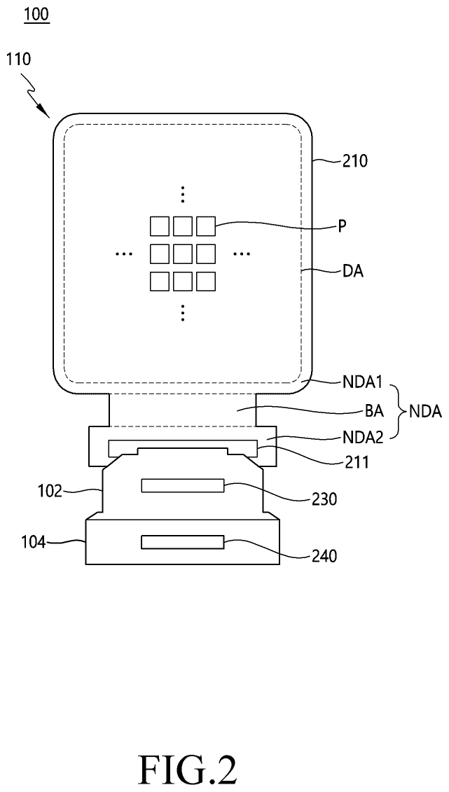

FIG. 1 illustrates a display device 100 according to embodiments of the present disclosure, and FIG. 2 is a plan view of a display device 100 according to embodiments of the present disclosure.

Referring to FIG. 1, a display device 100 according to the embodiments of the present disclosure can include a display panel 110, a cover member 118 disposed on the display panel 110, a flexible printed circuit 102 connected to the display panel 110, and a printed circuit board 104 connected to the flexible printed circuit 102.

The display device 100 according to the embodiments of the present disclosure can further include a support substrate 106 disposed under the display panel 110 and supporting the lower portion of the display panel 110, a polarizing layer 114 disposed on the display panel 110, a first adhesive layer 112 disposed between the display panel 110 and the polarizing layer 114, and a second adhesive layer 116 disposed between the polarizing layer 114 and the cover member 118.

The display panel 110 can include a substrate 210. The substrate 210 can be a member on which various components such as a plurality of metal layers and a plurality of insulating material layers are formed. The substrate 210 can be made of an insulating material. For example, the substrate 210 can be made of glass or resin. In addition, the substrate 210 can be made of a flexible material. For example, the substrate 210 can be made of a flexible plastic material such as polyimide (PI). However, the embodiments of the present disclosure are not limited thereto.

The display panel 110 can display information, images, and/or videos provided to a user. For example, the display panel 110 can include a display area DA and a non-display area NDA. For example, the substrate 210 can include a display area DA and a non-display area NDA. The display area DA and the non-display area NDA are not limited to the substrate 210, but can be described throughout the entire display device 100.

The display area DA can be an area where an image is displayed. The display area DA can include a plurality of pixels P. Each of the plurality of pixels P can be composed of a plurality of subpixels. At least one light emitting device can be arranged in each of the plurality of subpixels. The light emitting device can be configured differently depending on the type of the display device 100. For example, if the display device 100 is an inorganic light emitting display device, the light emitting device can be an inorganic-based light emitting device, such as a light emitting diode (LED), a micro LED, or a mini LED, but the embodiments of the present disclosure are not limited thereto.

The non-display area NDA can be an area where an image is not displayed. In the non-display area NDA, various wirings, and circuits for driving a plurality of pixels P of the display area DA can be arranged. For example, various driving circuits and various wirings can be arranged in the non-display area NDA, and a pad section 211 to which an integrated circuit and a printed circuit are connected can be arranged, but the embodiments of the present disclosure are not limited thereto.

For example, the driving circuit can include a data driving circuit and/or a gate driving circuit, but the embodiments of the present disclosure are not limited thereto. Wires or lines supplied with a control signal for controlling the driving circuit can be arranged on the substrate 210. For example, the control signal can include various timing signals including a clock signal, an input data enable signal, and synchronization signals, but the embodiments of the present disclosure are not limited thereto. The control signal can be supplied to the substrate 210 from the outside of the substrate 210 through the pad section 211. For example, circuit components such as a flexible printed circuit 102 and a printed circuit board 104 can be connected to the pad section 211.

According to the present embodiments, the non-display area NDA can include a first non-display area NDA1, a bending area BA, and a second non-display area NDA2. For example, the first non-display area NDA1 can be an area surrounding at least a portion of the display area DA. The bending area BA can be an area extending from at least one of a plurality of sides of the first non-display area NDA1 and can be a bendable area. The second non-display area NDA2 can be an area extending from the bending area BA and can include a pad section 211. For example, the bending area BA can be in a bent state, and the remaining area of the substrate 210 excluding the bending area BA can be in a flat state. In this case, as the bending area BA is bent, the second non-display area NDA2 can be located on the back surface of the display area DA. However, the embodiments of the present disclosure are not limited thereto.

The display area DA of the substrate 210 or the display device 100 can be configured in various shapes according to the design of the display device 100. For example, the display area DA can be configured in a rectangular shape with four corners formed in a round shape, but the embodiments of the present disclosure are not limited thereto. For another example, the display area DA can be configured in a rectangular shape with four corners formed in a right angle shape, a circular shape, but the embodiments of the present disclosure are not limited thereto.

According to the embodiments of the present disclosure, a width of the second non-display area NDA2 where the pad section 211 is arranged can be wider than a width of the bending area BA. In addition, a width of the display area DA can be wider than the width of the bending area BA. In the drawing, the width of the bending area BA is depicted as being narrower than the width of other areas of the substrate 210, but the shape of the substrate 210 including the bending area BA is for example, and the embodiments of the present disclosure are not limited thereto.

Referring to FIG. 1 and FIG. 2, a flexible printed circuit 102 and a printed circuit board 104 can be disposed at a lower portion of the display panel 110. The flexible printed circuit 102 and the printed circuit board 104 can be arranged at one edge of the display panel 110, but the embodiments of the present disclosure are not limited thereto. One side of the flexible printed circuit 102 can be connected to the display panel 110, and the other side can be connected to the printed circuit board 104, but the embodiments of the present disclosure are not limited thereto. The flexible printed circuit 102 can be a flexible film, but the embodiments of the present disclosure are not limited thereto.

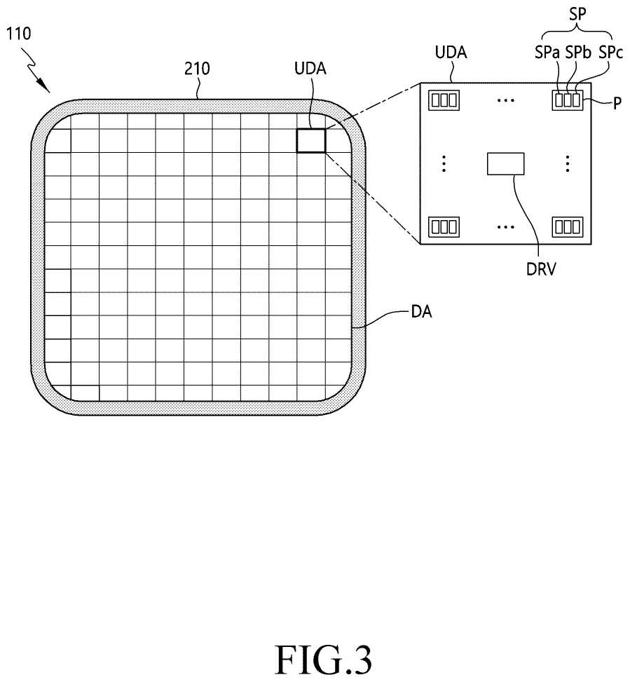

The pad section 211 disposed in the second non-display area NDA2 includes a plurality of pads, and a driving component including one or more flexible printed circuits 102 and a printed circuit board 104 can be attached or bonded. The plurality of pads included in the pad section 211 are electrically connected to one or more flexible printed circuits 102, and can transmit various signals (or power) from the printed circuit board 104 and one or more flexible printed circuits 102 to a driving circuit (for example, a driver DRV of FIG. 3) arranged in the display area DA.

The flexible printed circuit 102 can be a film in which various components are arranged on a flexible base film. For example, a first circuit component 230, such as a gate drive integrated circuit and/or a data drive integrated circuit, can be arranged on one or more flexible printed circuits 102, but the embodiments of the present disclosure are not limited thereto. The first circuit component 230 can be a component that processes data and a driving signal for displaying an image. The first circuit component 230 can be arranged in a manner such as a chip-on-glass (COG), a chip-on-film (COF), or a tape carrier package (TCP) depending on the mounting method, but the embodiments of the present disclosure are not limited thereto. The flexible printed circuit 102 can be attached or bonded to a plurality of pads through a conductive adhesive layer, but the embodiments of the present disclosure are not limited thereto.

The printed circuit board 104 can be a component that is electrically connected to the flexible printed circuit 102 and supplies a signal to the first circuit component 230. The printed circuit board 104 can be arranged on one side of the flexible printed circuit 102 and can be electrically connected to the flexible printed circuit 102. Various components for supplying various signals to the first circuit component 230 can be arranged on the printed circuit board 104. For example, second circuit components 240, which can have various implementations, such as a timing controller, a power supply, a memory, or a processor, can be arranged on the printed circuit board 104. For example, the second circuit components 240 arranged on the printed circuit board 104 can include a timing controller and/or a power management integrated circuit (PMIC), but the embodiments of the present disclosure are not limited thereto.

The printed circuit board 104 can include at least one hole, but the embodiments of the present disclosure are not limited thereto. An internal component detecting ambient light or temperature, such as a plurality of sensors, can be arranged in an area corresponding to at least one hole. For example, the internal component can include an ambient light sensor (ALS) or a temperature sensor, but the embodiments of the present disclosure are not limited thereto. For example, the hole can be a transmission hole, but the embodiments of the present disclosure are not limited thereto.

Referring to FIG. 1, a polarizing layer 114 can be arranged on a display panel 110 and can prevent or reduce light generated from an external light source from entering the display panel 110 and affecting a light emitting device.

A cover member 118 can be arranged on a polarizing layer 114 and can be a member for protecting the display panel 110.

A second adhesive layer 116 can be disposed between the polarizing layer 114 and the cover member 118. The second adhesive layer 116 can attach the cover member 118 to the display panel 110 or the polarizing layer 114.

A first adhesive layer 112 can be disposed between the display panel 110 and the polarizing layer 114. The first adhesive layer 112 can attach the polarizing layer 114 to the display panel 110. The first adhesive layer 112 can be omitted.

Each of the first adhesive layer 112 and the second adhesive layer 116 can include an optically clear adhesive (OCA), an optically clear resin (OCR), or a pressure sensitive adhesive (PSA), but the embodiments of the present disclosure are not limited thereto.

The support substrate 106 is disposed between the display panel 110 and the printed circuit board 104 to reinforce the rigidity of the display panel 110. The support substrate 106 can be a back plate, but the embodiments of the present disclosure are not limited thereto.

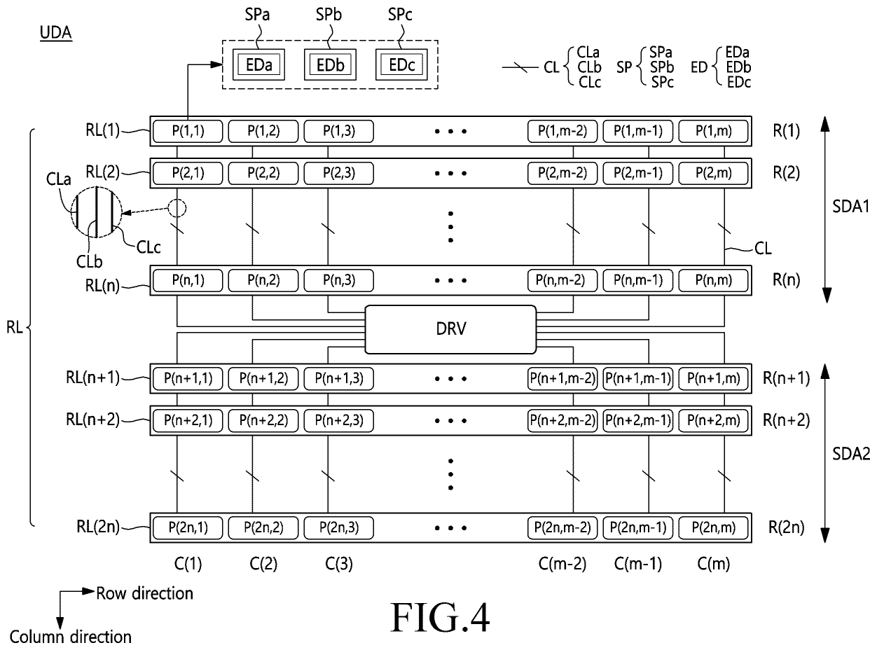

FIG. 3 is a plan view of a display panel 110 according to embodiments of the present disclosure, and FIG. 4 is a plan view of a unit driving area UDA of a display panel 110 according to embodiments of the present disclosure.

Referring to FIG. 3, the display area DA of the display panel 110 according to the embodiments of the present disclosure can include a plurality of unit driving areas UDA.

The display panel 110 according to the embodiments of the present disclosure can include a driver DRV arranged in each of the plurality of unit driving areas UDA. For example, the driver DRV can be a driving chip manufactured using a MOSFET (Metal-oxide-silicon field effect transistor) manufacturing process on a semiconductor substrate, but the embodiments of the present disclosure are not limited thereto.

Each of the plurality of unit driving areas UDA can be a driving area driven by one driver DRV. For example, the plurality of unit driving areas UDA can be independent driving areas driven by different drivers DRV.

The display panel 110 according to the embodiments of the present disclosure can include a substrate 210 including a display area DA, and a plurality of pixels P arranged in a matrix form in the display area DA.

A plurality of pixels P can be arranged in each of the plurality of unit driving areas UDA. Each of the plurality of pixels P can include a plurality of subpixels SP. Each of the plurality of subpixels SP can include at least one light emitting device.

For example, the plurality of subpixels SP can include a first subpixel SPa, a second subpixel SPb, and a third subpixel SPc, but is not limited thereto. The first subpixel SPa can include a first light emitting device that emits a first color light, the second subpixel SPb can include a second light emitting device that emits a second color light, and the third subpixel SPc can include a third light emitting device that emits a third color light. For example, the first color light, the second color light, and the third color light can be red light, green light, and blue light, respectively, but are not limited thereto.

Referring to FIG. 4, the display panel 110 according to the embodiments of the present disclosure can include a plurality of light emitting devices ED. Each of the plurality of subpixels SP can include a light emitting device ED.

For example, the first subpixel SPa can include a first light emitting device EDa, the second subpixel SPb can include a second light emitting device EDb, and the third subpixel SPc can include a third light emitting device EDc.

The display panel 110 according to the embodiments of the present disclosure can include a plurality of row lines RL and a plurality of column lines CL.

Each of the plurality of row lines RL can be arranged to extend in a row direction. The plurality of row lines RL can be electrically connected to a first electrode of each of a plurality of light emitting devices ED.

Each of the plurality of column lines CL can be arranged to extend in a column direction. The plurality of column lines CL can be electrically connected to a second electrode of each of the plurality of light emitting device ED.

For example, the first electrode of each of the plurality of light emitting device ED can be an anode electrode, and the second electrode of each of the plurality of light emitting device ED can be a cathode electrode. For another example, the first electrode of each of the plurality of light emitting device ED can be a cathode electrode, and the second electrode of each of the plurality of light emitting device ED can be an anode electrode.

Each of the plurality of row lines RL can be electrically connected to the second electrode of each of the plurality of light emitting device ED. For example, the second electrodes of each of the plurality of light emitting device ED can be commonly connected to one row line RL.

Each of the plurality of column lines CL can be electrically connected to the first electrode of each of the plurality of light emitting device ED. For example, the first electrode of each of the plurality of light emitting device ED can be commonly connected to one column line CL.

The line width of each of the plurality of row lines RL can be greater than the line width of each of the plurality of column lines CL.

The display panel 110 according to the embodiments of the present disclosure can include a plurality of drivers DRV. The plurality of drivers DRV can drive the plurality of light emitting device ED, the plurality of column lines CL, and the plurality of row lines RL.

The plurality of drivers DRV can be built into the display panel 110. The plurality of drivers DRV can be arranged in the display area DA, and can be arranged on the substrate 210. The plurality of drivers DRV can be arranged to correspond to a plurality of unit driving areas UDA. For example, one driver DRV can be arranged in one unit driving area UDA.

Each of the plurality of drivers DRV can drive a plurality of row lines RL and a plurality of column lines CL arranged in a corresponding unit driving area UDA among the plurality of unit driving areas UDA, thereby causing a plurality of light emitting device ED arranged in the corresponding unit driving area UDA to emit light.

The plurality of drivers DRV are disposed in the display area DA, and can be positioned closer to the substrate 210 than the plurality of light emitting device ED.

For example, the plurality of row lines RL can be driven sequentially. For another example, the plurality of row lines RL can be driven simultaneously. For another example, two or more row lines RL among the plurality of row lines RL can be driven simultaneously.

For example, during a specific display driving period, among the plurality of row lines RL arranged in the unit driving area UDA, at least one row line RL can be driven, and the remaining row lines RL may not be driven.

According to the embodiments of the present disclosure, a voltage applied to the row line RL can be referred to as a low-potential voltage, and the low-potential voltage can also be referred to as a row line voltage or a cathode voltage. The low-potential voltage can have various voltage values depending on the driving type or driving state. For example, the low-potential voltage can include a first low-potential voltage, a second low-potential voltage, and a third low-potential voltage.

Driving the row line RL can mean that the first low-potential voltage is supplied to the row line RL. Not driving the row line RL can mean that the second low-potential voltage higher than the first low-potential voltage is supplied to the row line RL. Accordingly, the light emitting device ED overlapping with the driven row line RL can emit light, and the light emitting device ED overlapping with the non-driven row line RL may not emit light.

For example, any first row line RL among the plurality of row lines RL can be supplied with a first low-potential voltage during a first period, and can be supplied with a second low-potential voltage higher than the first low-potential voltage during a second period different from the first period. Accordingly, the light emitting devices ED overlapping with the first row line RL can emit light during the first period, and may not emit light during the second period different from the first period. For example, the first period and the second period can be included in one display driving period. For another example, the first period and the second period can be included in different display driving periods.

The structure of one unit driving area UDA will be described in more detail with reference to FIG. 4.

As an example, one unit driving area UDA can be divided into a first sub-driving area SDA1 and a second sub-driving area SDA2. As another example, one unit driving area UDA can be divided into three or more sub-driving areas. As another example, one unit driving area UDA may not be divided into two or more sub-driving areas.

One unit driving area UDA can include one driver DRV and (2n×m) pixels P(1, 1), . . . , P(1, m), P(2, 1), . . . , P(2, m), . . . , P(2n, 1), . . . , P(2n, m) driven by one driver DRV.

In the embodiments of the present disclosure, n can be a sequence number of a row, or the number of rows in each of the first sub-driving area SDA1 and the second sub-driving area SDA2, or the number of row lines RL in each of the first sub-driving area SDA1 and the second sub-driving area SDA2, or the number of pixel rows in each of the first sub-driving area SDA1 and the second sub-driving area SDA2. m can be a sequence number of a column, or the number of columns in each of the first sub-driving area SDA1 and the second sub-driving area SDA2, or the number of column lines CL in each of the first sub-driving area SDA1 and the second sub-driving area SDA2, or the number of pixel columns in each of the first sub-driving area SDA1 and the second sub-driving area SDA2.

In the embodiments of the present disclosure, n can be a natural number greater than or equal to 1, and m can be a natural number greater than or equal to 1.

Here, (2n×m) pixels P(1, 1), . . . , P(1, m), P(2, 1), . . . , P(2, m), . . . , P(2n, 1), . . . , P(2n, m) can be arranged in 2n rows R(1), . . . , R(2n) and m columns C(1), . . . , C(m).

Among (2n×m) pixels P(1, 1), . . . , P(1, m), P(2, 1), . . . , P(2, m), . . . , P(2n, 1), . . . , P(2n, m), (n×m) pixels P(1, 1), . . . , P(1, m), P(2, 1), . . . , P(2, m), . . . , P(n, 1), . . . , P(n, m) arranged in the first to n-th rows R(1), . . . , R(n) can be arranged in the first sub-driving area SDA1.

Among (2n×m) pixels P(1, 1), . . . , P(1, m), P(2, 1), . . . , P(2, m), . . . , P(2n, 1), . . . , P(2n, m), (n×m) pixels P(n+1, 1), . . . , P(n+1, m), P(n+2, 1), . . . , P(n+2, m), . . . , P(2n, 1), . . . , P(2n, m) arranged in the (n+1)-th to the 2n-th row R(n+1), . . . , R(2n) can be arranged in the second sub-driving area SDA2.

One unit driving area UDA can include 2n row lines RL(1), . . . , RL(2n) to drive (2n×m) pixels P(1, 1), . . . , P(1, m), P(2, 1), . . . , P(2, m), . . . , P(2n, 1), . . . , P(2n, m).

Among the 2n row lines RL(1), . . . , RL(2n), the first to n-th row lines R(1), . . . , RL(n) can be arranged in the first sub-driving area SDA1. Among the 2n row lines RL(1), . . . , RL(2n), the (n+1)-th to the 2n-th row lines R(n+1), . . . , R(2n) can be arranged in the second sub-driving area SDA2.

Each of the 2n row lines RL(1), . . . , RL(2n) can overlap with m pixels. For example, the first row line RL(1) can overlap with m pixels P(1, 1), . . . . P(1, m) arranged in the first row R(1). The n-th row line RL(n) can overlap with m pixels P(n, 1), . . . . P(n, m) arranged in the n-th row (R(n)). The (n+1)-th row line RL(n+1) can overlap with the m pixels P(n+1, 1), . . . . P(n+1, m) arranged in the (n+1)-th row R(n+1). The 2n-th row line RL(2n) can overlap with the m pixels P(2n, 1), . . . . P(2n, m) arranged in the 2nth row R(2n).

For example, the first row line RL(1) can be connected to the k subpixels SPa, SPb and SPc included in each of the m pixels P(1, 1), . . . . P(1, m) arranged in the first row R(1). More specifically, the first row line RL(1) can be connected to the second electrodes of the k light emitting devices EDa, EDb and EDc included in each of the m pixels P(1, 1), . . . . P(1, m) arranged in the first row R(1).

For example, the n-th row line RL(n) can be connected to the k subpixels SPa, SPb and SPc included in each of the m pixels P(n, 1), . . . . P(n, m) arranged in the n-th row R(n). More specifically, the n-th row line RL(n) can be connected to the second electrodes of the k light emitting devices EDa, EDb and EDc included in each of the m pixels P(n, 1), . . . . P(n, m) arranged in the n-th row R(n).

For example, the (n+1)-th row line RL(n+1) can be connected to k subpixels SPa, SPb and SPc included in each of m pixels P(n+1, 1), . . . . P(n+1, m) arranged in the (n+1)-th row R(n+1). More specifically, the (n+1)-th row line RL(n+1) can be connected to the second electrodes of k light emitting devices EDa, EDb and EDc included in each of m pixels P(n+1, 1), . . . . P(n+1, m) arranged in the (n+1)-th row R(n+1).

For example, the 2n-th row line RL(2n) can be connected to k subpixels SPa, SPb and SPc included in each of m pixels P(2n, 1), . . . . P(2n, m) arranged in the 2n-th row R(2n). More specifically, the 2n-th row line RL(2n) can be connected to the second electrodes of k light emitting devices EDa, EDb and EDc included in each of m pixels P(2n, 1), . . . . P(2n, m) arranged in the 2n-th row R(2n).

One unit driving area UDA can include (m×k×2) column lines CL to drive (2n×m) pixels P(1, 1), . . . , P(1, m), P(2, 1), . . . , P(2, m), . . . , P(2n, 1), . . . , P(2n, m). Here, k is the number of subpixels SP included in one pixel P. In the example of FIG. 4, k is 3. For example, one pixel P can include three subpixels SPa, SPb and SPc.

The first sub-driving area SDA1 can include (m×k) column lines CL to drive (n×m) pixels P(1, 1), . . . , P(1, m), . . . , P(n, 1), . . . , P(n, m) arranged in the first sub-driving area SDA1. In the example of FIG. 4, since k is 3, the first sub-driving area SDA1 can include 3m column lines CL.

In the first sub-driving area SDA1, k column lines CLa, CLb and CLc can be arranged in each of the m columns C(1), . . . , C(m). In the example of FIG. 4, since k is 3, in the first sub-driving area SDA1, each of the m columns C(1), . . . , C(m) can include three column lines CLa, CLb and CLc.

In each of the m columns C(1), . . . , C(m), each of the k column lines CL can be commonly connected to n pixels arranged in the corresponding column. In each of the m columns C(1), . . . , C(m), each of the k column lines CL can be commonly connected to first electrodes of n light emitting devices ED arranged in the corresponding column. In the example of FIG. 4, since k is 3, in each of the m columns C(1), . . . , C(m), three column lines CLa, CLb and CLc can be connected to the first electrodes of the 3n light emitting devices ED included in the n pixels arranged in the corresponding column. For example, in each of the m columns C(1), . . . , C(m), a first column line CLa can be commonly connected to the first electrodes of the n first light emitting devices EDa arranged in the corresponding column. In each of the m columns C(1), . . . , C(m), a second column line CLb can be commonly connected to the first electrodes of the n second light emitting devices EDb arranged in the corresponding column. In each of the m columns C(1), . . . , C(m), a third column line CLc can be commonly connected to the first electrodes of the n third light emitting devices EDc arranged in the corresponding column.

The second sub-driving area SDA2 can include (m×k) column lines CL to drive (n×m) pixels P(n+1, 1), . . . , P(n+1, m), . . . , P(2n, 1), . . . , P(2n, m) arranged in the second sub-driving area SDA2. In the example of FIG. 4, since k is 3, the second sub-driving area SDA2 can include 3m column lines CL.

In the second sub-driving area SDA2, k column lines CL can be arranged in each of the m columns C(1), . . . , C(m). In the example of FIG. 4, since k is 3, in the second sub-driving area SDA2, each of the m columns C(1), . . . , C(m) can include three column lines CLa, CLb and CLc.

In each of the m columns C(1), . . . , C(m), each of the k column lines CL can be commonly connected to n pixels arranged in the corresponding column. In each of the m columns C(1), . . . , C(m), each of the k column lines CL can be commonly connected to first electrodes of n light emitting devices ED arranged in the corresponding column. In the example of FIG. 4, since k is 3, in each of the m columns C(1), . . . , C(m), three column lines CLa, CLb and CLc can be connected to the first electrodes of the 3n light emitting devices ED included in the n pixels arranged in the corresponding column. For example, in each of the m columns C(1), . . . , C(m), a first column line CLa can be commonly connected to the first electrodes of the n first light emitting devices EDa arranged in the corresponding column. In each of the m columns C(1), . . . , C(m), the second column line CLb can be commonly connected to the first electrodes of the n second light emitting devices EDb arranged in the corresponding column. In each of the m columns C(1), . . . , C(m), the third column line CL3 can be commonly connected to the first electrodes of the n third light emitting devices EDc arranged in the corresponding column.

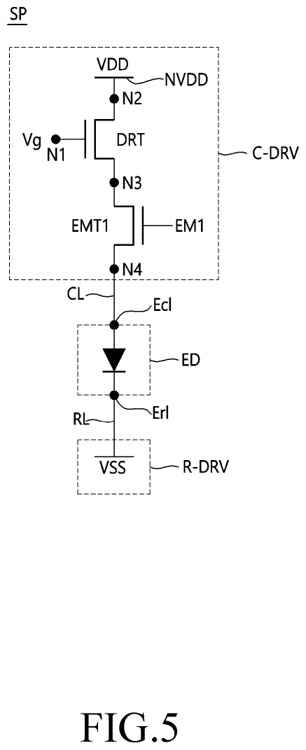

FIG. 5 illustrates a subpixel SP of a display panel 110 according to embodiments of the present disclosure.

Referring to FIG. 5, the subpixel SP according to embodiments of the present disclosure can include a light emitting device ED including a first electrode Ecl and a second electrode Erl, a column driver C-DRV for driving a column line CL electrically connected to the first electrode Ecl of the light emitting device ED, and a row driver R-DRV for driving a row line RL electrically connected to the second electrode Erl of the light emitting device ED.

The light emitting device ED can include a first electrode Ecl and a second electrode Erl. The first electrode Ecl can be electrically connected to a column line CL, and the second electrode Erl can be electrically connected to a row line RL. For example, the first electrode Ecl can be an anode electrode, and the second electrode Erl can be a cathode electrode. For another example, the first electrode Ecl can be a cathode electrode, and the second electrode Erl can be an anode electrode.

A column driver C-DRV included in a unit driving area UDA can be connected to a plurality of column lines CL included in the unit driving area UDA, and can drive a plurality of column lines CL included in the unit driving area UDA. Each of the plurality of column lines CL can be commonly connected to the first electrode Ecl of each of the plurality of light emitting devices ED included in the plurality of subpixels SP arranged in the corresponding column.

A row driver R-DRV included in a unit driving area UDA can be connected to a plurality of row lines RL included in the unit driving area UDA and can drive a plurality of row lines RL included in the unit driving area UDA. Each of the plurality of row lines RL can be commonly connected to a second electrode Erl of each of a plurality of light emitting devices ED included in a plurality of subpixels SP arranged in the corresponding row.

The column driver C-DRV can include main nodes including a first node N1, a second node N2, a third node N3, and a fourth node N4. The column driver C-DRV can include a driving transistor DRT and a first emission control transistor EMT1.

The first node N1 can be a node to which a voltage Vg for controlling the on-off of the driving transistor DRT is applied. The second node N2 can be a node electrically connected to a high-potential voltage node NVDD to which a high-potential voltage VDD is applied. The third node N3 can be a node to which the driving transistor DRT and the first emission control transistor EMT1 are connected. The fourth node N4 can be a node to which the first emission control transistor EMT1 and the light emitting device ED are electrically connected, and can be a node to which the column line CL is electrically connected. Here, a source electrode or a drain electrode of the first emission control transistor EMT1 and the first electrode Ecl of the light emitting device ED can be commonly connected to the column line CL.

The driving transistor DRT supplies a driving current to make the light emitting device ED emit light, is connected between the second node N2 and the third node N3, and can control the connection between the second node N2 and the third node N3 according to the voltage of the first node N1.

The gate electrode of the driving transistor DRT is electrically connected to the first node N1, and a gate voltage Vg can be applied thereto. The drain electrode or the source electrode of the driving transistor DRT can be electrically connected to the second node N2. The source electrode or the drain electrode of the driving transistor DRT can be electrically connected to the third node N3.

The first emission control transistor EMT1 can control a connection of a path through which the driving current flows, and can play a role in controlling an emission of the light emitting device ED.

If the driving transistor DRT and the first emission control transistor EMT1 are turned on between a high potential voltage VDD and a low potential voltage VSS, the driving current can be supplied to the light emitting device ED through the driving transistor DRT and the first emission control transistor EMT1. Accordingly, the light emitting device ED can emit light.

The first emission control transistor EMT1 is connected between the third node N3 and the fourth node N4, and can control the connection between the third node N3 and the fourth node N4 according to a first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or drain electrode of the first emission control transistor EMT1 can be electrically connected to the fourth node N4.

The first emission control signal EM1 can be a pulse width modulation signal that varies at a predefined time (for example, each frame, or each sub-frame included in one frame), but the embodiments of the present disclosure are not limited thereto.

The first emission control signal EM1 can be generated by the driver DRV, or can be supplied to the driver DRV from a driving-related circuit such as a timing controller.

The row driver R-DRV can drive at least one row line RL by supplying a low-potential voltage VSS to at least one row line RL.

The row driver R-DRV can perform display-on driving or display-off driving for one row line RL.

The row driver R-DRV can supply a low-potential voltage for display-on driving to one row line RL in order to perform display-on driving for one row line RL. The row driver R-DRV can supply a low-potential voltage for display-off driving to one row line RL in order to perform display-off driving for one row line RL.

A low-potential voltage for display-on driving and a low-potential voltage for display-off driving can be different. For example, the low-potential voltage for display-on driving can be lower than the low-potential voltage for display-off driving. In the embodiments of the present disclosure, the “low-potential voltage for display-on driving” is also referred to as the “first low-potential voltage,” and the “low-potential voltage for display-off driving” is also referred to as the “second low-potential voltage.”

The column driver C-DRV can further include at least one switching element and/or at least one transistor in addition to the driving transistor DRT and the first emission control transistor EMT1. Each of the transistors included in the column driver C-DRV can be an n-type transistor or a p-type transistor.

The column driver C-DRV can further include at least one capacitor.

The column driver C-DRV can further include at least one circuit element. For example, the at least one circuit element can include a power output buffer.

The row driver R-DRV can include at least one switching element and/or at least one transistor. Each of the transistors included in the row driver R-DRV can be an n-type transistor or a p-type transistor.

The row driver R-DRV can further include at least one circuit element. For example, at least one circuit element can include a power output buffer.

The column driver C-DRV and the row driver R-DRV can be internal circuits included in the driver DRV. As another example, the column driver C-DRV and the row driver R-DRV may not be included in the driver DRV and can be circuits formed on the substrate 210 of the display panel 110.

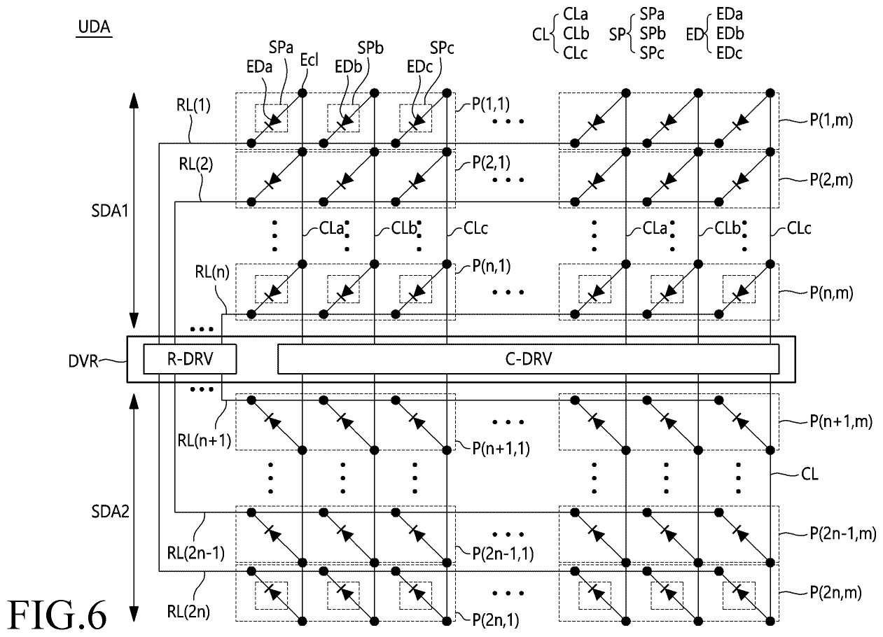

FIG. 6 is an equivalent circuit diagram of a unit driving area UDA of a display panel 110 according to embodiments of the present disclosure. In the following description, FIG. 4 and FIG. 5 are also referred to.

Referring to FIG. 6, each of the plurality of unit driving areas UDA can correspond to one driver DRV among the plurality of drivers DRV. For example, one driver DRV among the plurality of drivers DRV can be arranged in each of the plurality of unit driving areas UDAs.

Each of the plurality of unit driving areas UDAs can include two or more row lines RL(1) to RL(2n) among all row lines RL arranged in the display panel 110 and two or more column lines CL among all column lines CL arranged in the display panel 110.

Each of the plurality of unit driving areas UDAs can include a first sub-driving area SDA1 and a second sub-driving area SDA2. Some of the two or more row lines RL(1) to RL(2n) can be arranged in the first sub-driving area SDA1, and the rest can be arranged in the second sub-driving area SDA2. Some of the two or more column lines CL can be arranged in the first sub-driving area SDA1, and the rest can be arranged in the second sub-driving area SDA2.

Each of the plurality of unit driving areas UDAs can include a plurality of pixels P(1, 1), . . . , P(1, m), P(2, 1), . . . , P(2, m), . . . , P(2n, 1), . . . , P(2n, m) arranged in a matrix form.

Each of the plurality of pixels P(1, 1), . . . , P(1, m), P(2, 1), . . . , P(2, m), . . . , P(2n, 1), . . . , P(2n, m) can include k subpixels SPa, SPb and SPc. The k subpixels SPa, SPb and SPc can include k light emitting devices EDa, EDb and EDc.

Some of the plurality of pixels P(1, 1), . . . , P(1, m), P(2, 1), . . . , P(2, m), . . . , P(2n, 1), . . . , P(2n, m) can be arranged in the first sub-driving area SDA1, and the rest can be arranged in the second sub-driving area SDA2.

The k is the number of subpixels included in one pixel. In the example of FIG. 6, k is 3. For example, one pixel can include three subpixels SPa, SPb and SPc. Hereinafter, it will be described the structure of the unit driving area UDA is explained based on an example where K is 3.

The unit driving area UDA can include (2n×m) pixels P(1, 1), . . . , P(1, m), P(2, 1), . . . , P(2, m), . . . , P(2n, 1), . . . , P(2n, m). The (2n×m) pixels P(1, 1), . . . , P(1, m), P(2, 1), . . . , P(2, m), . . . , P(2n, 1), . . . , P(2n, m) can be arranged in 2n rows and m columns.

According to the example of FIG. 6, each of the (2n×m) pixels P(1, 1), . . . , P(1, m), P(2, 1), . . . , P(2, m), . . . , P(2n, 1), . . . , P(2n, m) can include three subpixels SPa, SPb and SPc.

According to the example of FIG. 6, three subpixels can include a first subpixel SPa including a first light emitting device EDa, a second subpixel SPb including a second light emitting device EDb, and a third subpixel SPc including a third light emitting device EDc.

Half of the (2n×m) pixels P(1, 1), . . . , P(1, m), P(2, 1), . . . , P(2, m), . . . , P(2n, 1), . . . , P(2n, m), which are (n×m) pixels P(1, 1), . . . , P(1, m), . . . , P(n, 1), . . . , P(n, m), can be arranged in the first sub-driving area SDA1.

Among the (2n×m) pixels P(1, 1), . . . , P(1, m), P(2, 1), . . . , P(2, m), . . . , P(2n, 1), . . . , P(2n, m), the remaining half (n×m) pixels P(n+1, 1), . . . , P(n+1, m), . . . , P(2n, 1), . . . , P(2n, m) can be arranged in the second sub-driving area SDA2.

According to the example of FIG. 6, the unit driving area UDA can include 2n row lines RL(1) to RL(2n) and (m×3×2) column lines CL.

Further, n row lines RL(1) to RL(n), which are half of 2n row lines RL(1) to RL(2n), can be arranged in the first sub-driving area SDA1, and n row lines RL(n+1) to RL(2n), which are the remaining half of 2n row lines RL(1) to RL(2n), can be arranged in the second sub-driving area SDA2.

The n row lines RL(1)˜RL(n) arranged in the first sub-driving area SDA1 can correspond to (n×m) pixels P(1, 1), . . . , P(1, m), . . . , P(n, 1), . . . , P(n, m) arranged in the first sub-driving area SDA1 by row (i.e., pixel row).

For example, among the n row lines RL(1) to RL(n) arranged in the first sub-driving area SDA1, the first row line RL(1) arranged in the first row (i.e., the first pixel row) can correspond to m pixels P(1, 1), . . . , P(1, m) included in the first pixel row. The first row line RL(1) can be electrically connected to the second electrode Erl of each of the 3m light emitting devices ED included in the first pixel row.

For another example, among the n row lines RL(1) to RL(n) arranged in the first sub-driving area SDA1, the second row line RL(2) arranged in the second row (i.e., the second pixel row) can correspond to m pixels P(2, 1), . . . , P(2, m) included in the second pixel row. The second row line RL(2) can be electrically connected to the second electrode Erl of each of the 3m light emitting devices ED included in the second pixel row.

For another example, among the n row lines RL(1) to RL(n) arranged in the first sub-driving area SDA1, the n-th row line RL(n) arranged in the n-th row (i.e., the n-th pixel row) can correspond to the m pixels P(n, 1), . . . , P(n, m) included in the n-th pixel row. The n-th row line RL(n) can be electrically connected to the second electrode Erl of each of the 3m light emitting devices ED included in the n-th pixel row.

The n rows RL(n+1) to RL(2n) arranged in the second sub-driving area SDA2 can correspond to the (n×m) pixels P(n+1, 1), . . . , P(n+1, m), . . . , P(2n, 1), . . . , P(2n, m) arranged in the second sub-driving area SDA2 by row (i.e., pixel row).

For example, among the n row lines RL(n+1) to RL(2n) arranged in the second sub-driving area SDA2, the (n+1)-th row line RL(n+1) arranged in the (n+1)-th row (i.e., the (n+1)-th pixel row) can correspond to the m pixels P(n+1, 1), . . . , P(n+1, m) included in the (n+1)-th pixel row. The (n+1)-th row line RL(n+1) can be electrically connected to the second electrode Erl of each of the 3m light emitting devices ED included in the (n+1)-th pixel row.

For another example, among the n row lines RL(n+1) to RL(2n) arranged in the second sub-driving area SDA2, the (2n−1)-th row line RL(2n−1) arranged in the (2n−1)-th row (i.e., he (2n−1)-th pixel row) can correspond to the m pixels P(2n−1, 1), . . . , P(2n−1, m) included in the (2n−1)-th pixel row. The (2n−1)-th row line RL(2n−1) can be electrically connected to the second electrode Erl of each of the 3m light emitting devices ED included in the (2n−1)-th pixel row.

For another example, among the n row lines RL(n+1) to RL(2n) arranged in the second sub-driving area SDA2, the 2n-th row line RL(2n) arranged in the 2n-th row (i.e., 2n-th pixel row) can correspond to the m pixels P(2n, 1), . . . , P(2n, m) included in the 2n-th pixel row. The 2n-th row line RL(2n) can be electrically connected to all of the second electrodes Erl of each of the 3m light emitting devices ED included in the 2n-th pixel row.

Further, 3m column lines CL, which are half of the (m×3×2) column lines CL, can be arranged in the first sub-driving area SDA1, and 3m column lines CL, which are the remaining half of the (m×3×2) column lines CL, can be arranged in the second sub-driving area SDA2.

Furthermore, 3m column lines CL arranged in the first sub-driving area SDA1 can correspond to (n×m) pixels P(1, 1), . . . , P(1, m), . . . , P(n, 1), . . . , P(n, m) arranged in the first sub-driving area SDA1 by column (i.e., pixel column).

For example, among the 3m column lines CL arranged in the first sub-driving area SDA1, three first column lines CLa, CLb and CLc arranged in a first column (i.e., the first pixel column) can correspond to n pixels P(1, 1), P(2, 1), . . . , P(n, 1) arranged in the first pixel column.

In the first sub-driving area SDA1, three first column lines CLa, CLb and CLc arranged in the first pixel column can be respectively connected to three subpixels SPa, SPb and SPc included in each of n pixels P(1, 1), P(2, 1), . . . , P(n, 1) arranged in the first pixel column.

In the first sub-driving area SDA1, three first column lines CLa, CLb and CLc arranged in the first pixel column can be respectively electrically connected to the first electrodes Ecl of three light emitting devices EDa, EDb and EDc included in each of n pixels P(1, 1), P(2, 1), . . . , P(n, 1) arranged in the first pixel column.

For example, among the 3m column lines CL arranged in the first sub-driving area SDA1, three m-th column lines CLa, CLb and CLc arranged in a m-th column (i.e., m-th pixel column) can correspond to n pixels P(1, m), P(2, m), . . . , P(n, m) arranged in the m-th pixel column.

In the first sub-driving area SDA1, three m-th column lines CLa, CLb and CLc arranged in the m-th pixel column can be respectively connected to three subpixels SPa, SPb and SPc included in each of n pixels P(1, m), P(2, m), . . . , P(n, m) arranged in the m-th pixel column.

In the first sub-driving area SDA1, three m-th column lines CLa, CLb and CLc arranged in the m-th pixel column can be respectively electrically connected to the first electrodes Ecl of three light emitting devices EDa, EDb and EDc included in each of n pixels P(1, m), P(2, m), . . . , P(n, m) arranged in the m-th pixel column.

Further, 3m column lines CL arranged in the second sub-driving area SDA2 can correspond to (n×m) pixels P(n+1, 1), . . . , P(n+1, m), . . . , P(2n, 1), . . . , P(2n, m) arranged in the second sub-driving area SDA2 by column (i.e., pixel column).

For example, among the 3m column lines CL arranged in the second sub-driving area SDA2, three first column lines CLa, CLb and CLc arranged in the first column (i.e., the first pixel column) can correspond to n pixels P(n+1, 1), . . . , P(2n−1, 1), P(2n, 1) arranged in the first pixel column.

In the second sub-driving area SDA2, three first column lines CLa, CLb and CLc arranged in the first pixel column can be respectively connected to three subpixels SPa, SPb and SPc included in each of n pixels P(n+1, 1), . . . , P(2n−1, 1), P(2n, 1) arranged in the first pixel column.

In the second sub-driving area SDA2, the three first column lines CLa, CLb and CLc arranged in the first pixel column can be respectively electrically connected to the first electrodes Ecl of the three light emitting devices EDa, EDb and EDc included in each of the n pixels P(n+1, 1), . . . , P(2n−1, 1), P(2n, 1) arranged in the first pixel column.

For example, among the 3m column lines CL arranged in the second sub-driving area SDA2, the three m-th column lines CLa, CLb and CLc arranged in the m-th column (i.e., the m-th pixel column) can correspond to the n pixels P(n+1, m), . . . , P(2n−1, m), P(2n, m) arranged in the m-th pixel column.

In the second sub-driving area SDA2, three m-th column lines CLa, CLb and CLc arranged in the m-th pixel column can be respectively connected to three subpixels SPa, SPb and SPc included in each of n pixels P(n+1, m), . . . , P(2n−1, m), P(2n, m) arranged in the m-th pixel column.

In the second sub-driving area SDA2, three m-th column lines CLa, CLb and CLc arranged in the m-th pixel column can be respectively electrically connected to the first electrodes Ecl of three light emitting devices EDa, EDb and EDc included in each of n pixels P(n+1, m), . . . , P(2n−1, m), P(2n, m) arranged in the m-th pixel column.

Two or more row lines RL(1) to RL(2n) arranged in the unit driving area UDA can be electrically connected to the row driver R-DRV included in the driver DRV of the unit driving area UDA. Two or more column lines CL arranged in the unit driving area UDA can be electrically connected to the column driver C-DRV included in the driver DRV of the unit driving area UDA.

The driver DRV can be arranged between the first sub-driving area SDA1 and the second sub-driving area SDA2.

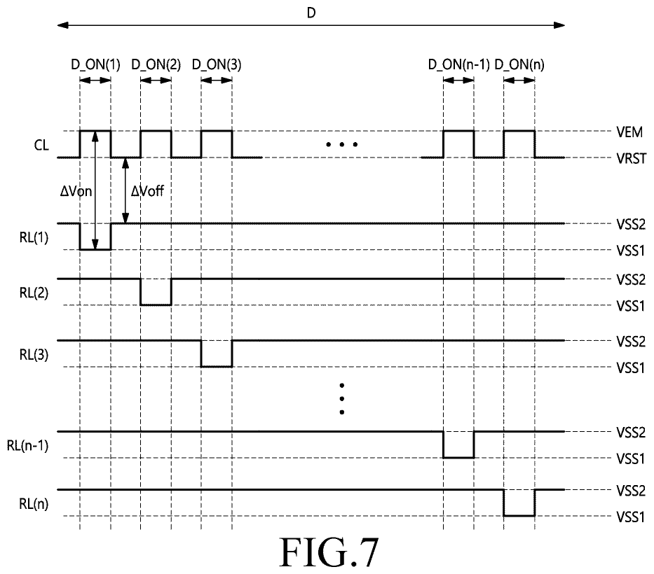

FIG. 7 illustrates a driving timing diagram for n row lines RL(1) to RL(n) and one column line CL included in a first sub-driving area SDA1 of a display panel 110 according to embodiments of the present disclosure. However, FIG. 6 is also referred to in the following description.

Referring to FIG. 7, the row driver R-DRV of the driver DRV can drive n row lines RL(1) to RL(n) arranged in the first sub-driving area SDA1.

The driving for each of the n row lines RL(1) to RL(n) arranged in the first sub-driving area SDA1 can include display-on driving for emitting light emitting devices ED arranged in each of the n row lines RL(1) to RL(n) and display-off driving for not emitting light emitting devices EDs arranged in each of the n row lines RL(1) to RL(n).

Hereinafter, it will be exemplified the driving sequence for each of the n row lines RL(1) to RL(n) arranged in the first sub-driving area SDA1.

For example, display-on driving for each of the plurality of row lines RL can be performed sequentially. As another example, display-on driving for each of the plurality of row lines RL can be performed simultaneously. As another example, display-on driving for each of two or more row lines RL among the plurality of row lines RL can be performed simultaneously. Hereinafter, for convenience of explanation, it will be described as an example a case in which display-on driving for each of the plurality of row lines RL is performed sequentially. However, it is not limited thereto.

The row driver R-DRV of the driver DRV can sequentially drive n row lines RL(1) to RL(n) arranged in the first sub-driving area SDA1. For example, display-on driving periods D_ON(1) to D_ON(n) for n row lines RL(1) to RL(n) arranged in the first sub-driving area SDA1 can be sequential.

Among the n row lines RL(1) to RL(n) arranged in the first sub-driving area SDA1, for any one row line RL, during the display driving period D, the display-on driving period for the corresponding row line RL can exist at least once. During the display driving period D, all remaining times except the display-on driving period for the corresponding row line RL can be display-off driving periods.

During any one display driving period D, among the n row lines RL(1) to RL(n) arranged in the unit driving area UDA, the display-on driving can be performed for at least one row line RL, and the display-on driving may not be performed for the remaining row lines RL, but the display-off driving can be performed.

For example, during any one display driving period D, among the n row lines RL(1) to RL(n) arranged in the unit driving area UDA, display-on driving can be performed for a first row line RL(1), and display-off driving can be performed for the second to n-th row lines RL(2) to RL(n).

For another example, during any one display driving period D, among the n row lines RL(1) to RL(n) arranged in the unit driving area UDA, display-on driving can be performed for the second row line RL(2), and display-on driving may not be performed for the first row line RL(1) and a third to n-th row lines RL(3) to RL(n).

For another example, during any one display driving period D, among the n row lines RL(1) to RL(n) arranged in the unit driving area UDA, display-on driving can be performed for the third row line RL(3), and display-off driving can be performed instead of display-on driving for the first and second row lines RL(1), RL(2) and the fourth to n-th row lines RL(4) to RL(n).

For another example, during any one display driving period D, among the n row lines RL(1) to RL(n) arranged in the unit driving area UDA, display-on driving can be performed for the (n−1)-th row line RL(n−1), and display-off driving can be performed instead of display-on driving for the first to (n−2)-th row lines RL(1) to RL(n−2) and the n-th row line RL(n).

For another example, during any one display driving period D, among the n row lines RL(1) to RL(n) arranged in the unit driving area UDA, display-on driving can be performed for the n-th row line RL(n), and display-off driving can be performed instead of display-on driving for the first to (n−1)-th row lines RL(1) to RL(n−1).

If display-on driving is performed for any row line RL among the n row lines RL(1) to RL(n) arranged in the unit driving area UDA, it can mean that a first low-potential voltage VSS1 of a predefined level is supplied to the corresponding row line RL. When display-on driving is performed for any row line RL, the light emitting devices ED arranged corresponding to the corresponding row line RL can emit light.

When display-off driving is performed for any row line RL among the n row lines RL(1) to RL(n) arranged in the unit driving area UDA without display-on driving, it can mean that a second low-potential voltage VSS2 of a predefined level is supplied to the corresponding row line RL. When display-off driving is performed for a specific row line RL, the light emitting devices ED arranged corresponding to the corresponding row line RL may not emit light.

The first low-potential voltage VSS1 can be a low-potential voltage VSS for display-on driving, and the second low-potential voltage VSS2 can be a low-potential voltage VSS for display-off driving. The second low-potential voltage VSS2 can be a voltage higher than the first low-potential voltage VSS1.

Any one row line RL among the n row lines RL(1) to RL(n) arranged in the unit driving area UDA can be supplied with the first low-potential voltage VSS1 during a first period, and can be supplied with the second low-potential voltage VSS2 higher than the first low-potential voltage VSS1 during a second period different from the first period. For example, the first period and the second period can be included in one display driving period D. For another example, the first period and the second period can be included in different display driving periods D.

For example, among the n row lines RL(1) to RL(n) arranged in the unit driving area UDA, the first row line RL(1) can be supplied with a first low-potential voltage VSS1 during a first display-on driving period D_ON(1), and can be supplied with a second low-potential voltage VSS2 higher than the first low-potential voltage VSS1 during a second display-on driving period D_ON(2) to D_ON(n) different from the first display-on driving period D_ON(1).

For example, during the first display-on driving period D_ON(1), the first row line RL(1) can be supplied with a first low-potential voltage VSS1, and the second to n-th row lines RL(2) to RL(n) can be supplied with a second low-potential voltage VSS2. During the second display-on driving period D_ON(2), the second row line RL(2) can be supplied with a first low-potential voltage VSS1, and the first row line RL(1) and the third to n-th row lines RL(3) to RL(n) can be supplied with a second low-potential voltage VSS2.

For example, during the first display-on driving period D_ON(1), a plurality of light emitting devices ED overlapping with the first row line RL(1) and arranged in the first row can emit light, and a plurality of light emitting devices ED overlapping with the second to n-th row lines RL(2) to RL(n) and arranged in the second to n-th rows may not emit light. During the second display-on driving period D_ON(2), a plurality of light emitting devices ED overlapping with the second row line RL(2) and arranged in the second row can emit light, and a plurality of light emitting devices ED overlapping with the first row line RL(1) and the third to n-th row lines RL(3) to RL(n) and arranged in the first row and the third to n-th rows may not emit light.

For example, the first display-on driving period D_ON(1) and the second display-on driving period D_ON(2) to D_ON(n) can be included in one display driving period D. For another example, the first display-on driving period D_ON(1) and the second display-on driving period D_ON(2) to D_ON(n) can be included in different display driving periods D.

Further, (m×k) column lines CL can be arranged in a unit driving area UDA. In the unit driving area UDA, the (m×k) column lines CL can intersect with n row lines RL(1) to RL(n). The column line CL illustrated in FIG. 7 can be one of the (m×k) column lines CL.

During the display driving period D, each of the (m×k) column lines CL intersecting the n row lines RL(1) to RL(n) can be supplied with a display voltage VEM required to emit light from the corresponding light emitting device ED in synchronization with the display-on driving period D_ON(1) to D_ON(n) of each of the n row lines RL(1) to RL(n). Here, the display voltage VEM can also be referred to as a light emitting driving voltage or an emission driving voltage.

During the display driving period D, during all remaining times except for the display-on driving period D_ON(1) to D_ON(n) of each of the n row lines RL(1) to RL(n), a reset voltage VRST can be applied to each of the (m×k) column lines CL intersecting the n row lines RL(1) to RL(n).

The display voltage VEM can be a constant voltage or a voltage that varies depending on the image signal. The reset voltage VRST can be a voltage that is lower than the display voltage VEM, and can be a constant voltage or a variable voltage.

During the display driving period D, during the display-on driving period D_ON(1) to D_ON(n) of each of the n row lines RL(1) to RL(n), the voltage difference VEM-VSS1 between the display voltage VEM applied to the corresponding column line CL and the first low-potential voltage VSS1 applied to the corresponding row line RL can be a display-on voltage ΔVon.

A light emitting device ED can be connected between the corresponding column line CL and the corresponding row line RL. A display voltage VEM and a first low-potential voltage VSS1 can be respectively applied to the first electrode Ecl and the second electrode Erl of the light emitting device ED.

The display-on voltage ΔVon is a voltage difference between the first electrode Ecl and the second electrode Erl of the light emitting device ED, and can be a voltage that can cause the light emitting device ED to emit light. For example, the display-on voltage ΔVon can be equal to or higher than a threshold voltage, which is a unique characteristic value of the light emitting device ED.

During the display driving period D, during all the remaining time except for the display-on driving period D_ON(1) to D_ON(n) of each of the n row lines RL(1) to RL(n), the voltage difference VRST-VSS2 between the reset voltage VRST applied to the corresponding column line CL and the second low-potential voltage VSS2 applied to the corresponding row line RL can be a display-off voltage ΔVoff.

A light emitting device ED can be connected between the corresponding column line CL and the corresponding row line RL. A reset voltage VRST and a second low-potential voltage VSS2 can be respectively applied to the first electrode Ecl and the second electrode Erl of the light emitting device ED.

The display-off voltage ΔVoff is a voltage difference between the first electrode Ecl and the second electrode Erl of the corresponding light emitting device ED, and can be a voltage that does not allow the corresponding light emitting device ED to emit light. For example, the display-off voltage ΔVoff can be less than the threshold voltage, which is a unique characteristic (or, a unique characteristic value) of the corresponding light emitting device ED. For example, the display-on voltage ΔVon can be greater than or equal to the display-off voltage ΔVoff.

Hereinafter, it will be described in more detail a circuit for driving n light emitting devices ED(1) to ED(n) connected to one column line CL in the display panel 110 according to embodiments of the present disclosure.

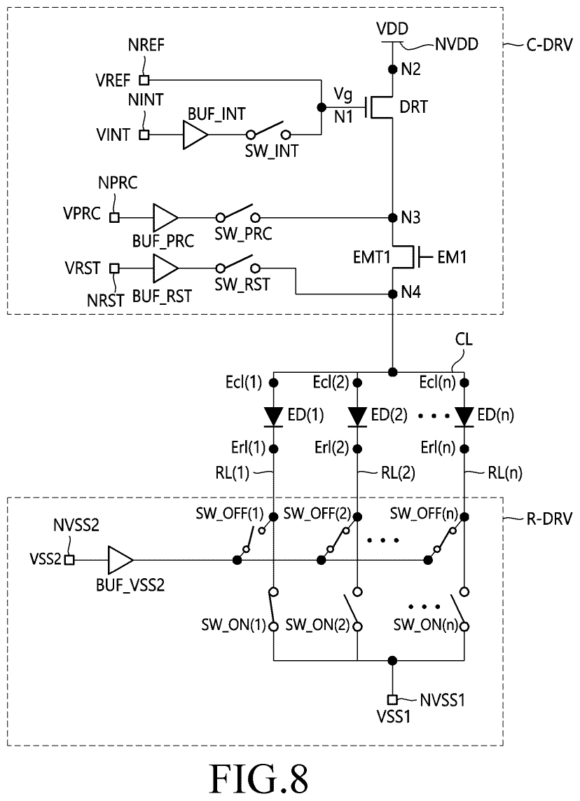

FIG. 8 illustrates a circuit for driving n light emitting devices ED(1) to ED(n) connected to one column line CL included in a first sub-driving area SDA1 of a display panel 110 according to embodiments of the present disclosure. FIG. 4 and FIG. 6 can also be referred to in the following description.

Referring to FIG. 8, n light emitting devices ED(1) to ED(n) connected to one column line CL can be arranged in the same column. The n light emitting devices ED(1) to ED(n) arranged in the same column can be connected to one column line CL. The n light emitting devices ED(1) to ED(n) connected to one column line CL can be arranged in one of the first sub-driving area SDA1 and the second sub-driving area SDA2 included in the unit driving area UDA.

The n light emitting devices ED(1) to ED(n) connected to one column line CL can be light emitting devices emitting the same color light. The n light emitting devices ED(1) to ED(n) arranged in the same column can be light emitting devices emitting the same color light.

For example, the n light emitting devices ED(1) to ED(n) arranged in the same column can emit light sequentially. As another example, the n light emitting devices ED(1) to ED(n) arranged in the same column can emit light simultaneously. As another example, two or more of n light emitting devices ED(1) to ED(n) arranged in the same column can emit light simultaneously.

For example, n light emitting devices ED(1) to ED(n) arranged in the same column can include first electrodes Ecl(1) to Ecl(n) and second electrodes Erl(1) to Erl(n).

All first electrodes Ecl(1) to Ecl(n) of n light emitting devices ED(1) to ED(n) arranged in the same column can be connected to one column line CL. The second electrodes Erl(1) to Erl(n) of the n light emitting devices ED(1) to ED(n) arranged in the same column can be respectively connected to the n row lines RL(1) to RL(n).

A circuit for driving the n light emitting devices ED(1) to ED(n) arranged in the same column can include a column driver C-DRV and a row driver R-DRV.

The column driver C-DRV can be configured to drive the column line CL connected to all of the first electrodes Ecl(1) to Ecl(n) of the n light emitting devices ED(1) to ED(n) arranged in the same column.

The row driver R-DRV can be configured to drive n row lines RL(1) to RL(n) which are respectively connected to the second electrodes Erl(1) to Erl(n) of n light emitting devices ED(1) to ED(n) arranged in the same column.

The column driver C-DRV can include first to fourth nodes N1 to N4, and can include a driving transistor DRT and a first emission control transistor EMT1.

The first node N1 can be a node to which a voltage Vg for controlling the on-off of the driving transistor DRT is applied. The second node N2 can be a node electrically connected to a high-potential voltage node NVDD to which a high-potential voltage VDD is applied. The third node N3 can be a node to which the driving transistor DRT and the first emission control transistor EMT1 are connected. The fourth node N4 can be a node to which the first emission control transistor EMT1 and the n light emitting devices ED(1) to ED(n) are electrically connected, and can be a node to which the column line CL is electrically connected. Here, the source electrode or the drain electrode of the first emission control transistor EMT1 and the first electrodes Ecl(1) to Ecl(n) of the n light emitting devices ED(1) to ED(n) can be commonly connected to the column line CL.

The driving transistor DRT supplies a driving current to emit light to n light emitting devices ED(1) to ED(n), is connected between the second node N2 and the third node N3, and can control the connection between the second node N2 and the third node N3 according to the voltage of the first node N1.

The gate electrode of the driving transistor DRT is electrically connected to the first node N1, and is supplied with a gate voltage Vg. The drain electrode or the source electrode of the driving transistor DRT can be electrically connected to the second node N2. The source electrode or the drain electrode of the driving transistor DRT can be electrically connected to the third node N3.

The first emission control transistor EMT1 can control the connection of a path through which the driving current flows, and can play a role in controlling an emission of the light emitting device ED.

The first emission control transistor EMT1 is connected between the third node N3 and the fourth node N4, and can control the connection between the third node N3 and the fourth node N4 according to the first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or the drain electrode of the first emission control transistor EMT1 can be electrically connected to the fourth node N4.

The first emission control signal EM1 can be a pulse width modulation signal that varies at a predefined time (for example, each frame, or each sub-frame included in one frame), but the embodiments of the present disclosure are not limited thereto.

The first emission control signal EM1 can be generated from the driver DRV or supplied to the driver DRV from a driving-related circuit such as a timing controller.

The column driver C-DRV can further include a reference voltage node NREF electrically connected to the first node N1. A reference voltage VREF can be applied to the reference voltage node NREF. Here, the reference voltage VREF can be a gate voltage Vg of the driving transistor DRT.

For example, the reference voltage VREF can have a constant voltage value.

For another example, the reference voltage VREF can have a different voltage value depending on the color light emitted from the light emitting device ED in which the display-on operation is performed. For example, the reference voltage VREF applied to the first node N1 during the driving period for emitting light of the light emitting device EDa emitting a first color light, the reference voltage VREF applied to the first node N1 during the driving period for emitting light of the light emitting device EDb emitting a second color light, and the reference voltage VREF applied to the first node N1 during the driving period for emitting light of the light emitting device EDc emitting a third color light can have different voltage values.

The column driver C-DRV can further include an initialization voltage node NINT electrically connected to the first node N1 through an initialization switch SW_INT. An initialization voltage VINT can be applied to the initialization voltage node NINT. Here, the initialization voltage VINT can be a gate voltage Vg of the driving transistor DRT.

The column driver C-DRV can further include an initialization buffer BUF_INT connected between the initialization switch SW_INT and the initialization voltage node NINT. The initialization buffer BUF_INT can amplify the initialization voltage VINT applied to the initialization voltage node NINT and supply an amplified initialization voltage to the first node N1.

The column driver C-DRV can further include a pre-charge voltage node NPRC electrically connected to a third node N3 through a pre-charge switch SW_PRC. A pre-charge voltage VPRC can be applied to the pre-charge voltage node NPRC.

The column driver C-DRV can further include a pre-charge buffer BUF_PRC connected between the pre-charge switch SW_PRC and the pre-charge voltage node NPRC. The pre-charge buffer BUF_PRC can amplify the pre-charge voltage VPRC applied to the pre-charge voltage node NPRC and supply an amplified pre-charge voltage to the third node N3.

The column driver C-DRV can further include a reset voltage node NRST electrically connected to a fourth node N4 through a reset switch SW_RST. A reset voltage VRST can be applied to the reset voltage node NRST.

The column driver C-DRV can further include a reset buffer BUF_RST connected between the reset switch SW_RST and the reset voltage node NRST. The reset buffer BUF_RST can amplify the reset voltage VRST applied to the reset voltage node NRST and supply an amplified reset voltage to the fourth node N4. Here, the fourth node N4 can be electrically connected to the corresponding column line CL.

The row driver R-DRV can be configured to drive n row lines RL(1) to RL(n) respectively connected to the second electrodes Erl(1) to Erl(n) of n light emitting devices ED(1) to ED(n) arranged in the same column.

The row driver R-DRV can include n display-on switches SW_ON(1) to SW_ON(n) that electrically connect each of n row lines RL(1) to RL(n) to a first low-potential voltage node NVSS1. A first low-potential voltage VSS1 can be applied to the first low-potential voltage node NVSS1.

The turn-on timing of each of the n display-on switches SW_ON(1) to SW_ON(n) can be different from each other. Accordingly, display-on driving for the n row lines RL(1) to RL(n) can be sequentially performed.

The row driver R-DRV can include n display-off switches SW_OFF(1) to SW_OFF(n) that electrically connect each of the n row lines RL(1) to RL(n) to a second low-potential voltage node NVSS2 to which a second low-potential voltage VSS2 is applied. The second low-potential voltage VSS2 can be a low-potential voltage higher than the first low-potential voltage VSS1. The row driver R-DRV can further include a second low-potential buffer BUF_VSS2 connected between the n display-off switches SW_OFF(1) to SW_OFF(n) and the second low-potential voltage node NVSS2.

The turn-on timing of each of the n display-off switches SW_OFF(1) to SW_OFF(n) can be different from each other. Accordingly, the display-off driving for the n display-off switches SW_OFF(1) to SW_OFF(n) can be performed at different timings.

According to the example of FIG. 8, the row driver R-DRV can perform display-on driving for the first row line RL(1) among the n row lines RL(1) to RL(n), and perform display-off driving for the second to n-th row lines RL(2) to RL(n).

To this end, among the n display-on switches SW_ON(1) to SW_ON(n), a first display-on switch SW_ON(1) can be in a turn-on state, and a second to n-th display-on switches SW_ON(2) to SW_ON(n) can be in a turn-off state. In addition, among the n display-off switches SW_OFF(1) to SW_OFF(n), the first display-off switch SW_OFF(1) can be in a turn-off state, and the second to n-th display-off switches SW_OFF(2) to SW_OFF(n) can be in a turn-on state.

Accordingly, among the n row lines RL(1) to RL(n), a first low-potential voltageVSS1) can be applied to the first row line RL(1), and a second low-potential voltage VSS2 can be applied to the second to n-th row lines RL(2) to RL(n). Here, the first low-potential voltage VSS1 can have a lower voltage value than the second low-potential voltage VSS2.

Each of the transistors DRT and EM1 included in the column driver C-DRV can be an n-type transistor or a p-type transistor. The switches SW_ON(1) to SW_ON(n), SW_OFF(1) to SW_OFF(n) included in the row driver R-DRV can be implemented as an n-type transistor or a p-type transistor. The column driver C-DRV can further include at least one capacitor.

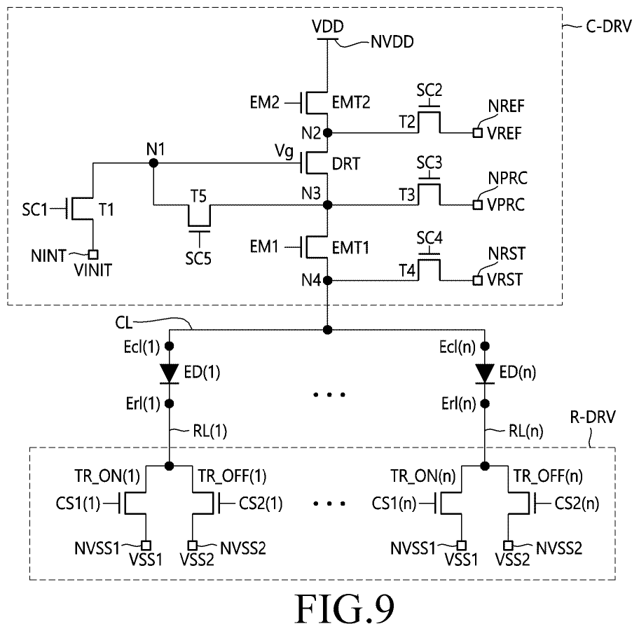

Hereinafter, it will be described the different circuit structures of the column driver C-DRV and the row driver R-DRV with reference to FIG. 9.

FIG. 9 illustrates another circuit for driving n light emitting devices ED(1) to ED(n) connected to one column line CL included in the first sub-driving area SDA1 of the display panel110) according to the embodiments of the present disclosure. In the following description, the description of the same content as in the circuit of FIG. 8 can be omitted.

Referring to FIG. 9, n light emitting devices ED(1) to ED(n) connected to one column line CL can be arranged in the same column. The n light emitting devices ED(1) to ED(n) arranged in the same column can be connected to one column line CL. The n light emitting devices ED(1) to ED(n) connected to one column line CL can be arranged in one of the first sub-driving area SDA1 and the second sub-driving area SDA2 included in the unit driving area UDA.

The n light emitting devices ED(1) to ED(n) connected to one column line CL can be light emitting devices emitting the same color light. The n light emitting devices ED(1) to ED(n) arranged in the same column can be light emitting devices emitting the same color light.

The n light emitting devices ED(1) to ED(n) arranged in the same column can include first electrodes Ecl(1) to Ecl(n) and second electrodes Erl(1) to Erl(n).

The first electrodes Ecl(1) to Ecl(n) of the n light emitting devices ED(1) to ED(n) arranged in the same column can all be connected to one column line CL. The second electrodes Erl(1) to Erl(n) of the n light emitting devices ED(1) to ED(n) arranged in the same column can be respectively connected to the n row lines RL(1) to RL(n).

A circuit for driving the n light emitting devices ED(1) to ED(n) arranged in the same column can include a column driver C-DRV and a row driver R-DRV.

The column driver C-DRV can include first to fourth nodes N1 to N4, and can include a driving transistor DRT, a first emission control transistor EMT1, and a second emission control transistor EMT2.

The first node N1 can be a node to which a voltage Vg for controlling on-off of the driving transistor DRT is applied. The second node N2 can be a node to which the second emission control transistor EMT2 and the driving transistor DRT are connected. The third node N3 can be a node to which the driving transistor DRT and the first emission control transistor EMT1 are connected. The fourth node N4 can be a node to which the first emission control transistor EMT1 and the n light emitting devices ED(1) to ED(n) are electrically connected, and can be a node to which the column line CL is electrically connected. Here, the source electrode or the drain electrode of the first emission control transistor EMT1 and the first electrodes Ecl(1) to Ecl(n) of the n light emitting devices ED(1) to ED(n) can be commonly connected to the column line CL.

The driving transistor DRT supplies a driving current to emit light to n light emitting devices ED(1) to ED(n), is connected between the second node N2 and the third node N3, and can control the connection between the second node N2 and the third node N3 according to the voltage of the first node N1.

The gate electrode of the driving transistor DRT is electrically connected to the first node N1, and can be supplied with a gate voltage Vg. The drain electrode or the source electrode of the driving transistor DRT can be electrically connected to the second node N2. The source electrode or the drain electrode of the driving transistor DRT can be electrically connected to the third node N3.

The first emission control transistor EMT1 and the second emission control transistor EMT2 can control the connection of a path through which a driving current flows, and can play a role in controlling an emission of a light emitting device ED.

The first emission control transistor EMT1 is connected between the third node N3 and the fourth node N4, and can control the connection between the third node N3 and the fourth node N4 according to a first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or the drain electrode of the first emission control transistor EMT1 can be electrically connected to the fourth node N4.

The first emission control signal EM1 can be a pulse width modulation signal that varies at a predefined time (for example, each frame, or each sub-frame included in a frame), but the embodiments of the present disclosure are not limited thereto. The first emission control signal EM1 can be generated by the driver DRV, or can be supplied to the driver DRV from a driving-related circuit such as a timing controller.

The second emission control transistor EMT2 is connected between the high-potential voltage node NVDD and the second node N2, and can control the connection between the high-potential voltage node NVDD and the second node N2 according to a second emission control signal EM2. The second emission control signal EM2 can be applied to the gate electrode of the second emission control transistor EMT2. The drain electrode or the source electrode of the second emission control transistor EMT2 can be electrically connected to the high-potential voltage node NVDD. The source electrode or drain electrode of the second emission control transistor EMT2 can be electrically connected to the second node N2. Here, the second emission control signal EM2 can be the same as or different from the first emission control signal EM1.

The column driver DRV can further include a first transistor T1 whose on-off is controlled according to a first scan signal SC1 so as to control the connection between the first node N1 and the initialization voltage node NINT. Here, the initialization voltage VINT can be applied to the initialization voltage node NINT.

The column driver DRV can further include a second transistor T2 whose on-off is controlled according to a second scan signal SC2, so as to control the connection between the second node N2 and the reference voltage node NREF. Here, a reference voltage VREF can be applied to the reference voltage node NREF.

The column driver DRV can further include a third transistor T3 whose on-off is controlled according to a third scan signal SC3, so as to control the connection between the third node N3 and the pre-charge voltage node NPRC. Here, a pre-charge voltage VPRC can be applied to the pre-charge voltage node NPRC.

The column driver DRV can further include a fourth transistor T4 whose on-off is controlled according to a fourth scan signal SC4, so as to control the connection between the fourth node N4 and the reset voltage node NRST. Here, a reset voltage VRST can be applied to the reset voltage node NRST.

The column driver DRV can further include a fifth transistor T5 whose on-off is controlled according to a fifth scan signal SC5, so as to control the connection between the first node N1 and the third node N3. If the fifth transistor T5 is turned on, the first node N1 and the third node N3 are electrically connected, so that the driving transistor DRT can be in a diode-connected state. Here, for example, the fifth scan signal SC5 can be a scan signal that is different from or the same as the second scan signal SC2.

The row driver R-DRV can be configured to drive n row lines RL(1) to RL(n) that are respectively connected to the second electrodes Erl(1) to Erl(n) of n light emitting devices ED(1) to ED(n) arranged in the same column.

The row driver R-DRV can include n display-on transistors TR_ON(1) to TR_ON(n) that electrically connect each of n row lines RL(1) to RL(n) to a first low-potential voltage node NVSS1. A first low-potential voltage VSS1 can be applied to the first low-potential voltage node NVSS1. The n display-on transistors TR_ON(1) to TR_ON(n) can be turned on and off by n display-on control signals CS1(1) to CS1(n).

The turn-on timing of each of the n display-on transistors TR_ON(1) to TR_ON(n) can be different from each other. Accordingly, display-on driving for the n row lines RL(1) to RL(n) can be sequentially performed.

The row driver R-DRV can include n display-off transistors TR_OFF(1) to TR_OFF(n) that electrically connect each of n row lines RL(1) to RL(n) to a second low-potential voltage node NVSS2 to which a second low-potential voltageVSS2) is applied. The second low-potential voltage VSS2 can be a low-potential voltage higher than the first low-potential voltage VSS1. The n display-off transistors TR_OFF(1) to TR_OFF(n) can be turned on and off by n display-off control signals CS2(1) to CS2(n).

The turn-on timing of each of the n display-off transistors TR_OFF(1) to TR_OFF(n) can be different from each other. Accordingly, display-off driving for n display-off transistors TR_OFF(1) to TR_OFF(n) can be performed at different timings.

For example, one display-on transistor among n display-on transistors TR_ON(1) to TR_ON(n) and one display-off transistor among n display-off transistors TR_OFF(1) to TR_OFF(n) can be connected to each of n row lines RL(1) to RL(n).

Only one of the display-on transistors and display-off transistors connected to each of n row lines RL(1) to RL(n) can be selectively turned on.

For example, if a display-on driving is performed for the first row line RL(1) among the n row lines RL(1) to RL(n), among the first display-on transistor TR_ON(1) and the first display-off transistor TR_OFF(1) connected to the first row line RL(1), the first display-on transistor TR_ON(1) can be turned on and the first display-off transistor TR_OFF(1) can be turned off. At this time, if display-off driving is performed for the second to n-th row lines RL(2) to RL(n), among the display-on transistors and display-off transistors connected to each of the second to n-th row lines RL(2) to RL(n), the display-on transistor can be turned off and the display-off transistor can be turned on. Accordingly, a first low-potential voltage VSS1, which is a low-potential voltage for driving the display-on, can be applied only to the first row line RL(1) among the n row lines RL(1) to RL(n), and a second low-potential voltage VSS2, which is a low-potential voltage for driving the display-off, can be applied to the remaining second to n-th row lines RL(2) to RL(n). Referring to FIG. 9, the driving timing of the subpixel SP is as follows.

During a first driving period, the first transistor T1 among the first to fifth transistors T1 to T5 can be turned on, and the initialization voltage VINT can be applied to the first node N1. The driving transistor DRT can be turned on by the initialization voltage VINT applied to the first node N1.

Thereafter, during a second driving period, the second transistor T2 can be turned on, and the reference voltage VREF can be applied to the second node N2. In this case, the fifth transistor T5 can also be turned on.

Thereafter, during a third driving period, the third transistor T3 can be turned on, so that the pre-charge voltage VPRC can be applied to the third node N3.

Then, during a fourth driving period, one of the n light emitting devices ED(1) to ED(n) can emit light. During the fourth driving period, the light emitting devices in an emission state among the n row lines RL(1) to RL(n) can be supplied with the first low-potential voltage VSS1, which is a low-potential voltage for display-on driving, and the light emitting devices in a non-emission state can be supplied with the second low-potential voltage VSS2, which is a low-potential voltage for display-off driving.

To this end, among the n row lines RL(1) to RL(n), the row line on which display-on driving is performed can be supplied with the first low-potential voltage VSS1, and the remaining row lines on which display-off driving is performed can be supplied with the second low-potential voltage VSS2.

Therefore, among the display-on transistor and the display-off transistor connected to the row line where the display-on driving is performed, the display-on transistor can be in a turn-on state and the display-off transistor can be in a turn-off state.

Among the display-on transistor and the display-off transistor connected to the row line where the display-off driving is performed, the display-on transistor can be in a turn-off state and the display-off transistor can be in a turn-on state.

Thereafter, during a fifth driving period, the fourth transistor T4 can be turned on, so that the reset voltage VRST can be applied to the fourth node N4. Accordingly, the column line CL can be reset to the reset voltage VRST. In addition, all of the first electrodes Ecl(1) to Ecl(n) of the n light emitting devices ED(1) to ED(n) connected to the column line CL can be reset to the reset voltage VRST.

The first to fourth scan signals SC1 to SC4 and the first and second emission control signals EM1 and EM2 can be generated by the corresponding driver DRV, or can be supplied to the corresponding driver DRV from a driving-related circuit such as a timing controller.

Each of the transistors DRT and T1 to T5 included in the column driver C-DRV can be an n-type transistor or a p-type transistor. Each of the transistors TR_ON(1) to TR_ON(n), TR_OFF(1) to TR_OFF(n) included in the row driver R-DRV can be an n-type transistor or a p-type transistor. The column driver C-DRV can further include at least one capacitor.

As described above, the column driver C-DRV and the row driver R-DRV can be included in the driver DRV.

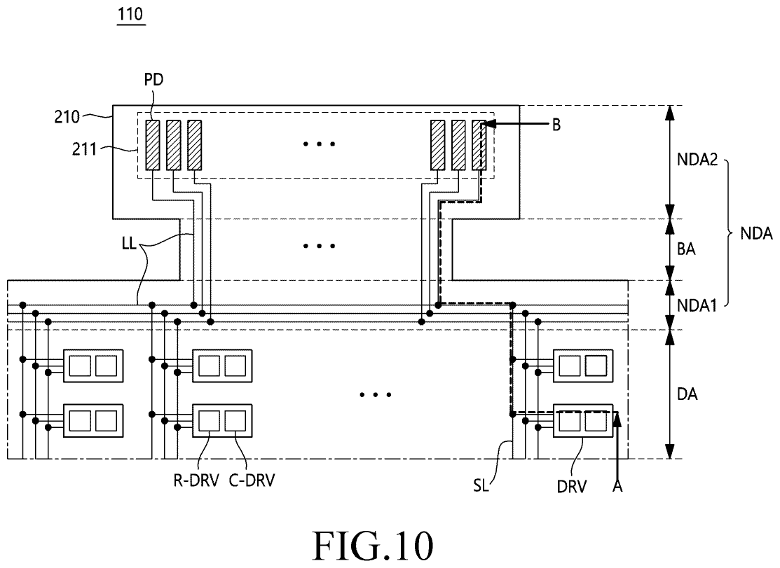

In order for the plurality of drivers DRV included in the display device 100 according to the embodiments of the present disclosure to perform a driving operation, the plurality of drivers DRV are required to be supplied with power required for the driving operation. Accordingly, hereinafter, it will be described a power supply structure for supplying power required for the driving operation to the plurality of drivers DRV with reference to FIG. 10.

FIG. 10 is a plan view of the display panel 110 according to the embodiments of the present disclosure.

Referring to FIG. 10, the substrate 210 of the display panel 110 according to the embodiments of the present disclosure can include a display area DA and a non-display area NDA, and the non-display area NDA can include a first non-display area NDA1, a bending area BA, and a second non-display area NDA2.

A plurality of drivers DRV can be arranged in the display area DA. Each of the plurality of drivers DRV can be a circuit for driving light emitting devices of a plurality of subpixels included in a corresponding unit driving area (UDA of FIGS. 4 and 6). Each of the plurality of drivers DRV can include a row driver R-DRV for driving a plurality of row lines and a column driver C-DRV for driving a plurality of column lines, in order to drive a plurality of light emitting devices ED included in a corresponding unit driving area (UDA of FIGS. 4 and 6).

A pad section 211 including a plurality of pads PD can be arranged in the second non-display area NDA2.

A plurality of signal lines SL and a plurality of link lines LL for signal transmission between a plurality of drivers DRV arranged in the display area DA and the pad section 211 can be arranged on the substrate 210. The plurality of signal lines SL can be electrically connected between the plurality of link lines LL and the plurality of drivers DRV. The plurality of link lines LL can electrically connect the plurality of pads PD and the plurality of signal lines SL.

The plurality of link lines LL can be arranged in the non-display area NDA, and all or part of each of the plurality of signal lines SL can be arranged in the display area DA.

Each of the plurality of drivers DRV can receive various signals to perform a driving operation through the plurality of link lines LL and the plurality of signal lines SL. Here, the various signals can include various power voltages and various signals required for the driving operation of each of the plurality of drivers DRV.

As the bending area BA is bent, a portion of the plurality of link lines LL can also be bent. Stress can be concentrated on a portion of the bent link line LL, and thus cracks can occur in the link line LL. Accordingly, the plurality of link lines LL can be formed of a conductive material having excellent ductility to reduce cracks when the bending area BA is bent. For example, the plurality of link lines LL can be formed of a conductive material having excellent ductility, such as gold (Au), silver (Ag), aluminum (Al), but the embodiments of the present disclosure are not limited thereto. In addition, the plurality of link lines LL can be composed of one of various conductive materials used in the display area DA. For example, the plurality of link lines LL can be composed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto. The plurality of link lines LL can be composed of a multilayer structure including various conductive materials. For example, the plurality of link lines LL can be composed of a triple layer structure of titanium (Ti)/aluminum (Al)/titanium (Ti), but the embodiments of the present disclosure are not limited thereto.

The plurality of link lines LL can be composed of various shapes to reduce stress. At least a portion of the plurality of link lines LL arranged on the bending area BA can extend in the same direction as the extension direction of the bending area BA, or can extend in a direction different from the extension direction of the bending area BA to reduce stress. For example, if the bending area BA extends in one direction from the first non-display area NDA1 toward the second non-display area NDA2, at least a portion of the link lines LL arranged on the bending area BA can extend in a direction oblique to the one direction. As another example, at least a portion of the plurality of link lines LL can be configured as patterns of various shapes. For example, at least a portion of the plurality of link lines LL arranged on the bending area BA can be a shape in which conductive patterns having at least one shape among a diamond shape, a rhombus shape, a trapezoidal wave shape, a triangular wave shape, a sawtooth wave shape, a sine wave shape, a circular shape, and an omega (Ω) shape are repeatedly arranged, but the embodiments of the present disclosure are not limited thereto. Therefore, in order to minimize the stress concentrated on the plurality of link lines LL and the resulting cracks, the shapes of the plurality of link lines LL can be formed in various shapes including the shapes described above, but the embodiments of the present disclosure are not limited thereto.

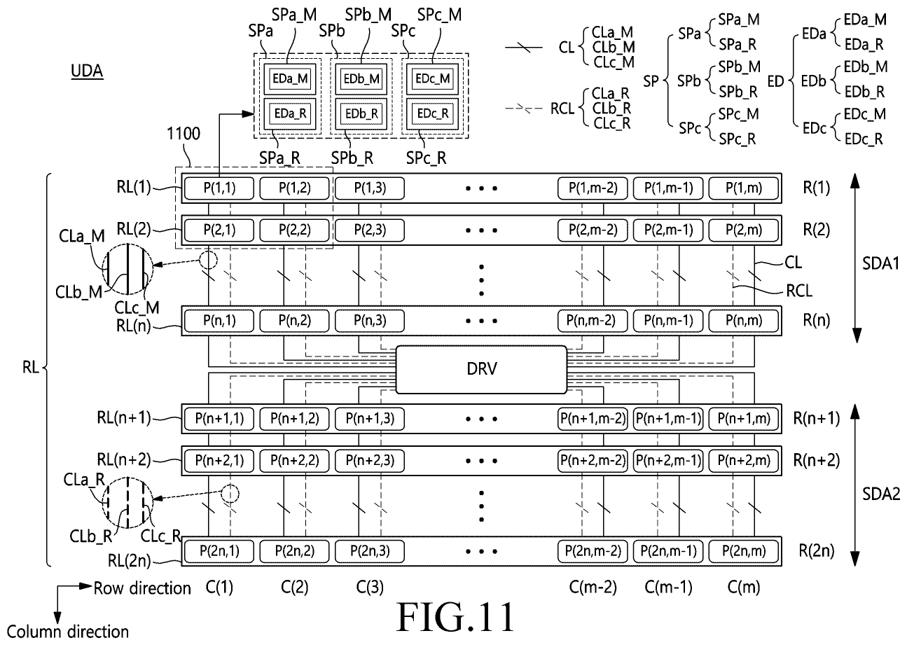

FIG. 11 illustrates a unit driving area UDA of a display panel 110 according to embodiments of the present disclosure. In the following description, FIG. 3 and FIG. 4 are also referred to, and the same contents described with reference to FIG. 3 and FIG. 4 can be omitted.

Referring to FIG. 11, the display panel 110 according to embodiments of the present disclosure can include a plurality of pixels P, a plurality of row lines RL, and a plurality of column lines CL.

According to the example of FIG. 11, the plurality of pixels P can include pixels P(1, 1), . . . , P(1, m), P(2, 1), . . . , P(2, m), . . . , P(2n, 1), . . . , P(2n, m) of (2n×m) pixels arranged in the unit driving area UDA. The plurality of row lines RL can include 2n row lines RL(1) to RL(2n) arranged in the unit driving area UDA.

The display panel 110 according to the embodiments of the present disclosure can include a redundancy structure.

According to the redundancy structure, each of the plurality of pixels P can include k main subpixels and k redundancy subpixels. Each of the k main subpixels can include a main light emitting device, and each of the k redundancy subpixels can include a redundancy light emitting device. In other words, each of the plurality of pixels P can include k main light emitting devices EDa_M, EDb_M and EDc_M and k redundancy light emitting devices EDa_R, EDb_R and EDc_R.

Each of the plurality of pixels P(1, 1), . . . , P(1, m), P(2, 1), . . . , P(2, m), . . . , P(2n, 1), . . . , P(2n, m) can include a first subpixel SPa, a second subpixel SPb, and a third subpixel SPc.

The first subpixel SPa can include a first main subpixel SPa_M and a first redundancy subpixel SPa_R. The first main subpixel SPa_M can include a first main light emitting device EDa_M, and the first redundancy subpixel SPa_R can include a first redundancy light emitting device EDa_R.

The first subpixel SPa can include a first light emitting device EDa that emits a first color light, and the first light emitting device EDa can include a first main light emitting device EDa_M and a first redundancy light emitting device EDa_R.

The second subpixel SPb can include a second main subpixel SPb_M and a second redundancy subpixel SPb_R. The second main subpixel SPb_M can include a second main light emitting device EDb_M, and the second redundancy subpixel SPb_R can include a second redundancy light emitting device EDb_R.

The second subpixel SPb can include a second light emitting device EDb that emits second color light, and the second light emitting device EDb can include a second main light emitting device EDb_M and a second redundancy light emitting device EDb_R.

The third subpixel SPc can include a third main subpixel SPc_M and a third redundancy subpixel SPc_R. The third main subpixel SPc_M can include a third main light emitting device EDc_M, and the third redundancy subpixel SPc_R can include a third redundancy light emitting device EDc_R.

The third subpixel SPc can include a third light emitting device EDc that emits a third color light, and the third light emitting device EDc can include a third main light emitting device EDc_M and a third redundancy light emitting device EDc_R.

The plurality of column lines CL can include a plurality of main column lines CLa_M, CLb_M and CLc_M and a plurality of redundancy column lines CLa_R, CLb_R and CLc_R.

In each of the plurality of columns (i.e., a plurality of pixel columns) included in each of the first sub-driving area SDA1 and the second sub-driving area SDA2, k main column lines CLa_M, CLb_M and CLc_M, and k redundancy column lines CLa_R, CLb_R and CLc_R can be arranged.

In each column (i.e., each pixel column), k main column lines CLa_M, CLb_M and CLc_M can be connected to the first electrodes Ecl of k main light emitting devices EDa_M, EDb_M and EDc_M.

In each column (i.e., each pixel column), k redundancy column lines CLa_R, CLb_R and CLc_R can be connected to the first electrodes Ecl of k redundancy light emitting devices EDa_R, EDb_R and EDc_R.

Hereinafter, in order to explain the planar structure of the display panel 110 according to the embodiments of the present disclosure in more detail, it will be described the planar structure of a portion 1100 of the planar view of FIG. 11 in more detail as an example.

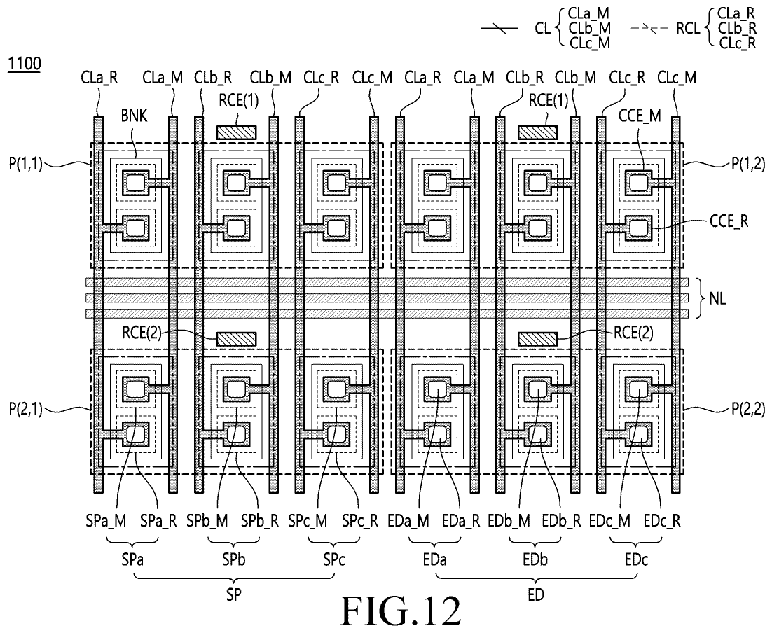

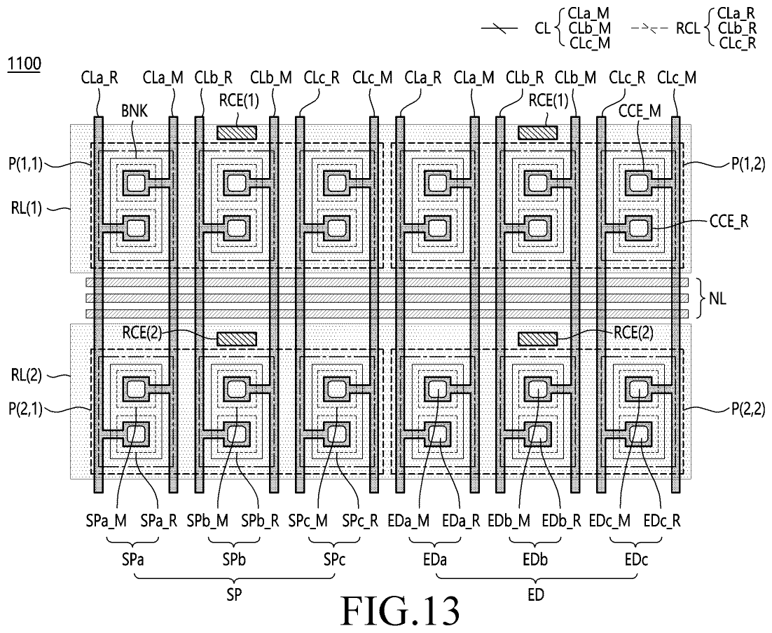

FIG. 12 and FIG. 13 are plan views of a portion 1100 of a display panel 110 according to embodiments of the present disclosure.

Particularly, FIG. 12 and FIG. 13 are enlarged plan views of a portion 1100 of the plan view of FIG. 11, and are enlarged plan views of a two-row, two-column area 1100. FIG. 12 is a plan view that does not represent two row lines RL(1) and RL(2) arranged in a two-row, two-column area 1100, and FIG. 13 is a plan view that adds two row lines RL(1) and RL(2) arranged in a two-row, two-column area 1100 to the plan view of FIG. 12.

Referring to FIG. 12 and FIG. 13, in the two-row, two-column area 1100, four pixels P(1,1), P(1,2), P(2,1), P(2,2) can be arranged in two rows and two columns. For example, in the two-row, two-column area 1100, two pixels P(1,1) and P(1,2) can be arranged in a first row (e.g., a first pixel row), and two pixels P(2,1) and P(2,2) can be arranged in a second row (e.g., a second pixel row). In addition, two pixels P(1,1) and P(2,1) can be arranged in a first column (e.g., a first pixel column), and two pixels P(1,2) and P(2,2) can be arranged in a second column (e.g., a second pixel column).

In the two-row, two-column area 1100, each of the four pixels P(1,1), P(1,2), P(2,1) and P(2,2) arranged in two rows and two columns can include k subpixels. Here, k is the number of subpixels included in one pixel.

It is exemplified a case where k is 3 is as an example. Accordingly, in the two-row, two-column area 1100, each of the four pixels P(1,1), P(1,2), P(2,1) and P(2,2)) arranged in two rows and two columns can include three subpixels SPa, SPb and SPc. In the following description, it can be explained assuming the case where k is 3.

The three subpixels can include a first subpixel SPa including a first light emitting device EDa that emits a first color light, a second subpixel SPb including a second light emitting device EDb that emits a second color light, and a third subpixel SPc including a third light emitting device EDc that emits a third color light.

If the display panel 110 according to the embodiments of the present disclosure has a redundancy structure, the subpixel redundancy structure is as follows.

The first subpixel SPa can include a first main subpixel SPa_M including a first main light emitting device EDa_M and a first redundancy subpixel SPa_R including a first redundancy light emitting device EDa_R, the second subpixel SPb can include a second main subpixel SPb_M including a second main light emitting device EDb_M and a second redundancy subpixel SPb_R including a second redundancy light emitting device EDb_R, and the third subpixel SPc can include a third main subpixel SPc_M including a third main light emitting device EDc_M and a third redundancy subpixel SPc_R including a third redundancy light emitting device EDc_R.

If the display panel 110 according to the embodiments of the present disclosure has a redundancy structure, the light emitting device redundancy structure is as follows.

The first light emitting device EDa can include a first main light emitting device EDa_M that emits a first color light and a first redundancy light emitting device EDa_R that emits a first color light, the second light emitting device EDb can include a second main light emitting device EDb_M that emits a second color light and a second redundancy light emitting device EDb_R that emits a second color light, and the third light emitting device EDb can include a third main light emitting device EDc_M that emits a third color light and a third redundancy light emitting device EDc_R that emits a third color light.

In the two-row, two-column area 1100, a first row line RL(1) and a second row line RL(2) can be arranged. The first row line RL(1) can be arranged in the first row (i.e., the first pixel row), and the second row line RL(2) can be arranged in the second row (i.e., the second pixel row).

The first row line RL(1) can correspond to two pixels P(1,1) and P(1,2) arranged in the first row (or the first pixel row), and can correspond to three subpixels SPa, SPb and SPc included in each of the two pixels P(1,1) and P(1,2) arranged in the first row (or the first pixel row).

In terms of the subpixel redundancy structure, the first row line RL(1) can be connected to the first main subpixel SPa_M, the first redundancy subpixel SPa_R, the second main subpixel SPb_M, the second redundancy subpixel SPb_R, the third main subpixel SPc_M, and the third redundancy subpixel SPc_R arranged in the first row (or the first pixel row).

At least a portion of the first row line RL(1) can overlap with the first main subpixel SPa_M, the first redundancy subpixel SPa_R, the second main subpixel SPb_M, the second redundancy subpixel SPb_R, the third main subpixel SPc_M, and the third redundancy subpixel SPc_R arranged in the first row (or the first pixel row).

From the perspective of the light emitting device redundancy structure, the first row line RL(1) can be connected to the second electrode Erl of each of the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the first row (or the first pixel row).

At least a portion of the first row line RL(1) can overlap with the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the first row (or the first pixel row).

The second row line RL(2) can correspond to two pixels P(2,1) and P(2,2) arranged in a second row (or the second pixel row), and can correspond to three subpixels SPa, SPb and SPc included in each of the two pixels P(2, 1) and P(2,2) arranged in the second row (or the second pixel row).

In terms of the subpixel redundancy structure, the second row line RL(2) can be connected to the first main subpixel SPa_M, the first redundancy subpixel SPa_R, the second main subpixel SPb_M, the second redundancy subpixel SPb_R, the third main subpixel SPc_M, and the third redundancy subpixel SPc_R arranged in the second row (or the second pixel row).

At least a portion of the second row line RL(2) can overlap with the first main subpixel SPa_M, the first redundancy subpixel SPa_R, the second main subpixel SPb_M, the second redundancy subpixel SPb_R, the third main subpixel SPc_M, and the third redundancy subpixel SPc_R arranged in the second row (or the second pixel row).

In terms of the light emitting device redundancy structure, the second row line RL(2) can be connected to the second electrode Erl of each of the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the second row (or the second pixel row).

At least a portion of the second row line RL(2) can overlap with the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the second row (or the second pixel row).

A plurality of column lines CL can be arranged in the two-row two-column area 1100. A plurality of column lines CL arranged in a two-row two-column area 1100 can include a plurality of first column lines CL connected to two pixels P(1,1) and P(2,1) arranged in a first column (or a first pixel column), and a plurality of second column lines CL connected to two pixels P(1,2) and P(2,2) arranged in a second column (or a second pixel column).

From the perspective of subpixel redundancy, a plurality of first column lines CL arranged in a first column (or first pixel column) can include a first main column line CLa_M that is commonly connected to a first main subpixel SPa_M included in each of two pixels P(1,1) and P(2,1) arranged in the first column (or first pixel column), and a first redundancy column line CLa_R that is commonly connected to a first redundancy subpixel SPa_R included in each of two pixels P(1,1) and P(2,1) arranged in the first column (or first pixel column).

The first main subpixel SPa_M included in each of the two pixels P(1,1) and P(2,1) arranged in the first column (or the first pixel column) can include a first main light emitting device EDa_M, and the first redundancy subpixel SPa_R included in each of the two pixels P(1,1) and P(2,1) arranged in the first column (or the first pixel column) can include a first redundancy light emitting device EDa_R.

The first main column line CLa_M arranged in the first column (or the first pixel column) can be commonly connected to the first electrodes Ecl of the two first main light emitting devices EDa_M arranged in the first column (or the first pixel column).

The first redundancy column line CLa_R arranged in the first column (or the first pixel column) can be commonly connected to the first electrodes Ecl of two first redundancy light emitting devices EDa_R arranged in the first column (or the first pixel column).

In addition, the plurality of first column lines CL arranged in the first column (or the first pixel column) can further include a second main column line CLb_M commonly connected to a second main subpixel SPb_M included in each of the two pixels P(1,1) and P(2,1) arranged in the first column (or the first pixel column), and a second redundancy column line CLb_R commonly connected to a second redundancy subpixel SPb_R included in each of the two pixels P(1,1) and P(2,1) arranged in the first column (or the first pixel column).

The second main subpixel SPb_M included in each of the two pixels P(1,1) and P(2,1) arranged in the first column (or the first pixel column) can include a second main light emitting device EDb_M, and the second redundancy subpixel SPb_R included in each of the two pixels P(1,1) and P(2,1) arranged in the first column (or the first pixel column) can include a second redundancy light emitting device EDb_R.

The second main column line CLb_M arranged in the first column (or the first pixel column) can be commonly connected to the first electrodes Ecl of the two second main light emitting devices EDb_M arranged in the first column (or the first pixel column).

The second redundancy column line CLb_R arranged in the first column (or the first pixel column) can be commonly connected to the first electrodes Ecl of the two second redundancy light emitting devices EDb_R arranged in the first column (or the first pixel column).

In addition, the plurality of first column lines CL arranged in the first column (or the first pixel column) can further include a third main column line CLc_M commonly connected to the third main subpixel SPc_M included in each of the two pixels P(1,1) and P(2,1) arranged in the first column (or the first pixel column), and a third redundancy column line CLc_R commonly connected to the third redundancy subpixel SPc_R included in each of the two pixels P(1,1) and P(2,1) arranged in the first column (or the first pixel column).

The third main subpixel SPc_M included in each of the two pixels P(1,1) and P(2,1) arranged in the first column (or the first pixel column) can include a third main light emitting device EDc_M, and the third redundancy subpixel SPc_R included in each of the two pixels P(1,1) and P(2,1) arranged in the first column (or the first pixel column) can include a third redundancy light emitting device EDc_R.

The third main column line CLc_M arranged in the first column (or the first pixel column) can be commonly connected to the first electrodes Ecl of the two third main light emitting devices EDc_M arranged in the first column (or the first pixel column).

The third redundancy column line CLc_R arranged in the first column (or the first pixel column) can be commonly connected to the first electrodes Ecl of two third redundancy light emitting devices EDc_R arranged in the first column (or the first pixel column).

From the perspective of subpixel redundancy, a plurality of second column lines CL arranged in a second column (or second pixel column) can include a first main column line CLa_M that is commonly connected to a first main subpixel SPa_M included in each of two pixels P(1,2) and P(2,2) arranged in the second column (or second pixel column), and a first redundancy column line CLa_R that is commonly connected to a first redundancy subpixel SPa_R included in each of two pixels P(1,2) and P(2,2) arranged in the second column (or second pixel column).

The first main subpixel SPa_M included in each of the two pixels P(1,2) and P(2,2) arranged in the second column (or the second pixel column) can include a first main light emitting device EDa_M, and the first redundancy subpixel SPa_R included in each of the two pixels P(1,2) and P(2,2) arranged in the second column (or the second pixel column) can include a first redundancy light emitting device EDa_R.

The first main column line CLa_M arranged in the second column (or the second pixel column) can be commonly connected to the first electrodes Ecl of the two first main light emitting devices EDa_M arranged in the second column (or the second pixel column).

The first redundancy column line CLa_R arranged in the second column (or the second pixel column) can be commonly connected to the first electrodes Ecl of the two first redundancy light emitting devices EDa_R arranged in the second column (or the second pixel column).

In addition, the plurality of second column lines CL arranged in the second column (second pixel column) can further include a second main column line CLb_M commonly connected to a second main subpixel SPb_M included in each of two pixels P(1,2) and P(2,2) arranged in the second column (or second pixel column), and a second redundancy column line CLb_R commonly connected to a second redundancy subpixel SPb_R included in each of two pixels P(1,2) and P(2,2) arranged in the second column (or second pixel column).

The second main subpixel SPb_M included in each of the two pixels P(1,2) and P(2,2) arranged in the second column (or the second pixel column) can include a second main light emitting device EDb_M, and the second redundancy subpixel SPb_R included in each of the two pixels P(1,2) and P(2,2) arranged in the second column (or the second pixel column) can include a second redundancy light emitting device EDb_R.

The second main column line CLb_M arranged in the second column (or the second pixel column) can be commonly connected to the first electrodes Ecl of the two second main light emitting devices EDb_M arranged in the second column (or the second pixel column).

The second redundancy column line CLb_R arranged in the second column (or the second pixel column) can be commonly connected to the first electrodes Ecl of two second redundancy light emitting devices EDb_R arranged in the second column (or the second pixel column).

In addition, the plurality of second column lines CL arranged in the second column (or the second pixel column) can further include a third main column line CLc_M commonly connected to a third main subpixel SPc_M included in each of two pixels P(1,2) and P(2,2) arranged in the second column (or the second pixel column), and a third redundancy column line CLc_R commonly connected to a third redundancy subpixel SPc_R included in each of two pixels P(1,2) and P(2,2) arranged in the second column (or the second pixel column).

The third main subpixel SPc_M included in each of the two pixels P(1,2) and P(2,2) arranged in the second column (or the second pixel column) can include a third main light emitting device EDc_M, and the third redundancy subpixel SPc_R included in each of the two pixels P(1,2) and P(2,2) arranged in the second column (or the second pixel column) can include a third redundancy light emitting device EDc_R.

The third main column line CLc_M arranged in the second column (or the second pixel column) can be commonly connected to the first electrodes Ecl of the two third main light emitting devices EDc_M arranged in the second column (or the second pixel column).

The third redundancy column line CLc_R arranged in the second column (or the second pixel column) can be commonly connected to the first electrodes Ecl of two third redundancy light emitting devices EDc_R arranged in the second column (or the second pixel column).

In each of the first column (or the first pixel column) and the second column (or the second pixel column), each of the plurality of column lines CL can include at least one column connection electrode having a shape protruding above a bank BNK. For example, the at least one column connection electrode can be an electrode electrically connected to each of the plurality of column lines CL or a portion protruding from each of the plurality of column lines CL.

Each of the first main column line CLa_M, the second main column line CLb_M, and the third main column line CLc_M can include a main column connection electrode CCE_M that protrudes above the bank BNK and extends above the bank BNK.

The first main light emitting devices EDa_M, the second main light emitting devices EDb_M, and the third main light emitting devices EDc_M can be arranged on the main column connection electrodes CCE_M arranged to extend above the bank BNK.

In each of the first column (or first pixel column) and the second column (or second pixel column), each of the first redundancy column line CLa_R, the second redundancy column line CLb_R, and the third redundancy column line CLc_R can include a redundancy column connection electrode CCE_R that protrudes above the bank BNK and extends above the bank BNK.

On the redundancy column connection electrodes CCE_R arranged to extend above the bank BNK, the first redundancy light emitting devices EDa_R, the second redundancy light emitting devices EDb_R, and the third redundancy light emitting devices EDc_R can be arranged.

The main column connection electrodes CCE_M and the redundancy column connection electrodes CCE_R arranged in the first column (or the first pixel column) can be disposed between the first main column line CLa_M and the first redundancy column line CLa_R.

The main column connection electrodes CCE_M and the redundancy column connection electrodes CCE_R arranged in the second column (or the second pixel column) can be disposed between the second main column line CLb_M and the second redundancy column line CLb_R.

The main column connection electrodes CCE_M and the redundancy column connection electrodes CCE_R arranged in the third column (or the third pixel column) can be disposed between the third main column line CLc_M and the third redundancy column line CLc_R.

The display panel 110 according to the embodiments of the present disclosure can further include at least one row connection electrode for electrically connecting each of the plurality of row lines RL to the driver DRV.

The display panel 110 according to the embodiments of the present disclosure can further include at least one first row connection electrode RCE(1) connected to a first row line RL(1) arranged in a first row (or a first pixel row), and at least one second row connection electrode RCE(2) connected to a second row line RL(2) arranged in a second row (or a second pixel row).

The first row line RL(1) can be vertically overlapped with at least one first row connection electrode RCE(1), and the second row line RL(2) can be vertically overlapped with at least one second row connection electrode RCE(2).

The first row line RL(1) can be electrically connected to the row driver R-DRV of the corresponding driver DRV through at least one first row connection electrode RCE(1). The second row line RL(2) can be electrically connected to the row driver R-DRV of the corresponding driver DRV through at least one second row connection electrode RCE(2).

According to embodiments of the present disclosure, a bank BNK can be arranged in each of a plurality of subpixels SP. The plurality of banks BNK can be structures on which a plurality of light emitting devices ED are mounted. When manufacturing a panel, in a transfer process for transferring a plurality of light emitting devices ED to a display device 100, a plurality of banks BNK can guide the positions of the plurality of light emitting devices ED. For example, when manufacturing a panel, a plurality of light emitting devices ED can be transferred onto a plurality of banks BNK in a transfer process of the plurality of light emitting devices ED. The plurality of banks BNK can be an organic insulating layer, a bank pattern, or a structure, but the embodiments of the present disclosure are not limited thereto.

The banks BNK of each of the plurality of subpixels SP can be arranged to be spaced apart from each other. The banks BNK of each of the plurality of subpixels SP can be configured to be separated from each other. Accordingly, the banks BNK of the first subpixel SPa, the second subpixel SPb, and the third subpixel SPc to which different types of light emitting devices ED are transferred can be easily identified.

The bank BNK of the first main subpixel SPa_M and the bank BNK of the first redundancy subpixel SPa_R can be connected to each other, or can be formed spaced apart from each other or separately. For example, considering the design of the transfer process requirements, the bank BNK of the first main subpixel SPa_M and the bank BNK of the first redundancy subpixel SPa_R, in which light emitting devices EDa_M, EDa_R of the same type (for example, types that emit the same color light) are arranged, can be connected to each other, or can be formed spaced apart from each other or separately. In addition, the bank BNK of the second main subpixel SPb_M and the bank BNK of the second redundancy subpixel SPb_R can be connected to each other, or can be formed spaced apart from each other or separately. The bank BNK of the third main subpixel SPc_M and the bank BNK of the third redundancy subpixel SPc_R can be connected to each other, or can be formed to be spaced apart from each other or separated from each other.

The bank BNK of the first main subpixel SPa_M and the first redundancy subpixel SPa_R, the bank BNK of the second main subpixel SPb_M and the second redundancy subpixel SPb_R, and the bank BNK of the third main subpixel SPc_M and the third redundancy subpixel SPc_R can be formed in various ways, and the embodiments of the present disclosure are not limited thereto.

For example, the plurality of banks BNK can be formed of an organic insulating material. The plurality of banks BNK can be formed of a single layer or multiple layers of an organic insulating material. For example, the plurality of banks BNK can be composed of a photo resist, a polyimide (PI), or an acrylic material, but the embodiments of the present disclosure are not limited thereto.

The plurality of row lines RL can be formed of a transparent conductive material, but the embodiments of the present disclosure are not limited thereto. The plurality of row lines RL can be composed of a transparent conductive material so that light emitted from the light emitting devices ED can be directed upward through the row lines RL. For example, the plurality of row lines RL can be composed of a transparent conductive material such as indium tin oxide (ITO), indium zinc oxide (IZO), indium gallium zinc oxide (IGZO), and the like, but the embodiments of the present disclosure are not limited thereto.

The plurality of column lines CL can be made of a conductive material. For example, the plurality of column lines CL can be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), but the embodiments of the present disclosure are not limited thereto. For another example, the plurality of column lines CL can have a multilayer structure of conductive materials. For example, the plurality of column lines CL can be made of a multilayer structure of titanium (Ti)/aluminum (Al)/titanium (Ti)/indium tin oxide (ITO), but the embodiments of the present disclosure are not limited thereto.

For example, if the light emitting device ED is a device manufactured through a semiconductor process, such as a micro LED, a plurality of light emitting devices ED can be formed on a wafer and the light emitting devices ED can be transferred to a substrate 210 of the display panel 110 to manufacture the display panel 110. In the process of transferring a plurality of light emitting devices ED having a microscopic size from the wafer to the substrate 210, various defects can occur. For example, a non-transfer defect can occur in which the light emitting device ED is not transferred in some subpixels SP, and a misalignment defect can occur in which the light emitting device ED is transferred out of its proper position due to an alignment error in other subpixels SP. In addition, the transfer process can proceed normally, but the transferred light emitting device ED itself can have a defect. Therefore, considering the defects (including non-transfer defects) that occur during the transfer process of the light emitting devices EDs, the main light emitting device and the redundancy light emitting device, which are light emitting devices of the same type (e.g., light emitting devices that emit light of the same color), can be transferred to one subpixel SP. A lighting test can be performed on the main light emitting device and the redundancy light emitting device of the same type, and it is possible to utilize only one of the main light emitting device and the redundancy light emitting device that is finally determined to be normal.

For example, the first main light emitting device EDa_M and the first redundancy light emitting device EDa_R can be transferred together to one first subpixel SPa, and the first main light emitting device EDa_M and the first redundancy light emitting device EDa_R can be inspected for defects. If, as a result of the inspection, both the first main light emitting device EDa_M and the first redundancy light emitting device EDa_R are determined to be normal, only the first main light emitting device EDa_M can be used, and the first redundancy light emitting device EDa_R can be not used. If, as a result of the inspection, only the first redundancy light emitting device EDa_R among the first main light emitting device EDa_M and the first redundancy light emitting device EDa_R is normal, the first main light emitting device EDa_M is not used, and only the first redundancy light emitting device EDa_R can be used. Accordingly, even if the same first main light emitting device EDa_M and the first redundancy light emitting device EDa_R are transferred to one first subpixel SPa, only one of the first main light emitting device EDa_M and the first redundancy light emitting device EDa_R can be used finally.

Accordingly, among the main light emitting device and the redundancy light emitting device arranged in one subpixel SP, the redundancy light emitting device can be a spare light emitting device transferred in preparation for a failure of the main light emitting device. In the event of a failure of the main light emitting device, the redundancy light emitting device can be used as a replacement. Therefore, by transferring the main light emitting device and the redundancy light emitting device together to one subpixel SP, it is possible to minimize the deterioration of display quality due to a defect in one of the main light emitting device and the redundancy light emitting device.

In the embodiments of the present disclosure, the first main subpixel SPa_M and the first redundancy subpixel SPa_R can also be referred to as a 1-1 subpixel and a 1-2 subpixel, respectively, the second main subpixel SPb_M and the second redundancy subpixel SPb_R can also be referred to as a 2-1 subpixel and a 2-2 subpixel, respectively, and the third main subpixel SPc_M and the third redundancy subpixel SPc_R can also be referred to as a 3-1 subpixel and a 3-2 subpixel, respectively.

In the embodiments of the present disclosure, the first main light emitting device EDa_M and the first redundancy light emitting device EDa_R can also be referred to as a 1-1 light emitting device and a 1-2 light emitting device, the second main light emitting device EDb_M and the second redundancy light emitting device EDb_R can also be referred to as a 2-1 light emitting device and a 2-2 light emitting device, and the third main light emitting device EDc_M and the third redundancy light emitting device EDc_R can also be referred to as a 3-1 light emitting device and a 3-2 light emitting device.

The display panel 110 according to the embodiments of the present disclosure can further include a plurality of communication lines NL. The plurality of communication lines NL can be arranged so as not to overlap with the metal layer in a vertical direction. For example, a plurality of communication lines NL can be arranged between a first row line RL(1) and a second row line RL(2).

For example, the plurality of communication lines NL can be wires for short-range communication such as NFC (Near Field Communication) and Bluetooth. The plurality of communication lines NL can serve as signal transmission wires and/or antennas, but the embodiments of the present disclosure are not limited thereto.

Referring to FIG. 13, the first row line RL(1) can be arranged above a plurality of light emitting devices arranged in the first row (or the first pixel row) and can be arranged in a bar shape overlapping with all of the plurality of light emitting devices arranged in the first row (or the first pixel row).

The second row line RL(2) can be arranged above the plurality of light emitting devices arranged in the second row (or the second pixel row), and can be arranged in a bar shape overlapping with all of the plurality of light emitting devices arranged in the second row (or the second pixel row).

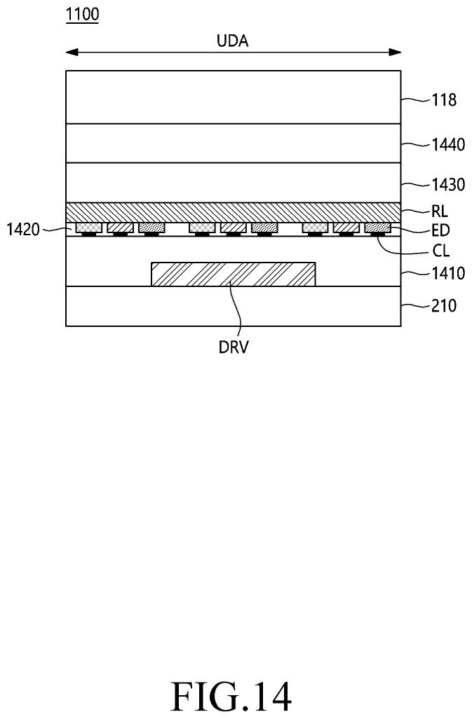

FIG. 14 is a cross-sectional view of a display panel 110 according to embodiments of the present disclosure. However, FIG. 14 is a cross-sectional view of a portion of a unit driving area UDA in which one driver DRV is arranged.

Referring to FIG. 14, a display panel 110 according to embodiments of the present disclosure can include a substrate 210, a driver DRV on the substrate 210, a layer stack 1410 on the driver DRV, a plurality of light emitting devices ED disposed on the layer stack 1410, an optical layer 1420 disposed on the layer stack 1410 and between the plurality of light emitting devices ED, an overcoat layer 1430 disposed on the plurality of light emitting devices ED and the optical layer 1420, an adhesive layer 1440 disposed on the overcoat layer 1430, and a cover member 118 disposed on the adhesive layer 1440.

A plurality of column lines CL can be arranged on a layer stack 1410. Each of the plurality of column lines CL can be arranged between the layer stack 1410 and a light emitting device ED. A plurality of row lines RL can be arranged on a plurality of light emitting devices ED and an optical layer 1420.

The display panel 110 according to embodiments of the present disclosure can include a substrate 210 including a display area DA, a plurality of light emitting devices ED arranged in the display area DA, a plurality of column lines CL electrically connected to first electrodes Ecl of each of the plurality of light emitting devices ED, a plurality of row lines RL electrically connected to second electrodes Erl of each of the plurality of light emitting devices ED, and a plurality of drivers DRV configured to drive the plurality of light emitting devices ED, the plurality of column lines CL, and the plurality of row lines RL.

A plurality of drivers DRV can be arranged in the display area DA, and can be positioned closer to the substrate 210 than the plurality of light emitting devices ED.

The layer stack 1410 can include a plurality of insulating layers. The plurality of insulating layers can include a plurality of organic layers. At least one of the plurality of organic layers can be arranged on a side of the driver DRV. For example, two or more organic layers can be arranged on a side of the driver DRV.

The layer stack 1410 can further include at least one metal layer connecting the driver DRV and the column line CL, and at least one metal layer connecting the driver DRV and the row line RL.

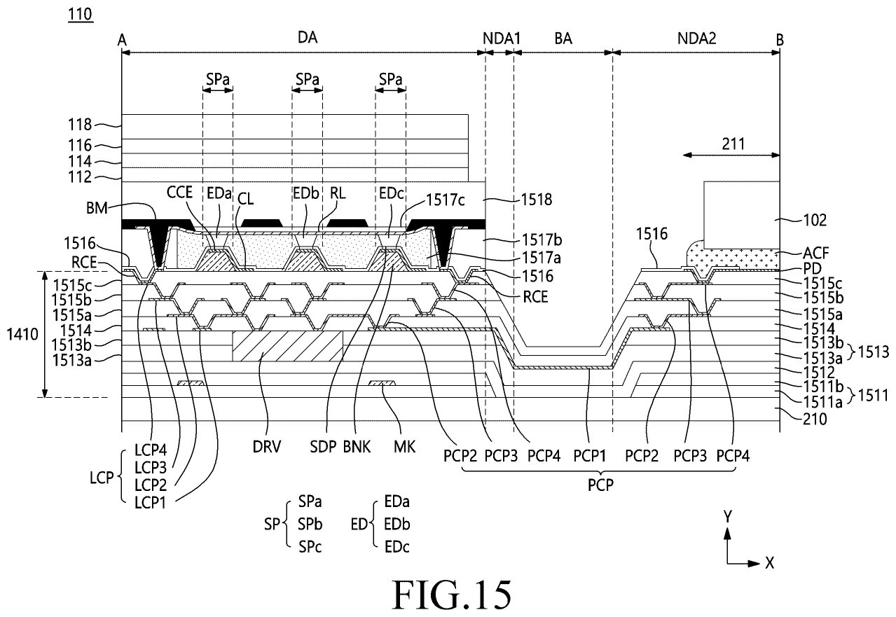

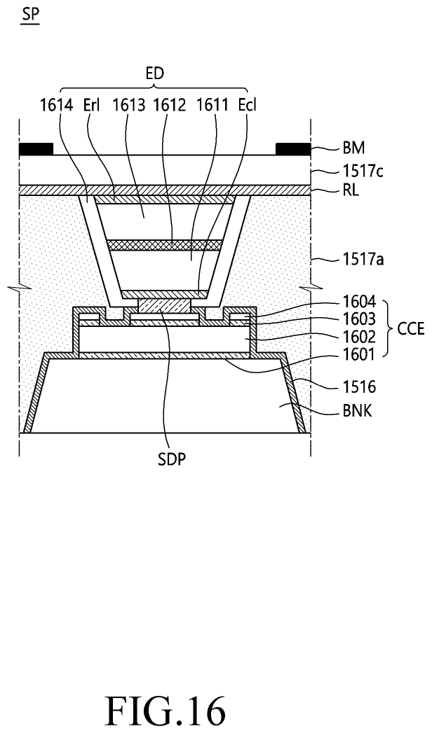

FIG. 15 is a detailed cross-sectional view of a display panel 110 according to embodiments of the present disclosure taken along the A-B cutting line of FIG. 10, and FIG. 16 is an enlarged cross-sectional view of a subpixel SP of a display panel 110 according to embodiments of the present disclosure. However, FIG. 15 is a cross-sectional view of a display area DA, a first non-display area NDA1, a bending area BA, and a second non-display area NDA2.

Meanwhile, for convenience of illustration, the A-B cutting line in FIG. 10 is illustrated as not overlapping with a signal line SL and a link line LL, but the A-B cutting line in FIG. 10 is intended to indicate the same position as the adjacent signal line SL and the link line LL.

Referring to FIG. 15, a buffer layer 1511 can be included on the substrate 210. The buffer layer 1511 can include a first buffer layer 1511a and a second buffer layer 1511b. The first buffer layer 1511a and the second buffer layer 1511b can be arranged in the display area DA, the first non-display area NDA1, and the second non-display area NDA2, and may not be arranged in the entirety or part of the bending area BA. However, the present disclosure is not limited thereto.

The first buffer layer 1511a and the second buffer layer 1511b can reduce the penetration of moisture or impurities through the substrate 210. The first buffer layer 1511a and the second buffer layer 1511b can be made of an inorganic insulating material. For example, the first buffer layer 1511a and the second buffer layer 1511b can be composed of a single layer or multiple layers of silicon oxide (SiOx) or silicon nitride (SiNx), but the embodiments of the present disclosure are not limited thereto.

For example, a portion of the first buffer layer 1511a and the second buffer layer 1511b on the bending area BA can be removed. The upper surface of the substrate 210 located on the bending area BA can be exposed by the area (e.g., opening) where the first buffer layer 1511a and the second buffer layer 1511b are removed.

By removing the first buffer layer 1511a and the second buffer layer 1511b from the bending area BA, it is possible to minimize an occurrence of cracks in the first buffer layer 1511a and the second buffer layer 1511b that can occur during bending.

A plurality of alignment keys MK can be arranged between the first buffer layer 1511a and the second buffer layer 1511b. The plurality of alignment keys MK can be configured to identify the position of the driver DRV during the manufacturing process of the display panel 110. For example, the plurality of alignment keys MK can be configured to align the position of the driver DRV transferred on the adhesive layer 1512. In another example, the plurality of alignment keys MK can be omitted.

An adhesive layer 1512 can be disposed on the second buffer layer 1511b. The adhesive layer 1512 can be disposed in the display area DA, the first non-display area NDA1, the bending area BA, and the second non-display area NDA2. For another example, at least a portion of the adhesive layer 1512 can be removed in the non-display area NDA including the bending area BA. For example, the adhesive layer 1512 can be made of any one of an adhesive polymer, an epoxy resin, a UV-curable resin, a polyimide series, an acrylate series, a urethane series, and a polydimethylsiloxane (PDMS), but the embodiments of the present disclosure are not limited thereto.

A driver DRV can be disposed on the adhesive layer 1512 in the display area DA. If the driver DRV is implemented as a driving chip (e.g., driver integrated circuit), the driver DRV can be mounted on the adhesive layer 1512 by a transfer process, but the embodiments of the present disclosure are not limited thereto.

The display panel 110 can further include a side protection layer 1513 disposed on the side of the plurality of drivers DRV, and an upper protection layer 1514 disposed on the plurality of drivers DRV and the side protection layer 1513. For example, the side protection layer 1513 can include at least one of a first protection layer 1513a and a second protection layer 1513b disposed on the side of the plurality of drivers DRV, and in some cases, can further include at least one additional protection layer. The first protection layer 1513a and the second protection layer 1513b can be disposed on the adhesive layer 1512. The first protection layer 1513a and the second protection layer 1513b can be arranged to surround the side surface of the driver DRV, but the embodiments of the present disclosure are not limited thereto. For example, the second protection layer 1513b can be arranged to cover at least a portion of the upper surface of the driver DRV. For example, at least one of the first protection layer 1513a and the second protection layer 1513b arranged on the bending area BA can be omitted. For example, the first protection layer 1513a can be arranged entirely on the display area DA and the non-display area NDA, and the second protection layer 1513b can be partially arranged on the display area DA, the first non-display area NDA1, and the second non-display area NDA2. For example, at least a portion of the second protection layer 1513b can be removed in all or part of the bending area BA. However, the embodiments of the present disclosure are not limited thereto.

For example, the side protection layer 1513 including at least one of the first protection layer 1513a and the second protection layer 1513b can be composed of an organic insulating material (i.e., organic layer), but the embodiments of the present disclosure are not limited thereto. For example, the first protection layer 1513a and the second protection layer 1513b can be composed of a photo resist, a polyimide (PI), or a photo acryl-based material, but the embodiments of the present disclosure are not limited thereto. For example, the first protection layer 1513a and the second protection layer 1513b can be an overcoating layer or an insulating layer, but the embodiments of the present disclosure are not limited thereto.

According to embodiments of the present disclosure, in the display area DA, a plurality of line connection patterns LCP can be arranged on the second protection layer 1513b. The plurality of line connection patterns LCP can be wiring for electrically connecting the driver DRV to other components. For example, the driver DRV can be electrically connected to a plurality of column lines CL, a plurality of row lines RL, and a plurality of row connection electrodes RCE through the plurality of line connection patterns LCP.

For example, the plurality of line connection patterns LCP can include a first line connection pattern LCP1, a second line connection pattern LCP2, a third line connection pattern LCP3, and a fourth line connection pattern LCP4, but the embodiments of the present disclosure are not limited thereto. For example, the first line connection pattern LCP1, the second line connection pattern LCP2, the third line connection pattern LCP3, and the fourth line connection pattern LCP4 can be arranged in different metal layers.

For example, a plurality of first line connection patterns LCP1 can be arranged on the second protection layer 1513b. The plurality of first line connection patterns LCP1 can be electrically connected to the driver DRV. The plurality of first line connection patterns LCP1 can transmit the voltage output from the driver DRV to the column line CL or the row line RL.

The display panel 110 can further include a side protection layer 1513 including at least one of the first protection layer 1513a and the second protection layer 1513b, and an upper protection layer 1514 arranged on the plurality of drivers DRV. For example, the upper protection layer 1514 can include a third protection layer 1514, and in some cases, can further include at least one additional protection layer. The third protection layer 1514 can be disposed on the second protection layer 1513b and the plurality of first line connection patterns LCP1. The third protection layer 1514 can be disposed entirely in the display area DA and the non-display area NDA. In the bending area BA, the third protection layer 1514 can cover or enclose the side surface of the second protection layer 1513b and the upper surface of the first protection layer 1513a.

For example, the third protection layer 1514 can be composed of an organic insulating material. For example, the third protection layer 1514 can be composed of a photo resist, a polyimide (PI), or a photo acryl-based material, but the embodiments of the present disclosure are not limited thereto. For example, the first protection layer 1513a, the second protection layer 1513b, and the third protection layer 1514 can be composed of the same insulating material, or at least one of the first protection layer 1513a, the second protection layer 1513b, and the third protection layer 1514 can be composed of a different insulating material from the rest. However, the embodiments of the present disclosure are not limited thereto.

A plurality of second line connection patterns LCP2 can be arranged on the third protection layer 1514. The plurality of second line connection patterns LCP2 can be electrically connected or directly connected to the driver DRV. For example, some of the second line connection patterns LCP2 can be directly or indirectly connected to the driver DRV through contact holes of the third protection layer 1514. Other parts of the second line connection patterns LCP2 can be electrically connected to the first line connection pattern LCP1 through contact holes of the third protection layer 1514. However, the embodiments of the present disclosure are not limited thereto. The voltage output from the driver DRV can be transmitted to the column line CL or the row line RL through the plurality of second line connection patterns LCP2 and other connection patterns.

A first insulating layer 1515a can be disposed on the plurality of second line connection patterns LCP2. The first insulating layer 1515a can be disposed entirely over the display area DA and the non-display area NDA, but the embodiments of the present disclosure are not limited thereto. The first insulating layer 1515a can be composed of an organic insulating material, but the embodiments of the present disclosure are not limited thereto. For example, the first insulating layer 1515a can be composed of a photo resist, a polyimide (PI), or a photo acryl-based material, but the embodiments of the present disclosure are not limited thereto.

A plurality of third line connection patterns LCP3 can be disposed on the first insulating layer 1515a. The plurality of third line connection patterns LCP3 can be electrically connected to the plurality of second line connection patterns LCP2. For example, the third line connection pattern LCP3 can be electrically connected to the second line connection pattern LCP2 through a contact hole of the first insulating layer 1515a.

A second insulating layer 1515b can be disposed on a plurality of third line connection patterns LCP3. The second insulating layer 1515b can be disposed in the display area DA, the first non-display area NDA1, and the second non-display area NDA2, and may not be disposed in the entirety or part of the bending area BA, but the embodiments of the present disclosure are not limited thereto. For example, the second insulating layer 1515b can be removed from the entirety or part of the bending area BA. The second insulating layer 1515b can be composed of an organic insulating material, but the embodiments of the present disclosure are not limited thereto. For example, the second insulating layer 1515b can be composed of a photo resist, a polyimide (PI), or a photo acryl-based material, but the embodiments of the present disclosure are not limited thereto.

A plurality of fourth line connection patterns LCP4 can be arranged on the second insulating layer 1515b. The plurality of fourth line connection patterns LCP4 can be electrically connected to a plurality of third line connection patterns LCP3. For example, the fourth line connection patterns LCP4 can be electrically connected to the third line connection patterns LCP3 through a contact hole of the second insulating layer 1515b.

According to the embodiments of the present disclosure, in the non-display area NDA, a plurality of pad connection patterns PCP can be arranged on the second protection layer 1513b. A plurality of pad connection patterns PCPs can be wiring for transmitting a signal transmitted from a flexible printed circuit 102 to a pad section 211 to a driver DRV of a display area DA. For example, a plurality of pad connection patterns PCP can be electrically connected to a plurality of pads PDs and can receive signals from the flexible printed circuit 102 through the plurality of pads PDs. The flexible printed circuit 102 can be connected to a printed circuit board 104 (see FIGS. 1 and 2).

For example, a plurality of pad connection patterns PCP can extend from the pad section 211 toward the display area DA and transmit signals to the wiring of the display area DA. In this case, a plurality of pad connection patterns PCP can function as link wiring LL (see FIG. 10). The plurality of pad connection patterns PCP can include a first pad connection pattern PCP1, a second pad connection pattern PCP2, a third pad connection pattern PCP3, and a fourth pad connection pattern PCP4.

The plurality of first pad connection patterns PCP1 can be arranged on the second protection layer 1513b. Each of the plurality of first pad connection patterns PCP1 can be arranged across the second non-display area NDA2, the bending area BA, and the first non-display area NDA1. Each of the plurality of first pad connection patterns PCP1 can include a first portion arranged in the bending area BA, a second portion extending from the first portion to the first non-display area NDA1, and a third portion extending from the first portion to the second non-display area NDA2. Each of the plurality of first pad connection patterns PCP1 can further extend from the first non-display area NDA1 to a portion of the display area DA. The plurality of first pad connection patterns PCP1 can transmit a signal transmitted from the flexible printed circuit 102 to the pad portion 211 to the driver DRV of the display area DA.

Each of the plurality of first pad connection patterns PCP1 can be electrically connected to the pad PD of the pad section 211 through connection patterns arranged in the second non-display area NDA2. Here, the connection patterns electrically connecting each of the plurality of first pad connection patterns PCP1 to the pad PD can include at least one of the second pad connection pattern PCP2, the third pad connection pattern PCP3, and the fourth pad connection pattern PCP4 arranged in the second non-display area NDA2.

Each of the plurality of first pad connection patterns PCP1 can be electrically connected to the driver DRV through connection patterns arranged in the display area DA. Here, the connection patterns electrically connecting each of the plurality of first pad connection patterns PCP1 to the driver DRV can include at least one of the second pad connection pattern PCP2, the third pad connection pattern PCP3, and the fourth pad connection pattern PCP4 arranged in the display area DA.

The plurality of second pad connection patterns PCP2 can be arranged on the third protection layer 1514. The plurality of second pad connection patterns PCP2 can be arranged in the second non-display area NDA2. The second pad connection pattern PCP2 can be electrically connected to the first pad connection pattern PCP1 through a contact hole of the third protection layer 1514. Therefore, the signal supplied from the flexible printed circuit 102 can be transmitted to the first pad connection pattern PCP1 through the second pad connection pattern PCP.

The third pad connection pattern PCP3 can be arranged on the first insulating layer 1515a. The third pad connection pattern PCP3 can be arranged in the second non-display area NDA2. The third pad connection pattern PCP3 can be electrically connected to the second pad connection pattern PCP2 through a contact hole of the first insulating layer 1515a. Therefore, the signal supplied from the flexible printed circuit 102 can be transmitted to the second pad connection pattern PCP2 through the third pad connection pattern PCP3, and the signal transmitted to the second pad connection pattern PCP2 can be transmitted again to the first pad connection pattern PCP1.

The fourth pad connection pattern PCP4 can be arranged on the second insulating layer 1515b. The fourth pad connection pattern PCP4 can be arranged in the second non-display area NDA2. The fourth pad connection pattern PCP4 can be electrically connected to the third pad connection pattern PCP3 through a contact hole of the second insulating layer 1515b. The pad PD of the pad section 211 can be electrically connected to the fourth pad connection pattern PCP4 through a contact hole of the third insulating layer 1515c.

A signal supplied from a flexible printed circuit 102 is input to a pad PD of a pad section 211, and a signal input to the pad PD is transmitted to a third pad connection pattern PCP3 through a fourth pad connection pattern PCP4, and a signal transmitted to the third pad connection pattern PCP3 can be transmitted again to a first pad connection pattern PCP1 through a second pad connection pattern PCP2. A signal transmitted to the first pad connection pattern PCP1 can be transmitted to a driver DRV through connection patterns arranged in a display area DA.

Referring to FIG. 15, a plurality of line connection patterns LCP and a plurality of pad connection patterns PCP can be arranged in various metal layers. The plurality of line connection patterns LCP and the plurality of pad connection patterns PCP can be formed of any one of a conductive material having excellent ductility or various conductive materials used in a display area DA.

For example, a metal pattern such as a first pad connection pattern PCP1 at least partially disposed in the bending area BA can be composed of a conductive material having excellent ductility, such as gold (Au), silver (Ag), or aluminum (Al), but the embodiments of the present disclosure are not limited thereto. For another example, the plurality of line connection patterns LCP and the plurality of pad connection patterns PCP can be composed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto.

A third insulating layer 1515c can be disposed on the plurality of line connection patterns LCP and the plurality of pad connection patterns PCP. The third insulating layer 1515c is disposed in the display area DA, the first non-display area NDA1, and the second non-display area NDA2, and can be disposed in all or part of the bending area BA, but the embodiments of the present disclosure are not limited thereto. In the bending area BA, a part of the third insulating layer 1515c can be removed. The third insulating layer 1515c can be composed of an organic insulating material, but the embodiments of the present disclosure are not limited thereto. For example, the third insulating layer 1515c can be composed of a photo resist, a polyimide (PI), or a photo acryl-based material, but the embodiments of the present disclosure are not limited thereto.

A plurality of banks BNK can be disposed on the third insulating layer 1515c in the display area DA. The plurality of banks BNKs can be arranged to overlap with at least a portion of each of the plurality of subpixels SPa, SPb and SPc. For example, the first subpixel SPa can include a first light emitting device EDa that emits a first color light, the second subpixel SPb can include a second light emitting device EDb that emits a second color light, and the third subpixel SPc can include a third light emitting device EDc that emits a third color light.

As an example, one light emitting device ED can be arranged on top of each of the plurality of banks BNKs. As another example, two or more light emitting devices ED can be arranged on top of each of the plurality of banks BNK. The two or more light emitting devices EDs arranged on top of each of the plurality of banks BNK can be light emitting devices of the same type. For example, the light emitting devices of the same type can be light emitting devices that emit the same color light. For example, the two or more light emitting devices ED arranged on top of each of the plurality of banks BNK can include a main light emitting device and a redundancy light emitting device.

In the display area DA, a plurality of row connection electrodes RCE can be arranged on the third insulating layer 1515c. The plurality of row connection electrodes RCE can transfer a low-potential voltage VSS output from the driver DRV to the row line RL.

In the display area DA, a plurality of column lines CL can be arranged on the third insulating layer 1515c. The plurality of column lines CL can be arranged in an area between the plurality of banks BNK. For example, the plurality of column lines CL can be arranged adjacent to one of the plurality of banks BNK.

Each of the plurality of column lines CL can include a wiring portion and a column connection electrode CCE protruding from the wiring portion. The wiring portion and the column connection electrode CCE included in each of the plurality of column lines CL can be formed integrally or can be different metals that are electrically connected.

For example, each of the plurality of column lines CL can include a column connection electrode CCE that is a portion protruding above an adjacent bank BNK among the plurality of banks BNK. The column connection electrode CCE of each of the plurality of column lines CL can be arranged to extend along the side and upper surface of the bank BNK. The column connection electrode CCE can be an electrode electrically connected to each of the plurality of column lines CL or can be a portion protruding from each of the plurality of column lines CL.

Referring to FIG. 16, the column connection electrode CCE of the column line CL can be composed of one conductive layer or multiple conductive layers. For example, a column connection electrode CCE electrically connected to a column line CL or protruding from the column line CL can include a first conductive layer 1601, a second conductive layer 1602, a third conductive layer 1603, and a fourth conductive layer 1604, but the embodiments of the present disclosure are not limited thereto.

The first conductive layer 1601 can be disposed on a bank BNK. The second conductive layer 1602 can be disposed on the first conductive layer 1601. The third conductive layer 1603 can be disposed on the second conductive layer 1602, and the fourth conductive layer 1604 can be disposed on the third conductive layer 1603. For example, each of the first conductive layer 1601, the second conductive layer 1602, the third conductive layer 1603, and the fourth conductive layer 1604 can be composed of titanium (Ti), molybdenum (Mo), aluminum (Al), or titanium (Ti) and indium tin oxide (ITO), but the embodiments of the present disclosure are not limited thereto.

According to the embodiments of the present disclosure, among the plurality of conductive layers constituting the column connection electrode CCE, some conductive layers having good reflection efficiency can be configured as an alignment key and/or a reflector for aligning the light emitting devices ED. For example, among the plurality of conductive layers constituting the column connection electrode CCE, the second conductive layer 1602 can include a reflective material. For example, the second conductive layer 1602 can include aluminum (Al), but the embodiments of the present disclosure are not limited thereto. Accordingly, the second conductive layer 1602 can be configured as a reflector. In addition, due to the high reflection efficiency of the second conductive layer 1602, it can be easily identified in the manufacturing process, and thus the position or transfer position of the light emitting device ED can be aligned based on the second conductive layer 1602.

For example, in order to configure the second conductive layer 1602 as a reflector, the third conductive layer 1603 and the fourth conductive layer 1604 disposed on the second conductive layer 1602 can be partially removed or etched. For example, a portion of the third conductive layer 1603 and the fourth conductive layer 1604 disposed on the bank BNK can be removed or etched to expose the upper surface of the second conductive layer 1602. For example, the openings of the third conductive layer 1603 and the fourth conductive layer 1604 can overlap with a portion of the upper surface of the second conductive layer 1602. For example, in the third conductive layer 1603 and the fourth conductive layer 1604, the central portion and the edge portion where a solder pattern SDP is arranged can remain, and the remaining portions excluding this portion (e.g., the central portion, the edge portion) can be removed. For example, the edge portion of each of the third conductive layer 1603 made of titanium (Ti) and the fourth conductive layer 1604 made of indium tin oxide (ITO) may not be etched. Accordingly, it is possible to prevent other conductive layers of the column connection electrode CCE of the column line CL from being corroded by the TMAH (Tetra Methyl Ammonium Hydroxide) solution used in the mask process of the column connection electrode CCE.

According to the embodiments of the present disclosure, the first conductive layer 1601 and the third conductive layer 1603 can include titanium (Ti) or molybdenum (Mo). The second conductive layer 1602 can include aluminum (Al). The fourth conductive layer 1604 can include a transparent conductive oxide layer such as indium tin oxide (ITO) or indium zinc oxide (IZO) that has good adhesion to the solder pattern SDP and corrosion resistance and acid resistance. However, the embodiments of the present disclosure are not limited thereto.

The first conductive layer 1601, the second conductive layer 1602, the third conductive layer 1603, and the fourth conductive layer 1604 can be sequentially deposited and then patterned by performing a photolithography process and an etching process, but the embodiments of the present disclosure are not limited thereto.

According to embodiments of the present disclosure, two or more of the column connection electrode CCE, the column line CL, the row connection electrode RCE, and the pad PD can be arranged on the same layer. The column connection electrode CCE, the column line CL, the row connection electrode RCE, and the pad PD can be composed of a single layer or multiple layers of a conductive material, but the embodiments of the present disclosure are not limited thereto. For example, two or more of the column connection electrode CCE, the column line CL, the row connection electrode RCE, and the pad PD can be composed of a multiple layer of indium tin oxide (ITO)/titanium (Ti)/aluminum (Al)/titanium (Ti), but the embodiments of the present disclosure are not limited thereto.

According to embodiments of the present disclosure, a solder pattern SDP can be arranged on the column connection electrode CCE in each of a plurality of subpixels. The solder pattern SDP can bond the light emitting device ED to the column connection electrode CCE. The column connection electrode CCE and the light emitting device ED can be electrically connected through eutectic bonding using the solder pattern SDP, but the embodiments of the present disclosure are not limited thereto. For example, if the solder pattern SDP is composed of indium (In) and the first electrode Ecl of the light emitting device ED is composed of gold (Au), the solder pattern SDP and the first electrode Ecl of the light emitting device ED can be bonded by applying heat and pressure in a transfer process of the light emitting device ED. Through eutectic bonding, the light emitting device ED can be bonded to the solder pattern SDP and the column connection electrode CCE without a separate adhesive. For example, the solder pattern SDP can be composed of indium (In), tin (Sn), or an alloy thereof, but the embodiments of the present disclosure are not limited thereto. For example, the solder pattern SDP can be a bonding pad, but the embodiments of the present disclosure are not limited thereto.

According to the embodiments of the present disclosure, the passivation layer 1516 can be disposed on a plurality of column lines CL, a plurality of column connection electrodes CCE, a plurality of row connection electrodes RCE, and a third insulating layer 1515c.

For example, the passivation layer 1516 can be disposed on a display area DA, a first non-display area NDA1, and a second non-display area NDA2. In the entirety or a portion of the bending area BA, at least a portion of the passivation layer 1516 can be removed. A portion of the passivation layer 1516 covering the plurality of pads PD in the second non-display area NDA2 can be removed. In addition, as illustrated in FIG. 16, the passivation layer 1516 can be removed from the area where the solder pattern SDP is arranged.

Since the passivation layer 1516 is arranged to cover the remaining area except for the bending area BA, the plurality of pads PD, and the area where the solder pattern SDP is arranged, the penetration of moisture or impurities into the light emitting device ED can be reduced. For example, the passivation layer 1516 can be composed of a single layer or multiple layers of silicon oxide (SiOx) or silicon nitride (SiNx), but the embodiments of the present disclosure are not limited thereto. For example, the passivation layer 1516 can be a protection layer or an insulating layer, but the embodiments of the present disclosure are not limited thereto. For example, as illustrated in FIG. 16, the passivation layer 1516 can include a hole through which the solder pattern SDP is exposed. For example, the hole of the passivation layer 1516 can overlap with the solder pattern SDP.

Referring to FIG. 16, a light emitting device ED can be arranged on the solder pattern SDP in each of a plurality of subpixels SP. The light emitting device ED can be formed on a silicon wafer by a method such as Metal Organic Chemical Vapor Deposition (MOCVD), Chemical Vapor Deposition (CVD), Plasma-Enhanced Chemical Vapor Deposition (PDCVD), Molecular Beam Epitaxy (MBE), Hydride Vapor Phase Epitaxy (HVPD), or Sputtering, but the embodiments of the present disclosure are not limited thereto.

The light emitting device ED can include a first electrode Ecl, a first semiconductor layer 1611, an active layer 1612, a second semiconductor layer 1613, a second electrode Erl, and an encapsulation film 1614, but the embodiments of the present disclosure are not limited thereto. For example, the encapsulation film 1614 may not be included in the light emitting device ED.

The first semiconductor layer 1611 can be disposed on the solder pattern SDP. The second semiconductor layer 1613 can be disposed on the first semiconductor layer 1611.

For example, one of the first semiconductor layer 1611 and the second semiconductor layer 1613 can be implemented as a compound semiconductor of group III-V, group II-VI, and can be doped with an impurity (or dopant). For example, one of the first semiconductor layer 1611 and the second semiconductor layer 1613 can be a semiconductor layer doped with an n-type impurity, and the other can be a semiconductor layer doped with a p-type impurity, but the embodiments of the present disclosure are not limited thereto. For example, at least one of the first semiconductor layer 1611 and the second semiconductor layer 1613 can be a layer doped with an n-type or p-type impurity in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto. For example, the n-type impurity can be silicon (Si), germanium (Ge), selenium (Se), carbon (C), tellurium (Te), or tin (Sn), but the embodiments of the present disclosure are not limited thereto. For example, the p-type impurity can be magnesium (Mg), zinc (Zn), calcium (Ca), strontium (Sr), barium (Ba), or beryllium (Be), but the embodiments of the present disclosure are not limited thereto.

For example, the first semiconductor layer 1611 and the second semiconductor layer 1613 can be a nitride semiconductor including an n-type impurity and a nitride semiconductor including a p-type impurity, respectively, but the embodiments of the present disclosure are not limited thereto. For example, the first semiconductor layer 1611 can be a nitride semiconductor containing a p-type impurity, and the second semiconductor layer 1613 can be a nitride semiconductor containing an n-type impurity, but the embodiments of the present disclosure are not limited thereto.

The active layer 1612 can be arranged between the first semiconductor layer 1611 and the second semiconductor layer 1613. The active layer 1612 can receive holes and electrons from the first semiconductor layer 1611 and the second semiconductor layer 1613 to emit light. For example, the active layer 1612 can be configured as one of a single well structure, a multi-well structure, a single quantum well structure, a multi-quantum well (MQW) structure, a quantum dot structure, and a quantum wire structure, but the embodiments of the present disclosure are not limited thereto. For example, the active layer 1612 can be configured as indium gallium nitride (InGaN) or gallium nitride (GaN), but the embodiments of the present disclosure are not limited thereto.

For another example, the active layer 1612 can include a multi-quantum well (MQW) structure having a well layer and a barrier layer having a higher band gap than the well layer. For example, the active layer 1612 can be formed of InGaN layer as a well layer and an AlGaN layer as a barrier layer, but the embodiments of the present disclosure are not limited thereto.

The first electrode Ecl of the light emitting device ED can be arranged between the first semiconductor layer 1611 and the solder pattern SDP. For example, the first electrode Ecl of the light emitting device ED can electrically connect the first semiconductor layer 1611 and the column connection electrode CCE. The column line voltage (e.g., the anode voltage) output from the driver DRV can be applied to the first semiconductor layer 1611 through the column line CL, the column connection electrode CCE, and the first electrode Ecl. For example, the first electrode Ecl can be composed of a conductive material capable of eutectic bonding with the solder pattern SDP, but the embodiments of the present disclosure are not limited thereto. For example, the first electrode Ecl of the light emitting device ED can be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the embodiments of the present disclosure are not limited thereto.

The second electrode Erl of the light emitting device ED can be disposed on the second semiconductor layer 1613. For example, the second electrode Erl of the light emitting device ED can electrically connect the second semiconductor layer 1613 and the row line RL. A row line voltage (e.g., referred to as a low-potential voltage VSS as a cathode voltage) output from the driver DRV can be applied to the second semiconductor layer 1613 through the row connection electrode RCE, the row line RL, and the second electrode Erl. The second electrode Erl of the light emitting device ED can be made of a transparent conductive material so that light emitted from the light emitting device ED can be directed to the upper portion of the light emitting device ED, but the embodiments of the present disclosure are not limited thereto. For example, the second electrode Erl can be made of a material such as indium tin oxide (ITO), indium zinc oxide (IZO), or indium gallium zinc oxide (IGZO), but the embodiments of the present disclosure are not limited thereto.

The encapsulation film 1614 can be disposed on at least a portion of the first semiconductor layer 1611, the active layer 1612, the second semiconductor layer 1613, the first electrode Ecl, and the second electrode Erl. For example, the encapsulation film 1614 can surround at least a portion of the first semiconductor layer 1611, the active layer 1612, the second semiconductor layer 1613, the first electrode Ecl, and the second electrode Erl.

For example, the encapsulation film 1614 can protect the first semiconductor layer 1611, the active layer 1612, and the second semiconductor layer 1613. For example, the encapsulation film 1614 can be disposed on a side surface of the first semiconductor layer 1611, a side surface of the active layer 1612, and a side surface of the second semiconductor layer 1613.

For example, the encapsulation film 1614 can be disposed on at least a portion of the first electrode Ecl and the second electrode Erl of the light emitting device ED. For example, the encapsulation film 1614 can be disposed on an edge portion (or one side) of the first electrode Ecl of the light emitting device ED and an edge portion (or one side) of the second electrode Erl of the light emitting device ED. At least a portion of the first electrode Ecl can be exposed from the encapsulation film 1614 so that the first electrode Ecl can be connected to the solder pattern SDP. For example, at least a portion of the second electrode Erl can be exposed from the encapsulation film 1614 so that the second electrode Erl can be connected to the row line RL. For example, the encapsulation film 1614 can be made of an insulating material such as silicon nitride (SiNx) or silicon oxide (SiOx), but the embodiments of the present disclosure are not limited thereto.

For another example, the encapsulation film 1614 can have a structure in which a reflective material is dispersed in a resin layer, but the embodiments of the present disclosure are not limited thereto. For example, the encapsulation film 1614 can be manufactured as a reflector of various structures, but the embodiments of the present disclosure are not limited thereto. Light emitted from the active layer 1612 can be reflected upward by the encapsulation film 1614, thereby improving light extraction efficiency. For example, the encapsulation film 1614 can be a reflective layer, but the embodiments of the present disclosure are not limited thereto.

According to the embodiments of the present disclosure, the light emitting device ED is described as having a vertical structure, but the embodiments of the present disclosure are not limited thereto. For example, the light emitting device ED can have a lateral structure or a flip chip structure.

The structure of the light emitting device ED illustrated in FIG. 16 can be substantially equally applied to all of the first light emitting device EDa, the second light emitting device EDb, and the third light emitting device EDc. According to embodiments of the present disclosure, a first optical layer 1517a can be arranged to surround a plurality of light emitting devices ED in the display area DA. For example, the first optical layer 1517a can be arranged to cover a plurality of light emitting devices ED and the bank BNK in the area of a plurality of subpixels SP. For example, the first optical layer 1517a can cover a bank BNK, a portion of the passivation layer 1516, and a region between the plurality of light emitting devices ED. The first optical layer 1517a can be arranged or covered between a plurality of light emitting devices ED included in one pixel and between a plurality of banks BNK. For example, the first optical layer 1517a can be arranged to extend in the first direction (X) and be spaced apart from each other in the second direction (Y). For example, the first optical layer 1517a can be arranged to surround the side of the light emitting devices ED and the banks BNK between the passivation layer 1516 and the row line RL, but the embodiments of the present disclosure are not limited thereto. For example, the first optical layer 1517a can be a diffusion layer or a sidewall diffusion layer, but the embodiments of the present disclosure are not limited thereto.

The first optical layer 1517a can include an organic insulating material having fine particles dispersed therein, but the embodiments of the present disclosure are not limited thereto. For example, the first optical layer 1517a can be composed of siloxane having fine metal particles, such as titanium dioxide (TiO₂) particles, dispersed therein, but the embodiments of the present disclosure are not limited thereto. Light from a plurality of light emitting devices ED can be scattered by the fine particles dispersed in the first optical layer 1517a and emitted to the outside of the display device 100. Accordingly, the first optical layer 1517a can improve the extraction efficiency of light emitted from the plurality of light emitting devices ED.

For example, the first optical layer 1517a can be arranged on each of a plurality of pixels, or can be arranged together on some pixels arranged in the same row, but the embodiments of the present disclosure are not limited thereto. For example, the first optical layer 1517a can be arranged on each of a plurality of pixels, or the plurality of pixels can share one first optical layer 1517a. For another example, each of the plurality of subpixels can separately include a first optical layer 1517a, but the embodiments of the present disclosure are not limited thereto.

According to the embodiments of the present disclosure, in the display area DA, a second optical layer 1517b can be arranged on the passivation layer 1516. For example, the second optical layer 1517b can be arranged to surround the first optical layer 1517a. For example, the second optical layer 1517b can be in contact with a side surface of the first optical layer 1517a. For example, the second optical layer 1517b can be arranged in an area between the plurality of pixels. However, the embodiments of the present disclosure are not limited thereto. For example, the second optical layer 1517b can be a diffusion layer, a diffusion layer window, or a window diffusion layer, but the embodiments of the present disclosure are not limited thereto.

The second optical layer 1517b can be composed of an organic insulating material, but the embodiments of the present disclosure are not limited thereto. The second optical layer 1517b can be composed of the same material as the first optical layer 1517a, but the embodiments of the present disclosure are not limited thereto. For example, the first optical layer 1517a can include fine particles, and the second optical layer 1517b may not include fine particles. For example, the second optical layer 1517b can be composed of siloxane, but the embodiments of the present disclosure are not limited thereto.

For example, the thickness of the first optical layer 1517a can be smaller than the thickness of the second optical layer 1517b, but the embodiments of the present disclosure are not limited thereto. Accordingly, when viewed from a planar view, the area where the first optical layer 1517a is disposed can include a concave portion that is sunken inwardly from the upper surface of the second optical layer 1517b.

According to the embodiments of the present disclosure, a row line RL can be disposed on the first optical layer 1517a and the second optical layer 1517b. For example, the row line RL can be electrically connected to a plurality of row connection electrodes RCE through contact holes of the second optical layer 1517b. For example, the row line RL can be disposed on a plurality of light emitting devices ED. For example, the row line RL can include a transparent conductive oxide such as indium tin oxide (ITO) or indium zinc oxide (IZO), but the embodiments of the present disclosure are not limited thereto. For example, the row line RL can be arranged to be in contact with the second electrode Erl of the light emitting device ED. For example, the row line RL can overlap with the first optical layer 1517a. For example, the row line RL can cover a plane on the outside of the first optical layer 1517a.

The row line RL can extend continuously in the first direction (X) of the substrate 210. Accordingly, the row line RL can be commonly connected to a plurality of pixels arranged in the first direction (X) of the substrate 210. For example, the row line RL can be commonly connected to a plurality of pixels.

According to the embodiments of the present disclosure, the row line RL can be continuously extended on the first optical layer 1517a, the second optical layer 1517b, and the light emitting device ED. The area where the first optical layer 1517a is disposed can include a concave portion that is sunken inwardly from the upper surface of the second optical layer 1517b. Accordingly, the first part of the row line RL disposed on the first optical layer 1517a can be disposed along the concave portion, and thus can be disposed at a lower position than the second part of the row line RL disposed on the second optical layer 1517b.

A third optical layer 1517c can be disposed on the row line RL. The third optical layer 1517c can be disposed so as to overlap with a plurality of light emitting devices ED and the first optical layer 1517a. Since the third optical layer 1517c is arranged on the row line RL and the plurality of light emitting devices ED, it is possible to improve a mura that can occur in some of the plurality of light emitting devices ED. For example, when transferring a plurality of light emitting devices ED onto the substrate 210 of the display panel 110, there can occur an area where the spacing between the plurality of light emitting devices ED is not uniform due to process deviation. If the spacing between the plurality of light emitting devices ED is not uniform, an emission areas of each of the plurality of light emitting devices ED can be arranged unevenly, and thus a mura can be visible to the user. Accordingly, since the third optical layer 1517c is arranged to uniformly diffuse light over the plurality of light emitting devices ED, it is possible to reduce light emitted from some of the light emitting devices ED from being visible as a mura. Accordingly, since the light emitted from the plurality of light emitting devices EDs is evenly diffused by the third optical layer 1517c and extracted to the outside of the display device 100, the luminance uniformity of the display device 100 can be improved.

The third optical layer 1517c can be composed of an organic insulating material in which fine particles are dispersed, but the embodiments of the present disclosure are not limited thereto. For example, the third optical layer 1517c can be composed of siloxane in which fine metal particles such as titanium dioxide (TiO₂) particles are dispersed, but the embodiments of the present disclosure are not limited thereto. For example, the third optical layer 1517c can be composed of the same material as the first optical layer 1517a, but the embodiments of the present disclosure are not limited thereto. For example, the third optical layer 1517c can be a diffusion layer or an upper diffusion layer, but the embodiments of the present disclosure are not limited thereto.

According to the embodiments of the present disclosure, light from a plurality of light emitting devices ED can be scattered by fine particles dispersed in a third optical layer 1517c and emitted to the outside of the display device 100. The third optical layer 1517c can evenly mix light emitted from a plurality of light emitting devices ED, thereby further improving the luminance uniformity of the display device 100. In addition, the light extraction efficiency of the display device 100 can be improved by the light scattered from the plurality of fine particles, thereby enabling the display device 100 to be driven at low power.

A black matrix BM can be arranged on the row line RL, the first optical layer 1517a, the second optical layer 1517b, and the third optical layer 1517c in the display area DA. For example, the black matrix BM can fill a contact hole of the second optical layer 1517b. The black matrix BM can be configured to cover the display area DA, so that external light reflection and the color mixing of light of the plurality of subpixels can be reduced. For example, the black matrix BM can also be arranged in the contact hole where the row line RL and the row connection electrode RCE are connected, so that light leakage between the neighboring plurality of subpixels can be prevented.

For example, the black matrix BM can be composed of an opaque material, but the embodiments of the present disclosure are not limited thereto. For example, the black matrix BM can be an organic insulating material to which a black pigment or a black dye is added, but the embodiments of the present disclosure are not limited thereto.

A cover layer 1518 can be arranged on the black matrix BM in the display area DA. The cover layer 1518 can protect a configuration under the cover layer 1518. For example, the cover layer 1518 can be composed of an organic insulating material, but the embodiments of the present disclosure are not limited thereto. For example, the cover layer 1518 can be composed of a photo resist, polyimide (PI), or photo acryl-based material, but the embodiments of the present disclosure are not limited thereto. For example, the cover layer 1518 can be an overcoating layer or an insulating layer, but the embodiments of the present disclosure are not limited thereto.

A polarizing layer 114 can be arranged on the cover layer 1518 via a first adhesive layer 112. A cover member 118 can be arranged on the polarizing layer 114 via a second adhesive layer 116. For example, the first adhesive layer 112 and the second adhesive layer 116 can include an optically clear adhesive (OCA), an optically clear resin (OCR), or a pressure sensitive adhesive (PSA), but the embodiments of the present disclosure are not limited thereto.

According to embodiments of the present disclosure, a plurality of pads PD can be arranged on a third insulating layer 1515c in a second non-display area NDA2. For example, at least a portion of the plurality of pads PD can be exposed from a passivation layer 1516. For example, the plurality of pads PD can be electrically connected to a fourth pad connection pattern PCP4 through a contact hole of the third insulating layer 1515c.

An adhesive layer ACF can be arranged on the plurality of pads PD. The adhesive layer ACF can be an adhesive layer in which conductive balls are dispersed in an insulating material, but embodiments of the present disclosure are not limited thereto. When heat or pressure is applied to the adhesive layer ACF, the conductive balls can be electrically connected at a portion where the heat or pressure is applied, thereby having conductive properties. The adhesive layer ACF can be disposed between a plurality of pads PD and a flexible printed circuit 102, so that the flexible printed circuit 102 can be attached or bonded to the plurality of pads PD. For example, the adhesive layer ACF can be an anisotropic conductive film ACF, but the embodiments of the present disclosure are not limited thereto.

A flexible printed circuit 102 can be disposed on the adhesive layer ACF. The flexible printed circuit 102 can be electrically connected to the plurality of pads PD through the adhesive layer ACF. Accordingly, a signal supplied from the flexible printed circuit 102 can be transmitted to a driver DRV of a display area DA through the plurality of pads PD, the fourth pad connection pattern PCP4, the third pad connection pattern PCP3, the second pad connection pattern PCP2, and the first pad connection pattern PCP1.

Referring to FIG. 15, the display panel 110 according to the embodiments of the present disclosure can include a substrate 210, a layer stack 1410 on a plurality of drivers DRV disposed on the substrate 210, an optical layer 1517a disposed between a plurality of light emitting devices EDa, EDb and EDc on the layer stack 1410, an adhesive layer 116 disposed on the plurality of light emitting devices EDa, EDb and EDc and the optical layer 1517a, and a cover member 118 disposed on the adhesive layer 116.

A plurality of column lines CL can be disposed between the layer stack 1410 and the plurality of light emitting devices EDa, EDb and EDc.

A plurality of row lines RL can be arranged on a plurality of light emitting devices EDa, EDb and EDc and an optical layer 1517a. A plurality of row lines RL can be arranged between a plurality of light emitting devices EDa, EDb and EDc, an optical layer 1517a, and an adhesive layer 116.

A layer stack 1410 can include a plurality of protection layers 1513a, 1513b and 1514 arranged on the side and upper surface of each of a plurality of drivers DRV, a plurality of insulating layers 1515a, 1515b and 1515c arranged on the plurality of protection layers 1513a, 1513b and 1514, and a bank BNK arranged on the plurality of insulating layers.

The plurality of protection layers 1513a, 1513b and 1514 can further include a side protection layer 1513 disposed on each side of the plurality of drivers DRV and an upper protection layer 1514 disposed on the upper surface of each of the plurality of drivers DRV.

The side protection layer 1513 can include a first protection layer 1513a disposed on the substrate 210 and a second protection layer 1513b disposed on the first protection layer 1513a.

The upper protection layer 1514 can include a second protection layer 1513b and a third protection layer 1514 disposed on the plurality of drivers DRV.

The plurality of insulating layers 1515a, 1515b and 1515c can include a first insulating layer 1515a disposed on the upper protection layer 1514, and a second insulating layer 1515b disposed on the first insulating layer 1515a. The plurality of insulating layers 1515a, 1515b and 1515c can further include a third insulating layer 1515c disposed on the second insulating layer 1515b.

Each of the plurality of light emitting devices EDa, EDb and EDc can be disposed on the bank BNK and positioned in an opening of the optical layer 1517a.

At least a portion of each of the plurality of column lines CL can extend onto the bank BNK on the plurality of insulating layers 1515a, 1515b and 1515c. Each of the plurality of row lines RL can be arranged on the optical layer 1517a and the plurality of light emitting devices EDa, EDb and EDc.

A first electrode Ecl of each of the plurality of light emitting devices EDa, EDb and EDc can be electrically connected to at least a portion of a column line CL extending onto the bank BNK among the plurality of column lines CL. A second electrode Erl of each of the plurality of light emitting devices EDa, EDb and EDe can be electrically connected to one of the plurality of row lines RL.

The display panel 110 according to the embodiments of the present disclosure can include a plurality of line connection patterns LCPs that connect each of a plurality of lines including a plurality of row lines RL and a plurality of column lines CL to a plurality of drivers DRV.

The plurality of line connection patterns LCPs can include a first line connection pattern LCP1 disposed on a side protection layer 1513, a second line connection pattern LCP2 disposed on an upper protection layer 1514 and electrically connected to the first line connection pattern LCP1 through a hole in the upper protection layer 1514, a third line connection pattern LCP3 disposed on a first insulating layer 1515a and electrically connected to the second line connection pattern LCP2 through a hole in the first insulating layer 1515a, and a fourth line connection pattern LCP4 disposed on a second insulating layer 1515b and electrically connected to the third line connection pattern LCP3 through a hole in the second insulating layer 1515b.

The first line connection pattern LCP1 can be electrically connected to one of the plurality of drivers DRV. The fourth line connection pattern LCP4 can be electrically connected to at least one second electrode Erl of the plurality of light emitting devices EDa, EDb and EDc, or can be electrically connected to at least one first electrode Ecl of the plurality of light emitting devices EDa, EDb and EDc.

The side protection layer 1513 arranged on each side of the plurality of drivers DRV can include two or more organic layers.

The first and second protection layers 1513a and 1513b as the side protection layer 1513, the third protection layer 1514 as the upper protection layer 1514, and the first to third insulating layers 1515a, 1515b and 1515c can each be composed of organic layers.

In the above, there have been described the structure and operation related to the display function of the display device 100 according to the embodiments of the present disclosure.

The display device 100 according to the embodiments of the present disclosure can provide not only a display function but also a touch sensing function. Accordingly, hereinafter, it will be described a structure and an operation related to the touch sensing function of the display device 100 according to the embodiments of the present disclosure.

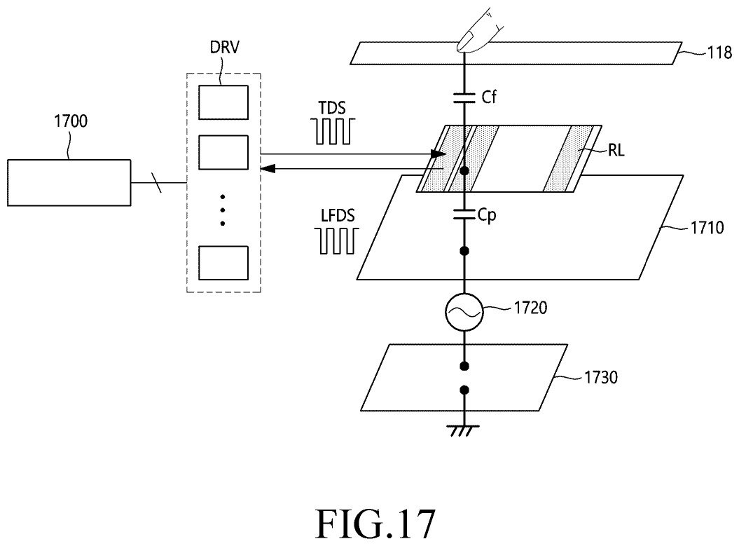

FIG. 17 is a diagram briefly illustrating the touch sensing structure of the display device 100 according to the embodiments of the present disclosure.

Referring to FIG. 17, the display device 100 according to the embodiments of the present disclosure can include a plurality of row lines RL that serve as touch sensors to perform touch sensing, a plurality of drivers DRV for driving and sensing the plurality of row lines RL, and a touch control circuit 1700 that controls the plurality of drivers DRV.

The plurality of drivers DRV can supply a touch driving signal TDS having a variable voltage level to at least one of the plurality of row lines RL. The touch driving signal TDS is a signal whose voltage level fluctuates, and can also be referred to as an AC signal or a pulse signal. For example, the touch driving signal TDS can have a signal waveform such as a square wave, a sine wave, or a triangular wave. For example, the frequency of the touch driving signal TDS can be constant. For another example, the frequency of the touch driving signal TDS can be variable. If the frequency of the touch driving signal TDS is variable according to the touch driving period T or time, it is possible to prevent the touch sensitivity degradation due to noise generated during the touch driving.

A plurality of drivers DRV can sense or detect an electrical state (e.g., a capacitance change) in at least one of a plurality of row lines RL to generate sensing data, and output the generated sensing data. Here, the sensing data can include digital sensing values.

The plurality of drivers DRV can include at least one analog-to-digital converter ADC to convert signals obtained by sensing an electrical state in at least one of the plurality of row lines RL to obtain digital sensing values.

For example, the electrical state in at least one of the plurality of row lines RL can include a capacitance Cf between a touch object such as a finger or a pen and each row line RL. For another example, the electrical state in at least one of the plurality of row lines RL can include a capacitance between two row lines RL.

The touch control circuit 1700 can supply a touch driving signal TDS or a signal as a base of the touch driving signal TDS to each of the plurality of drivers DRV, and determine an occurrence of a touch or a touch position based on sensing data provided from each of the plurality of drivers DRV. For example, the touch control circuit 1700 can include a timing controller or a micro-control unit. The touch control circuit 1700 can further include a power management integrated circuit PMIC, etc.

The display device 100 according to the embodiments of the present disclosure can perform self-capacitance-based touch sensing and/or mutual-capacitance-based touch sensing.

If a touch driving signal TDS is applied to at least one of a plurality of row lines RL for touch sensing, an unwanted parasitic capacitance Cp can be formed between the row line RL supplied with the touch driving signal TDS and other electrodes or other wirings around the corresponding row line RL. The parasitic capacitance Cp can be a factor causing a reduction of the touch sensitivity.

The display device 100 according to the embodiments of the present disclosure can further include a touch ground 1710 arranged below the plurality of row lines RL. The touch ground 1710 can correspond to an electrode that forms a parasitic capacitance Cp with the row line RL.

The display device 100 according to the embodiments of the present disclosure can further include a guard driver 1720 that supplies a load free driving signal LFDS whose signal characteristics correspond to the touch driving signal TDS to the touch ground 1710 in order to prevent an unwanted parasitic capacitance Cp from being formed between the row line RL and the touch ground 1710.

The load free driving signal LFDS output from the guard driver 1720 applied to the touch ground 1710 can be a signal whose signal characteristics are similar to the touch driving signal TDS output from the driver DRV and supplied to the row line RL. For example, the signal characteristics can include frequency, amplitude, and phase.

For example, the load free driving signal LFDS can have the same frequency as the touch driving signal TDS. The load free driving signal LFDS can have the same amplitude as the touch driving signal TDS. The load free driving signal LFDS can have the same phase as the touch driving signal TDS.

The display device 100 according to the embodiments of the present disclosure can further include a system ground 1730 that serves as a ground for the entire system.

Hereinafter, it will be described the touch sensing system and touch sensing operation of the display device 100 according to the embodiments of the present disclosure in more detail.

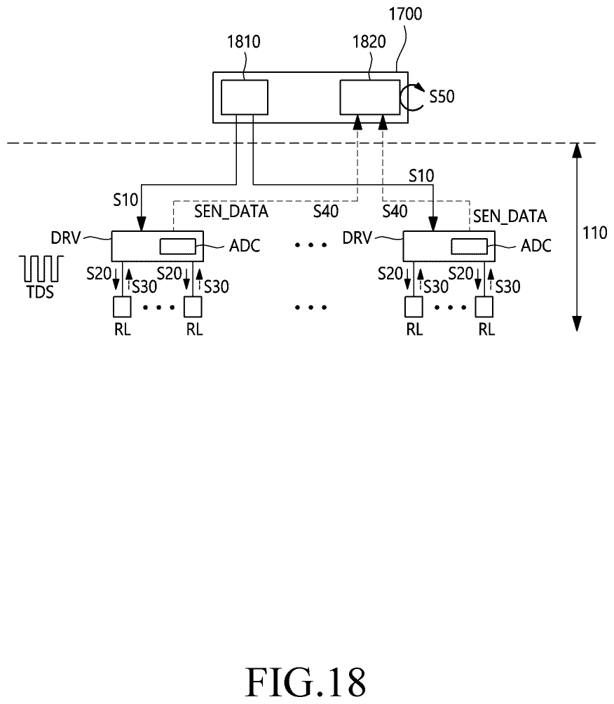

FIG. 18 illustrates the touch sensing system of the display device 100 according to the embodiments of the present disclosure.

Referring to FIG. 18, the display device 100 according to the embodiments of the present disclosure can include a plurality of row lines RL corresponding to touch sensors, a plurality of drivers DRV for driving and sensing the plurality of row lines RL, and a touch control circuit 1700 for controlling the plurality of drivers DRV.

The touch control circuit 1700 can include a signal supply circuit 1810 that supplies a touch driving signal TDS to at least one of the plurality of drivers DRV, and a touch sensing circuit 1820 that receives sensing data SEN_DATA from at least one of the plurality of drivers DRV to determine an occurrence of a touch and/or a touch position (e.g., touch coordinates).

Each of the plurality of drivers DRV can include an analog-to-digital converter ADC that converts a signal (e.g., analog signal) sensed through at least one row line RL of the plurality of row lines RL into a digital sensing value. In this way, since the analog-to-digital converter ADC exists in the display panel 110, a digital sensing value corresponding to a digital signal can exist among various signals existing in the display panel 110. For example, the display panel 110 can be a unique panel in which an analog domain in which an analog signal exists and a digital domain in which a digital signal exists coexist.

The signal supply circuit 1810 of the touch control circuit 1700 can supply a touch driving signal TDS or a signal that is the basis of the touch driving signal TDS to each of the plurality of drivers DRV (S10).

Each of the plurality of drivers DRV can receive a touch driving signal TDS or a signal that is the basis of the touch driving signal TDS from the signal supply circuit 1810 of the touch control circuit 1700 (S10), and output the touch driving signal TDS to at least one of two or more row lines RL arranged in the corresponding unit driving area UDA (S20).

Each of the plurality of drivers DRV can supply a touch driving signal TDS to all or part of two or more row lines RL included in a corresponding unit driving area UDA (S20).

Each of the plurality of drivers DRV can sense at least one of two or more row lines RL arranged in the corresponding unit driving area UDA (S30). Each of the plurality of drivers DRV can sense at least one of the two or more row lines RL, convert a sensing signal obtained according to the sensing result into a digital sensing value, and generate sensing data SEN_DATA including the converted digital sensing values.

Each of the plurality of drivers DRV can provide sensing data SEN_DATA to a touch sensing circuit 1820 of a touch control circuit 1700.

The touch control circuit 1700 can determine whether a touch has occurred or a touch position based on sensing data SEN_DATA provided from each of the plurality of drivers DRV (S50).

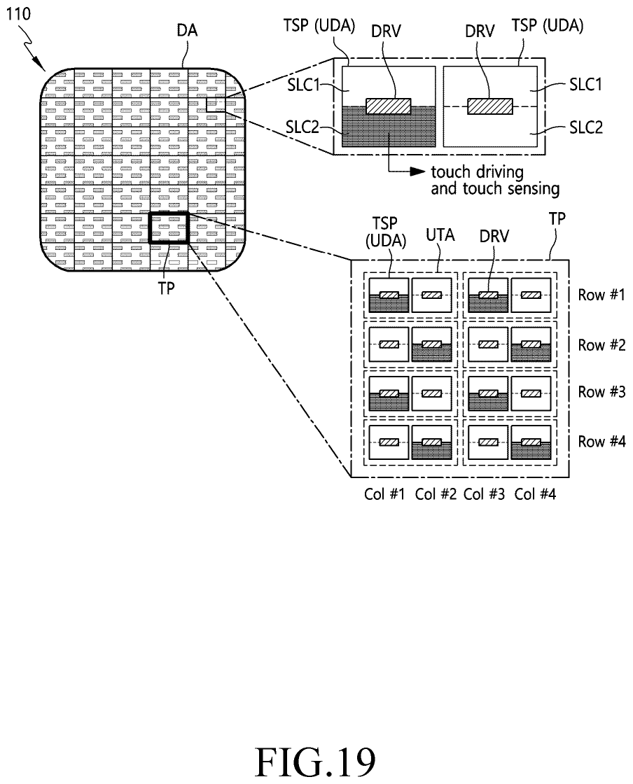

FIG. 19 illustrates a touch driving structure of a display panel 110 according to embodiments of the present disclosure. FIG. 4, FIG. 6, and FIG. 11 can also be referred to in the following description.

Referring to FIG. 19, the display area DA of the display panel 110 can include a plurality of touch pixel areas TP. Each of the plurality of touch pixel areas TP can be an area corresponding to one touch electrode TE.

A plurality of row lines RL arranged in one touch pixel area TP corresponding to one touch electrode and simultaneously performing touch driving can be processed as one touch electrode TE in the touch control circuit 1700 even if they are driven and sensed by a plurality of drivers DRV. For example, a plurality of row lines RL arranged in one touch pixel area TP and simultaneously performing touch driving can be recognized as one touch electrode TE electrically connected to each other.

The touch control circuit 1700 can determine an occurrence of the touch and/or a touch coordinate by considering the combined sensing data SEN_DATA obtained from each of the plurality of row lines RL arranged in one touch pixel area TP and simultaneously performing touch driving as sensing data obtained from one touch electrode TE.

Each of the plurality of touch pixel areas TP can include a plurality of touch subpixel areas TSP. According to the example of FIG. 19, each of the plurality of touch pixel areas TP can include 16 touch subpixel areas TSP. The 16 touch subpixel areas TSP can be arranged in 4 rows and 4 columns.

Each of the plurality of touch subpixel areas TSP can include one of the plurality of drivers DRV. For example, one driver DRV can be arranged in one touch subpixel area TSP. One touch subpixel area TSP can correspond to one unit driving area UDA.

Each of the plurality of touch subpixel areas TSP can include two or more row lines RL and two or more column lines CL. Each of the plurality of touch subpixel areas TSP can include two or more subpixels SP. Each of the plurality of touch subpixel areas TSP can include two or more light emitting devices ED.

Each of the plurality of touch pixel areas TP can include two or more unit touch driving areas UTA. Each of the two or more unit touch driving areas UTA can include at least one touch subpixel area TSP. According to the example of FIG. 19, each of the two or more unit touch driving areas UTA can include two touch subpixel areas TSP. Here, the unit touch driving area UTA is an area that becomes a basic unit of a touch driving pattern.

One touch subpixel area TSP corresponding to one unit driving area UDA can include two sub-touch driving areas SLC1 and SLC2. The two sub-touch driving areas can include a first sub-touch driving area SLC1 and a second sub-touch driving area SLC2. For example, the first sub-touch driving area SLC1 can correspond to an upper area in one touch subpixel area TSP, and the second sub-touch driving area SLC2 can correspond to a lower area in one touch subpixel area TSP. However, embodiments of the present disclosure are not limited thereto.

Two or more row lines RL and two or more column lines CL can be arranged in each of the first sub-touch driving area SLC1 and the second sub-touch driving area SLC2. Each of the first sub-touch driving area SLC1 and the second sub-touch driving area SLC2 can include two or more light emitting devices ED.

Two or more row lines RL arranged in the first sub-touch driving area SLC1 and two or more row lines RL arranged in the second sub-touch driving area SLC2 may not be connected to each other, and can be arranged separately from each other. Two or more column lines CL arranged in the first sub-touch driving area SLC1 and two or more column lines CL arranged in the second sub-touch driving area SLC2 may not be connected to each other, and can be arranged separately from each other.

The two sub-touch driving areas SLC1 and SLC2 can correspond to the two sub-driving areas SDA1 and SDA2 included in one unit driving area UDA in FIG. 4, FIG. 6, and FIG. 11, respectively.

One unit touch driving area UTA can include two touch subpixel areas TSP. One unit touch driving area UTA can include two sub-touch driving areas SLC1 and SLC2 included in each of two touch subpixel areas TSP. For example, one unit touch driving area UTA can include four sub-touch driving areas. One unit touch driving area UTA can include two drivers DRV.

For example, a touch pixel area TP can include 16 touch subpixel areas TSP arranged in four rows and four columns. Each of the 16 touch subpixel areas TSP can include one driver DRV and two sub-touch driving areas SLC1 and SLC2.

As an example, during a touch driving period for touch sensing, all four sub-touch driving areas included in one unit touch driving area UTA can be driven and sensed. Accordingly, during a touch driving period for touch sensing, each of the two drivers DRV included in one unit touch driving area UTA can drive and sense all two sub-touch driving areas SLC1 and SLC2 included in the corresponding touch subpixel area TSP.

As another example, during a touch driving period for touch sensing, only some of the four sub-touch driving areas included in one unit touch driving area UTA can be driven and sensed. According to the example of FIG. 19, during the touch driving period for touch sensing, only one sub-touch driving area among four sub-touch driving areas included in one unit touch driving area UTA can be driven and sensed. Accordingly, during the touch driving period for touch sensing, only one driver DRV among two drivers DRV included in one unit touch driving area UTA can drive and sense one of two sub-touch driving areas SLC1 and SLC2 included in the corresponding touch subpixel area TSP.

According to the embodiments of the present disclosure, the fact that the sub-touch driving area is driven and sensed can mean that two or more row lines RL arranged in the sub-touch driving area are driven (i.e., touch driven) and sensed.

The fact that two or more row lines RL arranged in the sub-touch driving area are driven (i.e., touch driven) can mean that a touch driving signal TDS having a variable voltage level is applied to two or more row lines RL arranged in the sub-touch driving area.

Referring to FIG. 19, in the touch pixel area TP, the sub-touch driving area where touch driving and touch sensing are performed can be arranged in a zigzag shape.

For example, if a touch pixel area TP includes 16 touch subpixel areas TSP arranged in four rows and four columns, in each of the first touch subpixel row Row #1 and the third touch subpixel row Row #3, the second sub-touch driving area SLC2 among the two sub-touch driving areas SLC1 and SLC2 included in the touch subpixel area TSP located in the first column Col #1 can be driven and sensed, the two sub-touch driving areas SLC1 and SLC2 included in the touch subpixel area TSP located in the second column Col #2 can be not driven and sensed. In addition, the second sub-touch driving area SLC2 among the two sub-touch driving areas SLC1 and SLC2 included in the touch subpixel area TSP located in the third column Col #3 can be driven and sensed, and the two sub-touch driving areas SLC1 and SLC2 included in the touch subpixel area TSP located in the fourth column Col #4 may not be driven and sensed.

In the second touch subpixel row Row #2 and the fourth touch subpixel row Row #4, the two sub-touch driving areas SLC1 and SLC2 included in the touch subpixel area TSP located in the first column Col #1 may not be driven and sensed, and the second sub-touch driving area SLC2 among the two sub-touch driving areas SLC1 and SLC2 included in the touch subpixel area TSP located in the second column Col #2 can be driven and sensed. In addition, the two sub-touch driving areas SLC1 and SLC2 included in the touch subpixel area TSP located in the third column Col #3 may not be driven and sensed, and the second sub-touch driving area SLC2 among the two sub-touch driving areas SLC1 and SLC2 included in the touch subpixel area TSP located in the fourth column Col #4 can be driven and sensed.

One touch pixel area TP includes a plurality of touch subpixel areas TSP, and each of the plurality of touch subpixel areas TSP can include two or more row lines RL and two or more column lines CL. Each of the plurality of touch subpixel areas TSP can include two or more light emitting devices ED.

One touch pixel area TP includes a plurality of touch subpixel areas TSP, and each of the plurality of touch subpixel areas TSP can include two sub-touch driving areas SLC1 and SLC2. Each of the two sub-touch driving areas SLC1 and SLC2 can include two or more row lines RL and two or more column lines CL. Each of the two sub-touch driving areas SLC1 and SLC2 can include two or more light emitting devices ED.

The touch subpixel area TSP will be exemplified by using the (2n×m) pixel array structure of FIG. 4.

One touch subpixel area TSP can be a unit driving area UDA driven by one of the plurality of drivers DRV.

Each of the plurality of pixels P can include k light emitting devices ED among the plurality of light emitting devices ED, and k can be a natural number greater than or equal to 2.

Each of the plurality of touch subpixel areas TSP can include (2n×m) pixels P arranged in 2n rows and m columns among the plurality of pixels P, 2n row lines RL among the plurality of row lines RL, and (m×k) column lines CL or (m×k×2) column lines CL among the plurality of column lines CL.

Each of the 2n row lines RL can correspond to m pixels P arranged in the same row among the (2n×m) pixels P. The (2n×m) pixels P can include (2n×m×k) light emitting devices ED. The n can be a natural number greater than or equal to 1, and the m can be a natural number greater than or equal to 1.

Each of the plurality of touch subpixel areas TSP can be divided into a first sub-touch driving area SLC1 and a second sub-touch driving area SLC2, which correspond to two sub-driving areas SDA1 and SDA2.

Each of the first sub-touch driving area SLC1 and the second sub-touch driving area SLC2 can include (n×m) pixels P arranged in n rows and m columns among (2n×m) pixels P, n row lines RL among 2n row lines RL, and (m×k) column lines CL among (m×k×2) column lines CL.

One row line RL among the n row lines RL can be shared by m pixels P arranged in one row among the (n×m) pixels P. The k column lines CL among the (m×k) column lines CL can be shared by n pixels P arranged in the same column among the (n×m) pixels P.

Each of the first sub-touch driving area SLC1 and the second sub-touch driving area SLC2 can include (n×m×k) light emitting devices ED. Among the (n×m×k) light emitting devices ED, the first electrodes Ecl of the n light emitting devices ED arranged in the same column can be electrically connected in common with one of the (m×k) column lines CL. Among the (n×m×k) light emitting devices ED, the second electrodes Erl of the (m×k) light emitting devices ED arranged in the same row can be electrically connected in common with one of the n row lines RL.

Among the plurality of touch subpixel areas TSP, two adjacent touch subpixel areas TSP can be combined to define one unit touch driving area UTA.

Among the plurality of touch subpixel areas TSPs, two adjacent touch subpixel areas TSP can include four sub-touch driving areas.

For example, during the touch driving period, a touch driving signal TDS can be supplied to all four sub-touch driving areas. For example, during the touch driving period, all four sub-touch driving areas can be driven and sensed.

For another example, during the touch driving period, a touch driving signal TDS can be supplied to only one to three sub-touch driving areas among the four sub-touch driving areas. For example, during the touch driving period, one to three sub-touch driving areas among the four sub-touch driving areas can be driven and sensed.

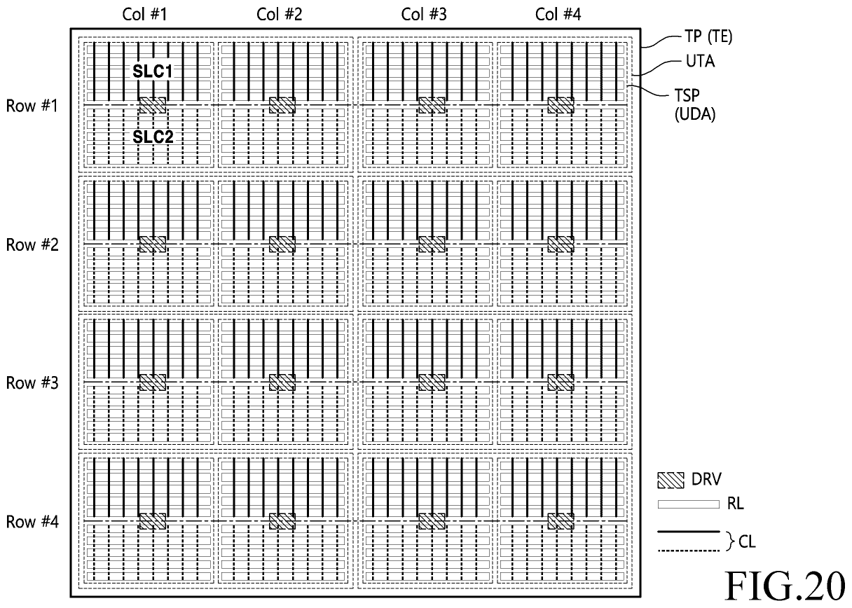

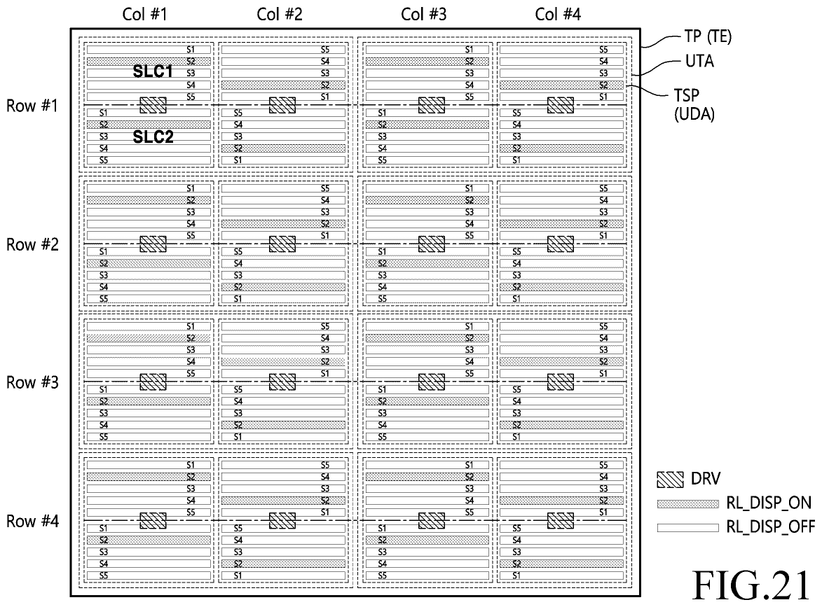

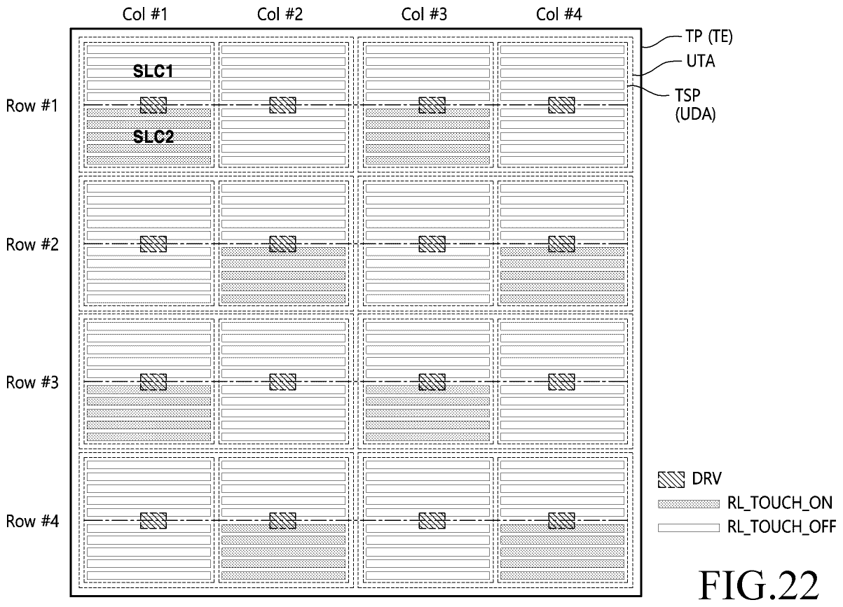

Hereinafter, it will be described a planar structure of the touch pixel area TP with reference to FIG. 20, and it will be described display driving and touch driving for the touch pixel area TP with reference to FIG. 21 and FIG. 22.

FIG. 20 is a plan view of one touch pixel area TP of a display panel 110 according to embodiments of the present disclosure.

Referring to FIG. 20, one touch pixel area TP can be an area of one touch electrode TE. At least one row line RL among a plurality of row lines RL arranged in one touch pixel area TP can constitute one touch electrode TE.

The touch pixel area TP can include a plurality of touch subpixel areas TSP arranged in a matrix form. For example, the touch pixel area TP can include 16 touch subpixel areas TSP arranged in four rows Row #1 to Row #4 and four columns Col #1 to Col #4.

Each of the 16 touch subpixel areas TSP can be a unit driving area UDA, and can include one driver DRV as a driving circuit.

Each of the 16 touch subpixel areas TSP can include a plurality of row lines RL and a plurality of column lines CL. The plurality of row lines RL and the plurality of column lines CL can overlap and intersect with each other. The plurality of row lines RL and the plurality of column lines CL can be arranged in different metal layers.

In each of the 16 touch subpixel areas TSP, a plurality of row lines RL and a plurality of column lines CL can be driven by the same driver DRV.

Each of the 16 touch subpixel areas TSP can include a first sub-touch driving area SLC1 and a second sub-touch driving area SLC2. Each of the first sub-touch driving area SLC1 and the second sub-touch driving area SLC2 can include at least one row line RL and at least one column line CL.

Each of the 16 touch subpixel areas TSP can include a plurality of pixels P, each of the plurality of pixels P can include two or more subpixels SP, and each of the two or more subpixels SP can include at least one light emitting device ED.

The light emitting device ED can include a first electrode and a second electrode. The first electrode can be electrically connected to one column line CL, and the second electrode can be electrically connected to one row line RL.

Two adjacent touch subpixel areas TSP can constitute one unit touch driving area UTA.

FIG. 21 illustrates a display driving situation for one touch pixel area TP during a display driving period D of a display device 100 according to embodiments of the present disclosure. Hereinafter, FIG. 20 is also referred to in the following description.

Referring to FIG. 21, during the display driving period D, a plurality of row lines RL can be classified into a display-on driving row line RL_DISP_ON in which display-on driving is performed and a display-off driving row line RL_DISP_OFF in which display-off driving is performed.

A first low-potential voltage VSS1 can be applied to a display-on driving row line RL_DISP_ON, and a second low-potential voltage VSS2 can be applied to a display-off driving row line RL_DISP_OFF.

When driving a display for a touch pixel area TP during a display driving period D, each of the 16 touch subpixel areas TSP included in the touch pixel area TP can be driven independently of each other.

A first sub-touch driving area SLC1 and a second sub-touch driving area SLC2 included in each of the 16 touch subpixel areas TSP can be driven independently of each other. For example, in the 16 touch subpixel areas TSP, when the first sub-touch driving area SLC1 is driven, the second sub-touch driving area SLC2 can also be driven.

In the 16 touch subpixel areas TSP, a plurality of row lines RL included in the first sub-touch driving area SLC1 can be driven sequentially, and a plurality of row lines RL included in the second sub-touch driving area SLC2 can be driven sequentially.

The display driving method of each of the 8 touch subpixel areas TSP arranged in the odd columns Col #1 and Col #3 can be the same, and the display driving method of each of the 8 touch subpixel areas TSP arranged in the even columns Col #2 and Col #4 can be the same.

The display driving method of each of the eight touch subpixel areas TSP arranged in odd columns Col #1 and Col #3 and the display driving method of each of the eight touch subpixel areas TSP arranged in even columns Col #2 and Col #4 can be different from each other.

In each of the 8 touch subpixel areas TSP arranged in odd columns Col #1 and Col #3, a plurality of row lines RL arranged in the first sub-touch driving area SLC1 can be sequentially driven from top to bottom, and a plurality of row lines RL arranged in the second sub-touch driving area SLC2 can also be sequentially driven from top to bottom. In FIGS. 21, S1 to S5 are indexes indicating the driving order, S1 is an index indicating the earliest driving order, and S5 is an index indicating the latest driving order.

In each of the 8 touch subpixel areas TSP arranged in even columns Col #2 and Col #4, a plurality of row lines RL arranged in the first sub-touch driving area SLC1 can be sequentially driven from bottom to top, and a plurality of row lines RL arranged in the second sub-touch driving area SLC2 can also be sequentially driven from bottom to top.

For example, in the touch subpixel area TSP of the first row Row #1 in the first column Col #1, a plurality of row lines RL arranged in the first sub-touch driving area SLC1 can be sequentially driven from top to bottom, and a plurality of row lines RL arranged in the second sub-touch driving area SLC2 can also be sequentially driven from top to bottom.

In the second column Col #2, in the touch subpixel area TSP of the first row Row #1, a plurality of row lines RL arranged in the first sub-touch driving area SLC1 can be sequentially driven from the bottom to the top, and a plurality of row lines RL arranged in the second sub-touch driving area SLC2 can also be sequentially driven from the bottom to the top.

FIG. 21 illustrates a situation at a specific point in time (e.g., a point in time corresponding to S2) during the display driving period D.

Referring to FIG. 21, at a specific point in time (e.g., a point in time corresponding to S2) during the display driving period D, in each touch subpixel area TSP arranged in an odd column Col #1 and Col #3, among the five row lines RL arranged in each of the first sub-touch driving area SLC1 and the second sub-touch driving area SLC2, the second row line RL from the top can be a display-on driving row line RL_DISP_ON, and the remaining row lines RL can be display-off driving row lines RL_DISP_OFF.

At a specific point in time (e.g., a point in time corresponding to S2) during the display driving period D, in each touch subpixel area TSP arranged in an even column Col #2 and Col #4, the second row line RL from the bottom among the five row lines RL arranged in each of the first sub-touch driving area SLC1 and the second sub-touch driving area SLC2 can be a display-on driving row line RL_DISP_ON, and the remaining row lines RL can be display-off driving row lines RL_DISP_OFF.

A first low-potential voltage VSS1 can be applied to the display-on driving row line RL_DISP_ON. Accordingly, the light emitting devices ED connected to the display-on driving row line RL_DISP_ON can emit light.

A second low-potential voltage VSS2 higher than the first low-potential voltage VSS1 can be applied to the display-off driving row line RL_DISP_OFF. Accordingly, the light emitting devices ED connected to the display-off driving row line RL_DISP_OFF may not emit light.

FIG. 22 illustrates a touch driving situation for one touch pixel area TP during a touch driving period T of a display device 100 according to embodiments of the present disclosure.

Referring to FIG. 22, during the touch driving period T, a touch driving signal TDS is applied to the row line RL to drive the row line RL.

During the touch driving period T, a plurality of row lines RL can be classified into a touch driving row line RL_TOUCH_ON and a non-touch driving row line RL_TOUCN_OFF.

A touch driving signal TDS whose voltage level is variable can be applied to a touch driving row line RL_TOUCH_ON. The touch driving row line RL_TOUCH_ON can be sensed by a driver DRV.

A touch driving signal TDS may not be applied to a non-touch driving row line RL_TOUCN_OFF. In some cases, even if a touch driving signal TDS or a similar signal is applied to the non-touch driving row line RL_TOUCN_OFF, the non-touch driving row line RL_TOUCN_OFF may not be sensed by a driver DRV.

Hereinafter, it will be described a touch driving method for 16 touch subpixel areas TSP included in a touch pixel area TP during a touch driving period T.

As an example, during one touch driving period T, all 16 touch subpixel areas TSP included in a touch pixel area TP can be driven.

In this case, all or part of a plurality of row lines RL included in each of the 16 touch subpixel areas TSPs can be driven. For example, all or part of a plurality of row lines RL arranged in each of the first sub-touch driving area SLC1 and the second sub-touch driving area SLC2 included in each of the 16 touch subpixel areas TSP can be driven. For another example, all or part of the plurality of row lines RL arranged in one of the first sub-touch driving area SLC1 and the second sub-touch driving area SLC2 included in each of the 16 touch subpixel areas TSP can be driven.

As another example, during one touch driving period T, only at least one of the 16 touch subpixel areas TSPs included in the touch pixel area TP can be driven.

In this case, all or part of the plurality of row lines RL included in each of at least one of the 16 touch subpixel areas TSP can be driven. For example, all or part of the plurality of row lines RL arranged in each of the first sub-touch driving area SLC1 and the second sub-touch driving area SLC2 included in each of at least one of the 16 touch subpixel areas TSP can be driven. For another example, all or part of a plurality of row lines RL arranged in one of the first sub-touch driving area SLC1 and the second sub-touch driving area SLC2 included in at least one of the 16 touch subpixel areas TSP can be driven.

According to the example of FIG. 22, during one touch driving period T, among the four touch subpixel areas TSP arranged in each of the first row Row #1 and the third row Row #3, only the touch subpixel areas TSP arranged in the first column Col #1 and the third column Col #3 can be driven. In addition, in this case, among the four touch subpixel areas TSP arranged in each of the second row Row #2 and the fourth row Row #4, only the touch subpixel areas TSP arranged in the second column Col #2 and the fourth column Col #4 can be driven.

In each of the first row Row #1 and the third second row Row #3, among the first sub-touch driving area SLC1 and the second sub-touch driving area SLC2 included in each of the touch subpixel areas TSP arranged in the first column Col #1 and the third column Col #3 where touch driving is performed, only the second sub-touch driving area SLC2 can be driven. If a touch driving signal TDS is applied to five row lines RL arranged in the second sub-touch driving area SLC2, which is the area where touch driving is performed, the second sub-touch driving area SLC2 can be driven.

In each of the second row Row #2 and the fourth row Row #4, among the first sub-touch driving area SLC1 and the second sub-touch driving area SLC2 included in each of the touch subpixel areas TSP arranged in the second column Col #2 and the fourth column Col #4 where touch driving is performed, only the second sub-touch driving area SLC2 can be driven. The second sub-touch driving area SLC2 can be driven by applying a touch driving signal TDS to five row lines RL arranged in the second sub-touch driving area SLC2, which is the area where touch driving is performed.

Hereinafter, it will be described a driving method of a display device 100 according to embodiments of the present disclosure in more detail.

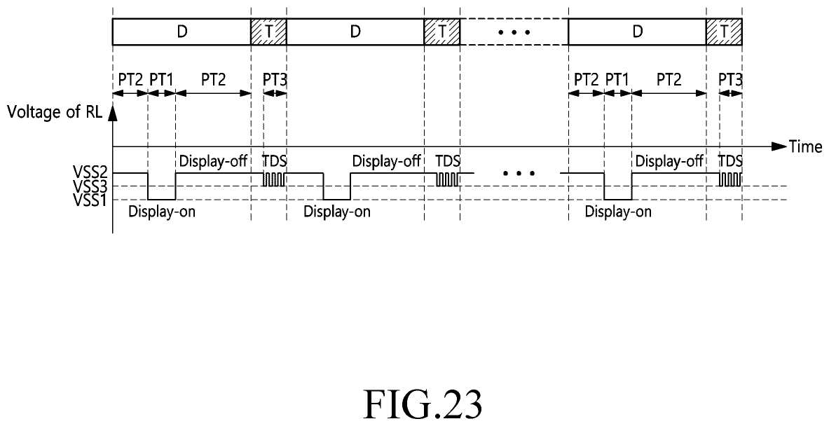

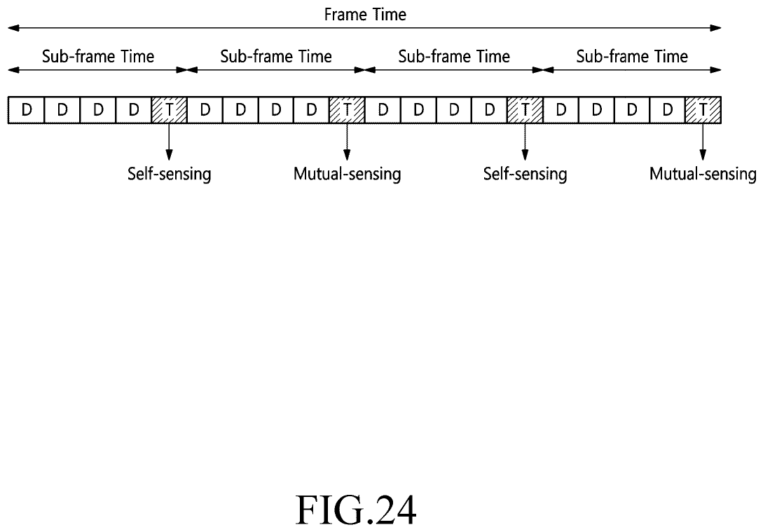

FIG. 23 and FIG. 24 are driving timing diagrams of a display device 100 according to embodiments of the present disclosure.

Referring to FIG. 23 and FIG. 24, the display device 100 according to the embodiments of the present disclosure can perform display driving for image display and touch driving (or touch sensing) for touch sensing.

The display device 100 according to the embodiments of the present disclosure can allocate a display driving period D and a touch driving period T, perform display driving during the display driving period D, and perform touch driving during the touch driving period T.

The display device 100 according to the embodiments of the present disclosure can perform display driving and touch driving according to a time-division driving method or a simultaneous driving method.

For example, the display device 100 according to the embodiments of the present disclosure can allocate the display driving period D and the touch driving period T as separate time periods according to the time-division driving method, and can perform display driving during the display driving period D and perform touch driving during the touch driving period T different from the display driving period D.

As another example, the display device 100 according to the embodiments of the present disclosure can perform display driving and touch driving simultaneously during the display driving period D and the touch driving period T that overlap in time according to the simultaneous driving method.

Hereinafter, for the convenience of explanation, the display device 100 according to the embodiments of the present disclosure performs display driving and touch driving at different time periods according to the time division driving method as an example. However, this is not limited thereto.

As an example of a time division driving method, as illustrated in FIG. 23, one display driving period D and one touch driving period T can alternately proceed. For example, one display driving period D can proceed, and then one touch driving period T can proceed.

As an example, one display driving period D can be a period during which display driving is performed to display an image on the entire screen. For example, the period that is the sum of one display driving period D and one touch driving period T can be a frame time. In this case, one display driving period D can correspond to an active time among the active time and a blank time included in one frame time, and one touch driving period T can correspond to a blank time among the active time and blank time included in one frame time.

As another example, two or more display driving periods D can be a period during which display driving is performed to display an image on the entire screen. For example, the time period that is the sum of two or more display driving periods D and two or more touch driving periods T can be a frame time. In this case, one frame time can include two or more sub-frame times. Each of the two or more sub-frame times can include a sub-active time and a sub-blank time. The time summing one display driving period D and one touch driving period T can be one sub-frame time among two or more sub-frame times included in one frame time. One display driving period D included in one sub-frame time can correspond to a sub-active time, and one touch driving period T can correspond to a sub-blank time.

As another example of the time division driving method, as illustrated in FIG. 24, a plurality of display driving periods D and one touch driving period T can alternately proceed. For example, a plurality of display driving periods D can proceed, and then one touch driving period T can proceed.

According to the example of FIG. 24, four display driving periods D can be performed, and then one touch driving period T can be performed. For example, the time summing four display driving periods D and one touch driving period T can correspond to one sub-frame time, and the time summing four sub-frame times can correspond to one frame time for displaying an image on the entire screen.

According to the example of FIG. 24, four touch driving periods T included in one frame time can include self-sensing-based touch driving periods T and mutual-sensing-based touch driving periods T that are alternately proceeded. For example, among the four touch driving periods T included in one frame time, the first and third touch driving periods T can be self-sensing-based touch driving periods T, and the second and fourth touch driving periods T can be mutual-sensing-based touch driving periods T.

Self-sensing-based touch driving can be a touch driving for determining the occurrence of the touch and/or a touch coordinate based on the capacitance (e.g., self-capacitance) between a plurality of row lines RL corresponding to a touch electrode TE and a touch object (e.g., a finger, a pen, etc.).

Mutual-sensing-based touch driving can be a touch driving for determining the occurrence of the touch and/or a touch coordinate based on the capacitance (e.g., mutual-capacitance) between a plurality of row lines RL corresponding to a touch electrode TE and a plurality of row lines RL corresponding to another touch electrode TE.

Referring to FIG. 23, a plurality of row lines RL can simultaneously perform the role of a cathode electrode (or an anode electrode) for display driving and the role of a touch sensor (e.g., touch electrode) for touch driving. Therefore, the electrical state of the row line RL during the display driving period D and the electrical state of the row line RL during the touch driving period T can be different.

One row line RL among the plurality of row lines RL can be supplied with a first low-potential voltage VSS1 during a first period PT1, and can be supplied with a second low-potential voltage VSS2 during a second period PT2 different from the first period PT1.

The first period PT1 and the second period PT2 can be periods included in one display driving period D or periods included in different display driving periods D.

The first low-potential voltage VSS1 and the second low-potential voltage VSS2 are a type of low-potential voltage VSS and can be a row line voltage applied to the row line RL. In addition, the first low-potential voltage VSS1 and the second low-potential voltage VSS2 can be a voltage (for example, a cathode voltage or an anode voltage) applied to the second electrode Erl of the light emitting devices ED connected to the row line RL.

Among the first low-potential voltage VSS1 and the second low-potential voltage VSS2, the first low-potential voltage VSS1 can be a low-potential voltage for driving the display-on, and the second low-potential voltage VSS2 can be a low-potential voltage for driving the display-off.

The first low-potential voltage VSS1 can be a voltage lower than the second low-potential voltage VSS2. For example, the second low-potential voltage VSS2 can be a higher voltage than the first low-potential voltage VSS1. Accordingly, during the first period PT1, the voltage difference between the first electrode Ecl and the second electrode Erl of the light emitting device ED can be higher than the threshold voltage of the light emitting device ED. Accordingly, the light emitting device ED can be in a state capable of emitting light. Then, during the second period PT2, the voltage difference between the first electrode Ecl and the second electrode Erl of the light emitting device ED can be lower than the threshold voltage of the light emitting device ED. Accordingly, the light emitting device ED can be in a state in which it cannot emit light.

Meanwhile, one of the plurality of row lines RL can be supplied with a touch driving signal TDS, which is a signal whose voltage level swings, during a third period PT3 different from the first period PT1 and the second period PT2.

The third period PT3 can be a period included in the touch driving period T.

The touch driving signal TDS can be a signal having a predetermined frequency and whose voltage level fluctuates (for example, in the form of a rectangular wave). The touch driving signal TDS can be a signal that swings between a predefined high voltage and a low voltage. For example, the high voltage can be a second low-potential voltage VSS2, and the low voltage can be a third low-potential voltage VSS3. The amplitude of the touch driving signal TDS can be a voltage difference between the high voltage and the low voltage. For example, the third low-potential voltage VSS3 can be a voltage lower than the second low-potential voltage VSS2 and can be the same as or different from the first low-potential voltage VSS1. For example, the third low-potential voltage VSS3 can be a voltage higher than the first low-potential voltage VSS1 and lower than the second low-potential voltage VSS2.

Depending on the driving type and driving timing, each of the plurality of row lines RL can be driven in a predetermined method.

For example, the display-on driving for each of the plurality of row lines RL can be performed sequentially. For another example, the display-on driving for each of the plurality of row lines RL can be performed simultaneously. For another example, the display-on driving for each of two or more row lines RL among the plurality of row lines RL can be performed simultaneously.

For example, during a specific display driving period, among the plurality of row lines RL arranged in the unit driving area UDA, display-on driving can be performed for at least one row line RL, and display-off driving can be performed for the remaining row lines RL without display-on driving.

The display-on driving performed for a specific row line RL can mean that a first low-potential voltage VSS1 of a predefined level is supplied to the corresponding row line RL.

When the display-on driving for a specific row line RL is performed, the light emitting devices ED arranged corresponding to the corresponding row line RL can emit light.

The display-off driving performed for a specific row line RL without display-on driving can mean that a second low-potential voltage VSS2 of a predefined level is supplied to the corresponding row line RL. Here, the second low-potential voltage VSS2 can be a higher voltage than the first low-potential voltage VSS1.

When display-off driving is performed for a specific row line RL, the light emitting devices ED arranged corresponding to the row line RL may not emit light.

For example, a first row line RL among the plurality of row lines RL can be supplied with a first low-potential voltage VSS1 during a first period, and can be supplied with a second low-potential voltage VSS2 higher than the first low-potential voltage VSS1 during a second period different from the first period. For example, the first period and the second period can be included in one display driving period. For another example, the first period and the second period can be included in different display driving periods.

The situation in the display panel 110 during the first to third periods PT1, PT2 and PT3 will be described again as follows.

During the first period PT1, the first row line RL among the plurality of row lines RL can be supplied with a first low-potential voltage VSS1. Accordingly, display-on driving can be performed on the first row line RL during the first period PT1.

During a second period PT2 different from the first period PT1, the first row line RL among the plurality of row lines RL can be supplied with a second low-potential voltage VSS2 higher than the first low-potential voltage VSS1. Accordingly, during the second period PT2, display-off driving can be performed on the first row line RL.

During a third period PT3 different from the first period PT1 and the second period PT2, the first row line RL among the plurality of row lines RL can be supplied with a touch driving signal TDS, which is a signal whose voltage level swings. For example, during the third period PT3, the first row line RL can function as a touch sensor.

The plurality of row lines RL can further include a second row line RL different from the first row line RL.

The plurality of column lines CL can include a first column line CL overlapping with the first row line RL and the second row line RL.

In addition, the first row line RL, the second row line RL, and the first column line CL can be arranged together in a touch subpixel area TSP which is one unit driving area UDA. The first row line RL, the second row line RL, and the first column line CL can be driven by the same driver DRV.

During the first period PT1 in which display-on driving is performed on the first row line RL, the second row line RL can be supplied with the second low-potential voltage VSS2. For example, during the first period PT1, display-on driving can be performed on the first row line RL, and display-off driving can be performed on the second row line RL.

The plurality of light emitting devices ED can include a first light emitting device ED having a first electrode connected to a first column line CL and a second electrode connected to a first row line RL, and a second light emitting device ED having a first electrode connected to the first column line CL and a second electrode connected to a second row line RL.

During the first period PT1, display-on driving is performed on the first row line RL, and display-off driving is performed on the second row line RL. Accordingly, during the first period PT1, the first light emitting device ED can emit light, and the second light emitting device ED may not emit light.

During the third period PT3, the voltage difference between the first column line CL and the first row line RL can be less than the threshold voltage of the first light emitting device ED. Accordingly, during the third period PT3, the first light emitting device ED may not emit light.

The plurality of drivers DRV can be positioned closer to the substrate 210 than the plurality of light emitting devices ED.

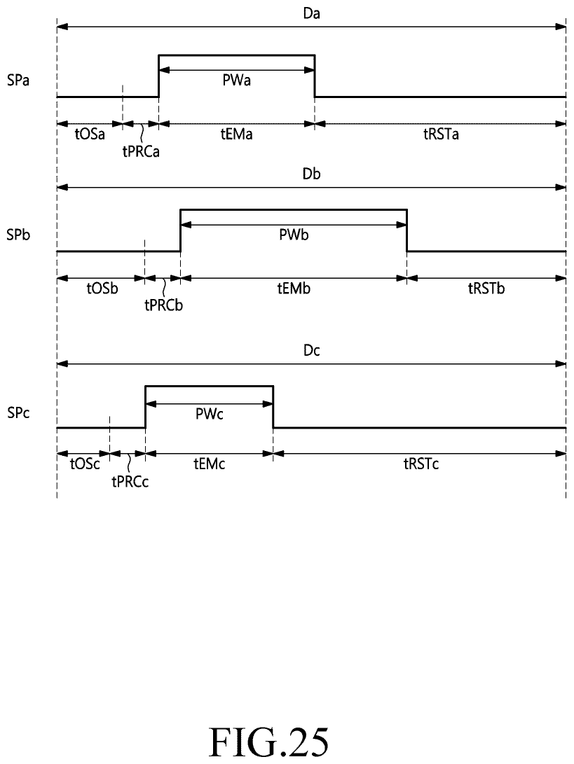

FIG. 25 is a display driving timing diagram for three subpixels SPa, SPb and SPc of the display device 100 according to embodiments of the present disclosure.

Referring to FIG. 25, a plurality of pixels P arranged in a display device 100 according to embodiments of the present disclosure can be classified into k subpixels. The k can be a natural number greater than or equal to 2. For example, k can be 3. In this case, the k subpixels can be three subpixels SPa, SPb and SPc.

If k is 3, each of a plurality of pixels P arranged in a display device 100 according to embodiments of the present disclosure can include three subpixels SPa, SPb and SPc. For example, the three subpixels SPa, SPb and SPc can include a first subpixel SPa including a first light emitting device EDa that emits a first color light, a second subpixel SPb including a second light emitting device EDb that emits a second color light, and a third subpixel SPc including a third light emitting device EDc that emits a third color light.

The display driving period D can include a first display driving period Da, a second display driving period Db, and a third display driving period Dc. The first display driving period Da can include a first pre-charge period tPRCa, a first emission period tEMa, and a first reset period tRSTa for the first subpixel SPa. The second display driving period Db can include a second pre-charge period tPRCb, a second emission period tEMb, and a second reset period RSTb for the second subpixel SPb. The third display driving period Dc can include a third pre-charge period tPRCc, a third emission period tEMc, and a third reset period tRSTc for the third subpixel SPc.

According to the display device 100 according to the embodiments of the present disclosure, the timing of the first emission period tEMa, the timing of the second emission period tEMb, and the timing of the third emission period tEMc can be different from each other.

According to the display device 100 according to the embodiments of the present disclosure, a first length PWa of the first emission period tEMa, a second length PWb of the second emission period tEMb, and a third length PWc of the third emission period tEMc can be different from each other.

The three graphs illustrated in FIG. 25 can be signal waveforms of one of the first emission control signal EM1 and the second emission control signal EM2 for each of the three subpixels SPa, SPb and SPc. For example, according to the display device 100 according to the embodiments of the present disclosure, the first length PWa of the first emission period tEMa, the second length PWb of the second emission period tEMb, and the third length PWc of the third emission period tEMc can each correspond to brightness to be expressed in the corresponding subpixel, correspond to an image signal (e.g., image data) corresponding to the corresponding subpixel, or correspond to a length of a turn-on level voltage section of an emission control signal in the column driver C-DRV. For example, the emission control signal in the column driver C-DRV is a display driving control signal supplied from a controller (e.g., a timing controller) to the column driver C-DRV, and can include the first emission control signal EM1 of FIGS. 5, 8, and 9, and can further include the second emission control signal EM2 of FIG. 9. For example, the turn-on level voltage section of the emission control signal can be a high level voltage section or a low level voltage section.

According to the display device 100 according to the embodiments of the present disclosure, the first display driving period Da can further include a first offset period tOSa before the first pre-charge period tPRCa, the second display driving period Db can further include a second offset period tOSb before the second pre-charge period tPRCb, and the third display driving period Dc can further include a third offset period tOSc before the third pre-charge period tPRCc.

According to the display device 100 according to the embodiments of the present disclosure, the length of the first offset period tOSa, the length of the second offset period tOSb, and the length of the third offset period tOSc can be different from each other.

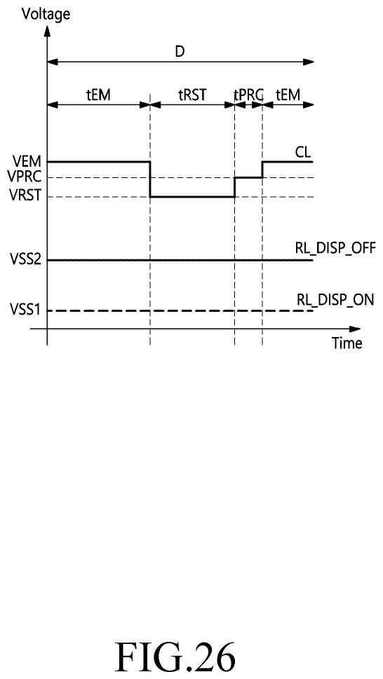

Hereinafter, it will be described the driving of the row line RL and the column line CL during the display driving period D in more detail with reference to FIG. 26.

FIG. 26 is a driving timing diagram for the row line RL and the column line CL during the display driving period D of the display device 100 according to the embodiments of the present disclosure.

Referring to FIG. 26, according to the display device 100 according to the embodiments of the present disclosure, during the display driving period D, at least one first row line RL_DISP_ON among the plurality of row lines RL is supplied with a first low-potential voltage VSS1. At least one second row line RL_DISP_OFF different from at least one first row line RL_DISP_ON among the plurality of row lines RL can be applied with a second low-potential voltage VSS2 higher than the first low-potential voltage VSS1.

As an example, at least one first row line RL_DISP_ON and at least one second row line RL_DISP_OFF can be arranged in one unit driving area UDA. In this case, at least one first row line RL_DISP_ON and at least one second row line RL_DISP_OFF can be electrically connected to the same driver DRV. At least one first row line RL_DISP_ON and at least one second row line RL_DISP_OFF can be driven by the same driver DRV.

As another example, at least one first row line RL_DISP_ON and at least one second row lines RL_DISP_OFF can be arranged in different unit driving areas UDAs. In this case, at least one first row line RL_DISP_ON and at least one second row line RL_DISP_OFF can be electrically connected to different drivers DRV. At least one first row line RL_DISP_ON and at least one second row line RL_DISP_OFF can be driven by different drivers DRV.

During the display driving period D, the light emitting devices ED overlapping with at least a portion of at least one first row line RL_DISP_ON can emit light, and the light emitting devices ED overlapping with at least a portion of at least one second row line RL_DISP_OFF may not emit light.

The display driving period D can include a pre-charge period tPRC, an emission period tEM, and a reset period tRST.

During the pre-charge period tPRC, the emission period tEM, and the reset period tRST, a first low-potential voltage VSS1 can be applied to at least one first row line RL_DISP_ON, and a second low-potential voltage VSS2 can be applied to at least one second row line RL_DISP_OFF.

During the pre-charge period tPRC, a display driving pre-charge voltage VPRC can be applied to at least one column line CL among the plurality of column lines CL. Here, the display driving pre-charge voltage VPRC can be a constant voltage or a variable voltage.

During the emission period tEM, an emission driving voltage VEM can be applied to at least one column line CL. Here, the emission driving voltage VEM can be a display voltage for displaying an image.

During the reset period tRST, a display driving reset voltage VRST can be applied to at least one column line CL. Here, the display driving reset voltage VRST can be a constant voltage or a variable voltage.

The voltage applied to the column line CL can be referred to as a column line voltage, and can also be referred to as an anode voltage or a cathode voltage. The pre-charge voltage for display driving VPRC, the emission driving voltage VEM, and the reset voltage for display driving VRST can be column line voltages having different purposes depending on the driving timing.

For example, among the pre-charge voltage for display driving VPRC, the emission driving voltage VEM, and the reset voltage for display driving VRST, the reset voltage for display driving VRST can have the lowest voltage value, and the emission driving voltage VEM can have the highest voltage value.

As an example, at least one column line CL can intersect with at least one first row line RL_DISP_ON and at least one second row line RL_DISP_OFF. In this case, at least one column line CL, at least one first row line RL_DISP_ON, and at least one second row line RL_DISP_OFF can be arranged in the same unit driving area UDA. At least one column line CL, at least one first row line RL_DISP_ON, and at least one second row line RL_DISP_OFF can be electrically connected to the same driver DRV. At least one column line CL, at least one first row line RL_DISP_ON, and at least one second row line RL_DISP_OFF can be driven by the same driver DRV.

In another example, the at least one column line CL may not intersect with the at least one first row line RL_DISP_ON and the at least one second row line RL_DISP_OFF. In this case, the at least one column line CL can be arranged in a different unit driving area UDA from the at least one first row line RL_DISP_ON and the at least one second row line RL_DISP_OFF. At least one column line CL can be electrically connected to another driver DRV different from at least one driver DRV that is electrically connected to at least one first row line RL_DISP_ON and at least one second row line RL_DISP_OFF. At least one column line CL can be driven by a driver DRV that is different from the driver DRV driving at least one first row line RL_DISP_ON and at least one second row line RL_DISP_OFF.

In another example, the at least one column line CL can intersect with one of the at least one first row line RL_DISP_ON and the at least one second row line RL_DISP_OFF. In this case, the at least one column line CL can be arranged in the same unit driving area UDA as one of the at least one first row line RL_DISP_ON and the at least one second row line RL_DISP_OFF. At least one column line CL can be electrically connected to at least one driver DRV that is electrically connected to one of the at least one first row line RL_DISP_ON and the at least one second row line RL_DISP_OFF. At least one column line CL can be driven by a driver DRV driving one of the at least one first row line RL_DISP_ON and the at least one second row line RL_DISP_OFF.

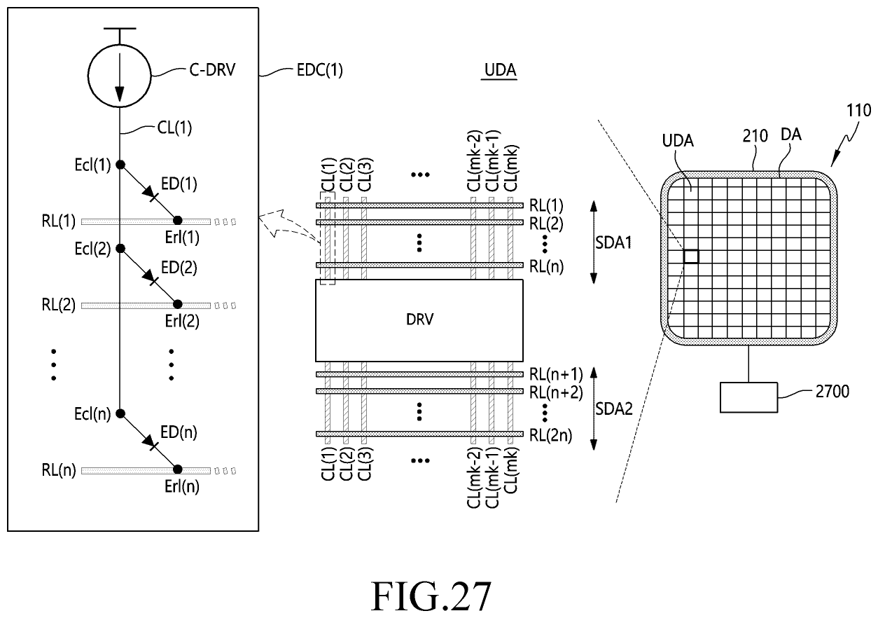

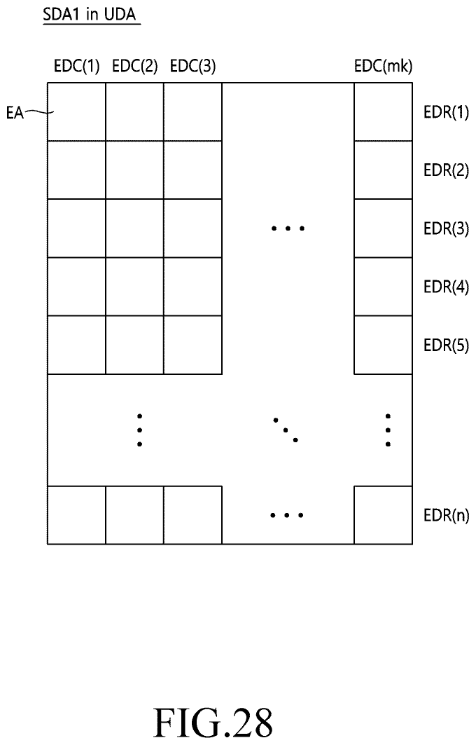

FIG. 27 illustrates a unit driving area UDA of a display device 100 according to embodiments of the present disclosure, and a first light emitting device column EDC(1) within the unit driving area UDA. FIG. 28 illustrates an arrangement of light emitting devices and emission areas EA within a first sub-driving area SDA1 included in the unit driving area UDA of a display device 100 according to embodiments of the present disclosure.

Referring to FIG. 27, the display device 100 according to the embodiments of the present disclosure can include a substrate 210 including a display area DA, a plurality of light emitting devices ED arranged in the display area DA, a plurality of column lines CL arranged in the display area DA and extending in the column direction, a plurality of row lines RL arranged in the display area DA and extending in the row direction, and a plurality of drivers DRV arranged on the substrate 210 and configured to drive the plurality of column lines CL and the plurality of row lines RL. For example, a metal layer on which the plurality of column lines CL are arranged and a metal layer on which the plurality of row lines RL are arranged can be different from each other.

The display device 100 according to the embodiments of the present disclosure can include a controller 2700 configured to output image data or a control signal corresponding to the image data to each of the plurality of drivers DRV.

The substrate 210, the plurality of light emitting devices ED, the plurality of column lines CL, and the plurality of row lines RL are included in the display panel 110 of the display device 100, and the controller 2700 can be included outside the display panel 110. For example, the controller 2700 can be mounted on a flexible printed circuit 102 or a printed circuit board 104.

The display area DA of the display panel 110 of the display device 100 according to the embodiments of the present disclosure can include a plurality of unit driving areas UDAs, and each of the plurality of unit driving areas UDA can be an area driven by one driver DRV.

Each of the plurality of unit driving areas UDA can include a separate driver DRV as well as a separate line structure. Here, the line structure can include a plurality of row lines RL and a plurality of column lines CL. For example, the plurality of unit driving areas UDA can include a first unit driving area UDA and a second unit driving area UDA. Two or more row lines RL included in the first unit driving area UDA and two or more row lines RL included in the second unit driving area UDA can be spaced apart from each other or electrically isolated, and two or more column lines CL included in the first unit driving area UDA and two or more column lines CL included in the second unit driving area UDA can be spaced apart from each other or electrically isolated.

Each of the plurality of unit driving areas UDA can include two or more column lines CL(1) to CL(m×k) among the plurality of column lines CL, and can include two or more row lines RL(1) to RL(2n) among the plurality of row lines RL.

For example, two or more column lines CL(1) to CL(m×k) and two or more row lines RL(1) to RL(2n) arranged in each of the plurality of unit driving areas UDA can intersect each other. For example, in each of the plurality of unit driving areas UDA, each of two or more row lines RL(1) to RL(2n) can intersect with two or more column lines CL(1) to CL(m×k).

For example, in each of the plurality of unit driving areas UDA, the metal layer on which the two or more column lines CL(1) to CL(m×k) are arranged and the metal layer on which the two or more row lines RL(1) to RL(2n) are arranged can be different from each other. For example, in each of the plurality of unit driving areas UDAs, each of the two or more row lines RL(1) to RL(2n) can overlap with two or more column lines CL(1) to CL(m×k).

For example, each of the plurality of unit driving areas UDA can include a first sub-driving area SDA1 and a second sub-driving area SDA2. The first sub-driving area SDA1 can include two or more column lines CL(1) to CL(m×k) and two or more row lines RL(1) to RL(n) that intersect with each other. The second sub-driving area SDA2 can include two or more column lines CL(1) to CL(m×k) and two or more row lines RL(n+1) to RL(2n) that intersect each other.

Here, n can be the number of row lines RL included in each of the first sub-driving area SDA1 and the second sub-driving area SDA2 or the number of pixel rows included in each of the first sub-driving area SDA1 and the second sub-driving area SDA2.

In addition, m can be the number of pixel columns included in each of the first sub-driving area SDA1 and the second sub-driving area SDA2. The k can be the number of subpixels included in one pixel or the number of light emitting devices ED included in one pixel.

In addition, mk can be (m×k), which can be the number of subpixel columns or light emitting device columns included in each of the first sub-driving area SDA1 and the second sub-driving area SDA2, and can be the number of column lines CL included in each of the first sub-driving area SDA1 and the second sub-driving area SDA2.

The first sub-driving area SDA1 included in each of the plurality of unit driving areas UDA can include light emitting devices ED arranged in each of the areas or points where two or more column lines CL(1) to CL(mk) and two or more row lines RL(1) to RL(n) intersect. The second sub-driving area SDA2 included in each of the plurality of unit driving areas UDA can include light emitting devices ED arranged in each of the areas or points where two or more column lines CL(1) to CL(mk) and two or more row lines RL(n+1) to RL(2n) intersect.

Accordingly, each of the plurality of column lines CLs can be electrically connected in common with a first electrode of each of two or more light emitting devices ED arranged in the same column among the plurality of light emitting devices ED. Each of the plurality of row lines RL can be electrically connected in common with a second electrode of each of two or more light emitting devices ED arranged in the same row among the plurality of light emitting devices ED.

For example, the first sub-driving area SDA1 can include n row lines RL(1) to RL(n) and (mk) column lines CL(1) to CL(mk) intersecting each other. At each point where n row lines RL(1) to RL(n) and (mk) column lines CL(1) to CL(mk) intersect each other, a light emitting device ED can be arranged.

For example, in the first sub-driving area SDA1, the second electrodes of the mk light emitting devices ED arranged in the first row (i.e., the first light emitting device row) can be electrically connected in common to the first row line RL(1). In the first sub-driving area SDA1, the first electrodes of the mk light emitting devices ED arranged in the first row (i.e., the first light emitting device row) can be electrically connected to the first to (mk)-th column lines CL(1) to CL(mk), respectively.

For example, in the first sub-driving area SDA1, the first electrodes Ecl(1) to Ecl(n) of the n light emitting devices ED(1) to ED(n) arranged in the first column (i.e., the first light emitting device column EDC(1)) can be electrically connected in common to the first column line CL(1). In the first sub-driving area SDA1, the second electrodes Erl(1) to Erl(n) of the n light emitting devices ED(1) to ED(n) arranged in the first column (i.e., the first light emitting device column (EDC(1)) can be electrically connected to the first to n-th row lines RL(1) to RL(n), respectively.

The first column line CL(1) can receive current (or voltage) from the column driver C-DRV.

The display-on driving for each of the first to n-th row lines RL(1) to RL(n) can be sequentially performed. If the first low-potential voltage VSS1, which is a low-potential voltage for display-on driving, is applied to the first row line RL(1), the current supplied from the column driver C-DRV can be supplied to the first light emitting device ED(1). At this time, the current supplied from the column driver C-DRV is not supplied to the second to n-th light emitting devices ED(2) to ED(n).

Subsequently, if the first low-potential voltage VSS1, which is a low-potential voltage for display-on driving, is applied to the second row line RL(2), the current supplied from the column driver C-DRV can be supplied to the second light emitting device ED(2). At this time, the current supplied from the column driver C-DRV is not supplied to the first light emitting device ED(1) and the third to n-th light emitting devices ED(3) to ED(n).

Referring to FIG. 28, one unit driving area UDA can include a plurality of light emitting devices ED arranged in a matrix form, and can include a plurality of emission areas EA that emit light by the plurality of light emitting devices ED.

For example, a first sub-driving area SDA1 included in one unit driving area UDA can have (n×m×k) light emitting devices ED arranged in n rows and (mk) columns. Accordingly, the first sub-driving area SDA1 included in one unit driving area UDA can include (n×m×k) emission areas EA formed by (n×m×k) light emitting devices ED.

For example, a first sub-driving area SDA1 included in one unit driving area UDA can include (mk) light emitting device columns EDC(1) to EDC(mk) and n light emitting device rows EDR(1) to EDR(n). For example, the first sub-driving area SDA1 can include the first to (mk) light emitting device columns EDC(1) to EDC(mk). The first sub-driving area SDA1 can include the first to n-th light emitting device rows EDR(1) to EDR(n).

Each of the first to n-th light emitting device rows EDR(1) to EDR(n) can include (mk) light emitting devices. One row line RL can be arranged in each of the first to n-th light emitting device rows EDR(1) to EDR(n). For example, the number of types of colors of light emitted by the (mk) light emitting devices included in each of the first to n-th light emitting device rows EDR(1) to EDR(n) can be k.

Each of the first to (mk)-th light emitting device columns EDC(1) to EDC(mk) can include n light emitting devices. Each of the first to (mk)-th light emitting device columns EDC(1) to EDC(mk) can have one column line CL. For example, the n light emitting devices included in each of the first to (mk)-th light emitting device columns EDC(1) to EDC(mk) can emit light of the same color.

In the case of having a redundancy structure as illustrated in FIGS. 12 and 13, each of the first to (mk)-th light emitting device columns EDC(1) to EDC(mk) can include (2*n) light emitting devices. Each of the first to (mk)-th light emitting device columns EDC(1) to EDC(mk) can have two column lines CL. For example, the (2*n) light emitting devices included in each of the first to (mk)-th light emitting device columns EDC(1) to EDC(mk) can include n main light emitting devices and n redundancy light emitting devices. The two column lines CL arranged in each of the first to (mk)-th light emitting device columns EDC(1) to EDC(mk) can include a main column line and a redundancy column line.

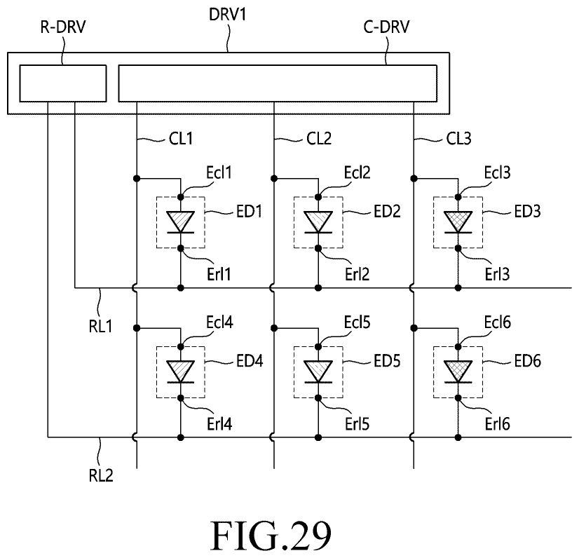

FIG. 29 is a plan view of a portion of a unit driving area UDA of a display device 100 according to embodiments of the present disclosure. FIGS. 1 to 28 are also referred to in the following description.

Referring to FIG. 29, a display area DA of a display device 100 according to embodiments of the present disclosure can include a plurality of light emitting devices ED1 to ED6.

The plurality of light emitting devices can include first to third light emitting devices ED1, ED2 and ED3 arranged in a first row (i.e., a first light emitting device row) and fourth to sixth light emitting devices ED4, ED5 and ED6 arranged in a second row (i.e., a second light emitting device row).

In the first row (i.e., the first light emitting device row), a first light emitting device ED1 can emit a first color light, the second light emitting device ED2 can emit a second color light, and the third light emitting device ED3 can emit a third color light.

In the second row (i.e., the second light emitting device row), the fourth light emitting device ED4 can emit a first color light, the fifth light emitting device ED5 can emit a second color light, and the sixth light emitting device ED6 can emit a third color light.

The fourth light emitting device ED4 can be arranged in the same column as the first light emitting device ED1, the fifth light emitting device ED5 can be arranged in the same column as the second light emitting device ED2, and the sixth light emitting device ED6 can be arranged in the same column as the third light emitting device ED3.

For example, the first color light, the second color light, and the third color light can be different color lights. In this case, the first color light, the second color light, and the third color light can be lights having different wavelengths. For example, the first color light can be red light, the second color light can be green light, and the third color light can be blue light. In this case, among the first color light, the second color light, and the third color light, the wavelength of the first color light can be the longest, and the wavelength of the third color light can be the shortest.

For example, the first light emitting device ED1 and the fourth light emitting device ED4 arranged in the first column (i.e., the first light emitting device column) can be light emitting devices that emit the first color light (EDa in FIG. 4). The second light emitting device ED2 and the fifth light emitting device ED5 arranged in the second column (i.e., the second light emitting device column) can be light emitting devices that equally emit the second color light (EDb in FIG. 4). The third light emitting device ED3 and the sixth light emitting device ED6 arranged in the third column (i.e., the third light emitting device column) can be light emitting devices that emit third color light (EDc in FIG. 4).

The display area DA of the display device 100 according to the embodiments of the present disclosure can include a first column line CL1 arranged in the first column (i.e., the first light emitting device column), a second column line CL2 arranged in the second column (i.e., the second light emitting device column), and a third column line CL3 arranged in the third column (i.e., the third light emitting device column).

The first column line CL1 corresponding to the first light emitting device column can be electrically connected in common with a first electrode Ecl1 of the first light emitting device ED1 and a first electrode Ecl4 of the fourth light emitting device ED4. The second column line CL2 corresponding to the second light emitting device column can be electrically connected in common with a first electrode Ecl2 of the second light emitting device ED2 and a first electrode Ecl5 of the fifth light emitting device ED5. The third column line CL3 corresponding to the third light emitting device column can be electrically connected in common with a first electrode Ecl3 of the third light emitting device ED3 and a first electrode Ecl6 of the sixth light emitting device ED6.

The display area DA of the display device 100 according to the embodiments of the present disclosure can include a first row line RL1 arranged in a first row (i.e., a first light emitting device row) and a second row line RL2 arranged in a second row (i.e., a second light emitting device row).

The first row line RL1 corresponding to the first light emitting device row can electrically connect a second electrode Erl1 of the first light emitting device ED1, a second electrode Erl2 of the second light emitting device ED2, and a second electrode Erl3 of the third light emitting device ED3 in common with the first driver DRV1.

The second row line RL2 corresponding to the second light emitting device row can electrically connect a second electrode Erl4 of the fourth light emitting device ED4, a second electrode Erl5 of the fifth light emitting device ED5, a second electrode Erl6 of the sixth light emitting device ED6 to the first driver DRV1.

The first row line RL1 can intersect the first column line CL1, the second column line CL2, and the third column line CL3, and the second row line RL2 can intersect the first column line CL1, the second column line CL2, and the third column line CL3.

The display area DA of the display device 100 according to the embodiments of the present disclosure can include a first driver DRV1 configured to drive a plurality of light emitting devices ED1 to ED6.

The first driver DRV1 can include a column driver C-DRV and a row driver R-DRV. The first driver DRV1 can be disposed in the display area DA.

The column driver C-DRV can be configured to drive the first electrode Ecl1 of the first light emitting device ED1, the first electrode Ecl2 of the second light emitting device ED2, and the first electrode Ecl3 of the third light emitting device ED3. The column driver C-DRV can be configured to further drive the first electrode Ecl4 of the fourth light emitting device ED4, the first electrode Ecl5 of the fifth light emitting device ED5, and the first electrode Ecl6 of the sixth light emitting device ED6.

The row driver R-DRV can be configured to drive the second electrode Erl1 of the first light emitting device ED1, the second electrode Erl2 of the second light emitting device ED2, and the second electrode Erl3 of the third light emitting device ED3. The row driver R-DRV can further be configured to drive the second electrode Erl4 of the fourth light emitting device ED4, the second electrode Erl5 of the fifth light emitting device ED5, and the second electrode Erl6 of the sixth light emitting device ED6.

The column driver C-DRV can drive the first electrode of each of the first to sixth light emitting devices ED1 to ED6 by driving the first column line CL1, the second column line CL2, and the third column line CL3.

The row driver R-DRV can drive the second electrode of each of the first to sixth light emitting devices ED1 to ED6 by driving the first row line RL1 and the second row line RL2.

For example, the row driver R-DRV can sequentially drive the first row line RL1 and the second row line RL2. At the timing when the first row line RL1 and the second row line RL2 are each driven by the row driver R-DRV, the column driver C-DRV can simultaneously drive the first column line CL1, the second column line CL2, and the third column line CL3.

During a first period, the first row line RL1 can have a first low-potential voltage VSS1, and the second row line RL2 can have a second low-potential voltage VSS2 (see FIG. 7 and FIG. 23). Here, the first period can be a display-on driving period of the first row line RL1 or a display-on driving period of the first to third light emitting devices ED1 to ED3 connected to the first row line RL1.

During a second period different from the first period, the first row line RL1 can have a second low-potential voltage VSS2, and the second row line RL2 can have a first low-potential voltage VSS1 (see FIG. 7 and FIG. 23). Here, the second period can be a display-on driving period of the second row line RL2 or a display-on driving period of the fourth to sixth light emitting devices ED4 to ED6 connected to the second row line RL2.

For example, the first low-potential voltage VSS1 can be a low-potential voltage for display-on driving. The second low-potential voltage VSS2 can be a low-potential voltage for display-off driving, and can be a voltage higher than the first low-potential voltage VSS1.

During the first period, at least one of the first light emitting device ED1, the second light emitting device ED2, and the third light emitting device ED3 can emit light. During the second period, at least one of the fourth light emitting device ED4, the fifth light emitting device ED5, and the sixth light emitting device ED6 can emit light.

Meanwhile, referring to the circuits of FIGS. 8 and 9 and the driving timing diagrams of FIGS. 25 and 26, during a reset period within the display driving period, a reset voltage VRST for resetting the first electrode of the light emitting device ED can be applied to the first electrode of the light emitting device ED or the column line CL connected thereto.

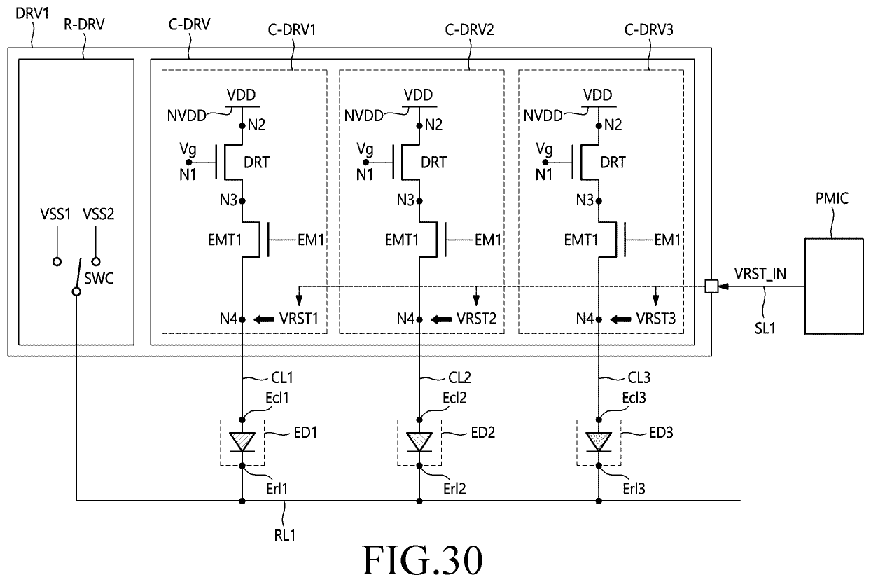

Hereinafter, it will be described a reset circuit for resetting the first electrode of each of the first to third light emitting devices ED1 to ED3 of FIG. 29 with reference to FIGS. 30 to 34. FIGS. 1 to 29 are also referred to in the following description. In particular, the description of the same content as that described with reference to FIG. 29 can be omitted.

FIG. 30 illustrates a common reset circuit structure of a display device 100 according to embodiments of the present disclosure.

Referring to FIG. 30, the first driver DRV1 can include a first column driver C-DRV1 configured to drive a first electrode Ecl1 of a first light emitting device ED1, a second column driver C-DRV2 configured to drive a first electrode Ecl2 of a second light emitting device ED2, and a third column driver C-DRV3 configured to drive a first electrode Ecl3 of a third light emitting device ED3.

Each of the first column driver C-DRV1, the second column driver C-DRV2, and the third column driver C-DRV3 can include a first node N1, a second node N2, a third node N3, and a fourth node N4.

The first node N1 can be a node to which a voltage Vg for controlling the on-off of a driving transistor DRT is applied. The second node N2 can be a node electrically connected to a high-potential voltage node NVDD to which a high-potential voltage VDD is applied. The third node N3 can be a node to which the driving transistor DRT and a first emission control transistor EMT1 are connected. The fourth node N4 can be a node to which the first emission control transistor EMT1 and the corresponding light emitting devices ED1, ED2 and ED3 are electrically connected, and can be a node to which the corresponding column lines CL1, CL2 and CL3 are electrically connected. Here, a source electrode or a drain electrode of the first emission control transistor EMT1 and the first electrodes Ecl1, Ecl2 and Ecl3 of the corresponding light emitting devices ED1, ED2 and ED3 can be commonly connected to the corresponding column lines CL1, CL2 and CL3.

Each of the first column driver C-DRV1, the second column driver C-DRV2, and the third column driver C-DRV3 can include a driving transistor DRT and the first emission control transistor EMT1.

In each of the first column driver C-DRV1, the second column driver C-DRV2, and the third column driver C-DRV3, the driving transistor DRT is controlled by the voltage Vg of the first node N1, and can be connected between the second node N2 and the third node N3.

In each of the first column driver C-DRV1, the second column driver C-DRV2, and the third column driver C-DRV3, the first emission control transistor EMT1 is turned on or off by a first emission control signal EM1, and can be connected between the third node N3 and the fourth node N4.

The fourth node N4 of the first column driver C-DRV1 can be electrically connected to the first electrode Ecl1 of the first light emitting device ED1 via the first column line CL1.

The fourth node N4 of the second column driver C-DRV2 can be electrically connected to the first electrode Ecl2 of the second light emitting device ED2 via the second column line CL2.

The fourth node N4 of the third column driver C-DRV3 can be electrically connected to the first electrode Ecl3 of the third light emitting device ED3 via the third column line CL3.

The circuit structures of each of the first column driver C-DRV1, the second column driver C-DRV2, and the third column driver C-DRV3 illustrated in FIG. 30 can be the same as FIG. 5, but this is only an example for convenience of explanation, and can be implemented with the circuit of FIG. 8 or 9. However, it is not limited thereto, and can be variously modified. For example, the circuit structures of each of the first column driver C-DRV1, the second column driver C-DRV2, and the third column driver C-DRV3 illustrated in FIG. 30 can further include at least one transistor or further include at least one capacitor.

Referring to FIG. 30, the first driver DRV1 can include a row driver R-DRV configured to drive the second electrode Erl1 of the first light emitting device ED1, drive the second electrode Erl2 of the second light emitting device ED2, and drive the second electrode Erl3 of the third light emitting device ED3.

The row driver R-DRV can drive the first row line RL1 that is electrically connected in common with the second electrode Erl1 of the first light emitting device ED1, the second electrode Erl2 of the second light emitting device ED2, and the second electrode Erl3 of the third light emitting device ED3.

In the case of the display driving, the row driver R-DRV can select one of the first low-potential voltage VSS1 that is a low-potential voltage for display-on driving and the second low-potential voltage VSS2 that is a low-potential voltage for display-off driving, and supply the selected voltage to the first row line RL1. To this end, the row driver R-DRV can include a switch circuit SWC that selects one of the first low-potential voltage VSS1 and the second low-potential voltage VSS2 and supplies the selected voltage to the first row line RL1. Here, the switch circuit SWC can be configured as the circuit configuration of FIG. 8 SW_ON(1)˜SW_ON(n), SW_OFF(1)˜SW_OFF(n) or the circuit configuration of FIG. 9 TR_ON(1)˜TR_ON(n), TR_OFF(1)˜TR_OFF(n).

The first driver DRV1 can receive an input reset voltage VRST_IN, output a first reset voltage VRST1 for resetting the first electrode Ecl1 of the first light emitting device ED1 during the first reset period (tRSTa of FIG. 25) to the first column line CL1 or the fourth node N4 electrically connected thereto, output a second reset voltage VRST2 for resetting the first electrode Ecl2 of the second light emitting device ED2 during the second reset period (tRSTb of FIG. 25) to the second column line CL2 or the fourth node N4 electrically connected thereto, and output a third reset voltage VRST3 for resetting the first electrode Ecl3 of the third light emitting device ED3 during the third reset period (tRSTc of FIG. 25) to the third column line CL3 or the fourth node N4 electrically connected thereto.

The first driver DRV1 can receive an input reset voltage VRST_IN from a power management integrated circuit (PMIC) through a first signal line SL1.

As described above with reference to FIG. 25, the first to third reset periods tRSTa, tRSTb and tRSTc for the first to third light emitting devices ED1, ED2 and ED3 can each follow the emission periods tEMa, tEMb and tEMc for the first to third light emitting devices ED1, ED2 and ED3.

Therefore, by the column driver C-DRV1, the first reset voltage VRST1 can be applied to the first electrode Ecl1 of the first light emitting device ED1 after the first light emitting device ED1 emits light, a second reset voltage VRST2 can be applied to the first electrode Ecl2 of the second light emitting device ED2 after the second light emitting device ED2 emits light, and a third reset voltage VRST3 can be applied to the first electrode Ecl3 of the third light emitting device ED3 after the third light emitting device ED3 emits light.

Referring to FIGS. 25 and 30, according to the driving method of the display device 100 according to the embodiments of the present disclosure, a first display driving period Da for driving the first light emitting device ED1 can include a first emission period tEMa in which the first light emitting device ED1 emits light, and a first reset period tRSTa in which the first electrode Ecl1 of the first light emitting device ED1 is reset with the first reset voltage VRST1 (the first electrode Ecl1 of the first light emitting device ED1 is reset to the first reset voltage VRST1). A second display driving period Db for driving the second light emitting device ED2 can include a second emission period tEMb in which the second light emitting device ED2 emits light, and a second reset period tRSTb in which the first electrode Ecl2 of the second light emitting device ED2 is reset to a second reset voltage VRST2. A third display driving period Dc for driving the third light emitting device ED3 can include a third emission period tEMc in which the third light emitting device ED3 emits light, and a third reset period tRSTe in which the first electrode Ecl3 of the third light emitting device ED3 is reset to a third reset voltage VRST3.

The first reset period tRSTa can follow the first emission period tEMa, the second reset period tRSTb can follow the second emission period tEMb, and the third reset period tRSTc can follow the third emission period tEMc.

Among a starting time of the first reset period tRSTa, a starting time of the second reset period tRSTb, and a starting time of the third reset period tRSTc, at least one can be different from the others. For example, the starting time of the first reset period tRSTa, the starting time of the second reset period tRSTb, and the starting time of the third reset period tRSTc can all be different from each other.

Among a starting time of the first emission period tEMa, a starting time of the second emission period tEMb, and a starting time of the third emission period tEMc, at least one can be different from the others. For example, the starting time of the first emission period tEMa, the starting time of the second emission period tEMb, and the starting time of the third emission period tEMc can all be different from each other.

Among a length PWa of the first emission period tEMa, a length PWb of the second emission period tEMb, and a length PWc of the third emission period tEMc, at least one can be different from the others. For example, the length PWa of the first emission period tEMa, the length PWb of the second emission period tEMb, and the length PWc of the third emission period tEMc can all be different from each other.

Referring to FIG. 30, the display device 100 according to the embodiments of the present disclosure can have a common reset circuit structure. According to the common reset circuit structure according to the embodiments of the present disclosure, the first reset voltage VRST1, the second reset voltage VRST2, and the third reset voltage VRST3 can be equal to or substantially equal to the input reset voltage VRST_IN. Accordingly, the first reset voltage VRST1, the second reset voltage VRST2, and the third reset voltage VRST3 can all be the same or substantially the same.

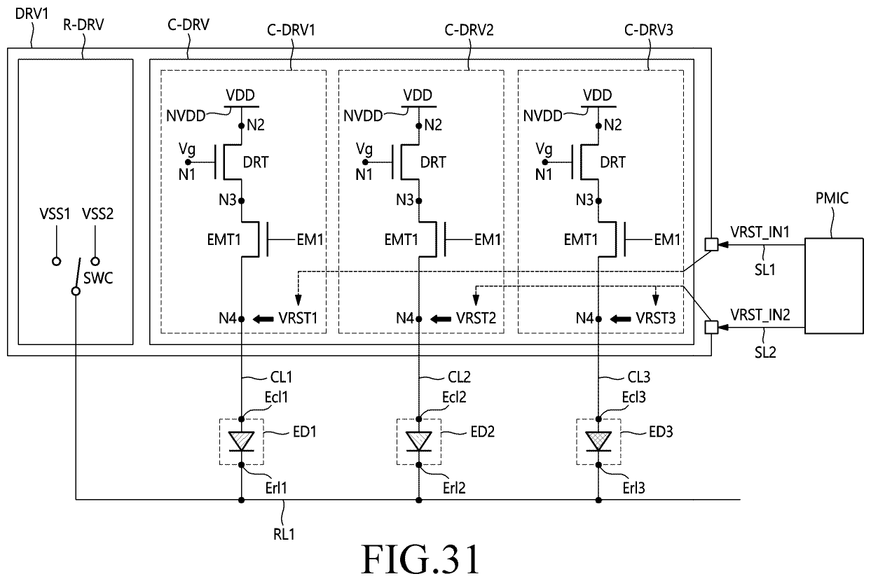

Hereinafter, it will be described an improved reset circuit structure compared to the common reset circuit structure according to embodiments of the present disclosure with reference to FIGS. 31 to 34.

FIGS. 31 to 34 illustrate an improved reset circuit structure of a display device 100 according to embodiments of the present disclosure and the corresponding reset voltages.

Referring to FIGS. 31 to 34, the first driver DRV1 can receive two or more input reset voltages “VRST_IN1 and VRST_IN2”, or “VRST_IN1, VRST_IN2, and VRST_IN3” for resetting each of the first electrode Ecl1 of the first light emitting device ED1, the first electrode Ecl2 of the second light emitting device ED2, and the first electrode Ecl3 of the third light emitting device ED3.

The two or more input reset voltages “VRST_IN1 and VRST_IN2”, or “VRST_IN1, VRST_IN2, and VRST_IN3” input to the first driver DRV1 can have different voltage values.

The first driver DRV1 can output a first reset voltage VRST1, a second reset voltage VRST2, and a third reset voltage VRST3 by using two or more input reset voltages “VRST_IN1 and VRST_IN2”, or “VRST_IN1, VRST_IN2, and VRST_IN3”.

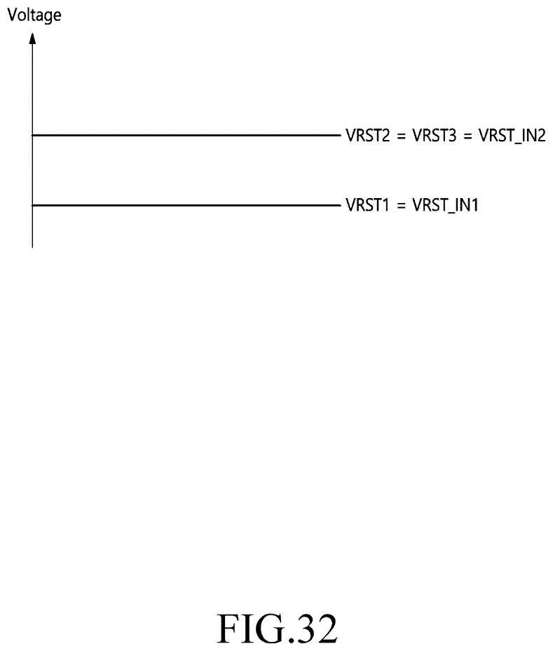

For example, as illustrated in FIGS. 31 and 32, the first driver DRV1 can receive two different input reset voltages VRST_IN1 and VRST_IN2, and output a first reset voltage VRST1, a second reset voltage VRST2, and a third reset voltage VRST3. In this case, the first reset voltage VRST1 can be the same as the first input reset voltage VRST_IN1, and the second reset voltage VRST2 and the third reset voltage VRST3 can each be the same as the second input reset voltage VRST_IN2. For example, the second reset voltage VRST2 and the third reset voltage VRST3 can be the same, and the first reset voltage VRST1 can be different from the second reset voltage VRST2 and the third reset voltage VRST3.

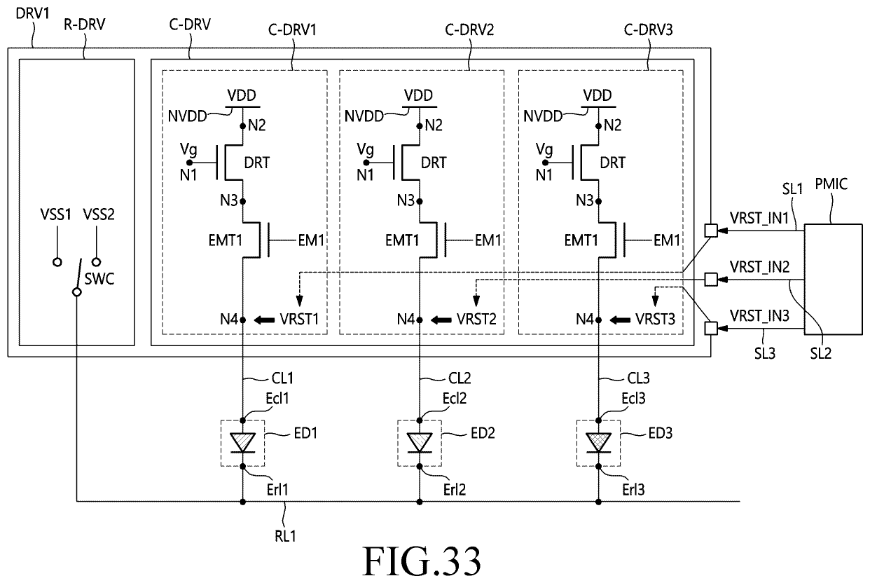

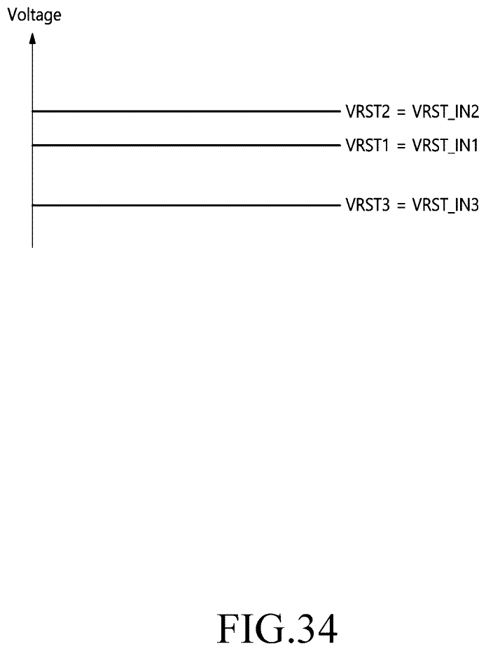

As another example, as illustrated in FIG. 33 and FIG. 34, the first driver DRV1 can receive three different input reset voltages VRST_IN1, VRST_IN2 and VRST_IN3, and output the first reset voltage VRST1, the second reset voltage VRST2, and the third reset voltage VRST3. In this case, the first reset voltage VRST1 can be the same as the first input reset voltage VRST_IN1, the second reset voltage VRST2 can be the same as the second input reset voltage VRST_IN2, and the third reset voltage VRST3 can be the same as the third input reset voltage VRST_IN3. For example, the first reset voltage VRST1, the second reset voltage VRST2, and the third reset voltage VRST3 can all be different from each other.

In the display device 100 according to the embodiments of the present disclosure, each of the first to third light emitting devices ED1, ED2 and ED3 can have different types of color light, and thus can have different luminance characteristics. Here, the luminance characteristics can include a luminance ratio according to a change in grayscale or gradation.

According to the improved reset circuit structure of the display device 100 according to the embodiments of the present disclosure, there can be provided a reset function suitable for different luminance characteristics of the first to third light emitting devices ED1, ED2 and ED3. Accordingly, the emission performance of the first to third light emitting devices ED1, ED2 and ED3 can be improved, thereby improving image quality.

The improved reset circuit structure according to the embodiments of the present disclosure can include a dual reset circuit structure and an individual reset circuit structure (also referred to as a triple reset circuit structure). Hereinafter, the dual reset circuit structure according to the embodiments of the present disclosure will be described with reference to FIGS. 31 and 32, and the individual reset circuit structure will be described with reference to FIGS. 33 and 34. The description of the same contents among the above can be omitted.

FIGS. 31 and 32 illustrate the dual reset circuit structure of the display device 100 according to the embodiments of the present disclosure and the corresponding reset voltages.

Referring to FIG. 31, the first driver DRV1 can receive a first input reset voltage VRST_IN1 and a second input reset voltage VRST_IN2 to reset each of the first electrode Ecl1 of the first light emitting device ED1, the first electrode Ecl2 of the second light emitting device ED2, and the first electrode Ecl3 of the third light emitting device ED3.

Referring to FIG. 32, the first input reset voltage VRST_IN1 and the second input reset voltage VRST_IN2 can have different voltage values. For example, the second input reset voltage VRST_IN2 can be higher than the first input reset voltage VRST_IN1.

Referring to FIGS. 31 and 32, the first driver DRV1 can receive a first input reset voltage VRST_IN1 from a power management integrated circuit PMIC through a first signal line SL1, and can receive a second input reset voltage VRST_IN2 different from the first input reset voltage VRST_IN1 from the power management integrated circuit PMIC through a second signal line SL2.

The first reset voltage VRST1 can correspond to the first input reset voltage VRST_IN1, and the second reset voltage VRST2 and the third reset voltage VRST3 can each correspond to the second input reset voltage VRST_IN2.

Referring to FIG. 31 and FIG. 32 together with FIG. 25, a first reset period tRSTa for resetting the first electrode Ecl1 of the first light emitting device ED1 can follow the first emission period tEMa of the first light emitting device ED1. Accordingly, after the first light emitting device ED1 emits light, a first reset voltage VRST1 can be applied to the first electrode Ecl1 of the first light emitting device ED1.

The second reset period tRSTb for resetting the first electrode Ecl2 of the second light emitting device ED2 can follow the second emission period tEMb of the second light emitting device ED2. Accordingly, after the second light emitting device ED2 emits light, a second reset voltage VRST2 can be applied to the first electrode Ecl2 of the second light emitting device ED2.

Referring to FIG. 32, the second reset voltage VRST2 and the third reset voltage VRST3 can be the same. Each of the second reset voltage VRST2 and the third reset voltage VRST3 can be different from the first reset voltage VRST1. For example, the second reset voltage VRST2 and the third reset voltage VRST3 can be the same, and each of the second reset voltage VRST2 and the third reset voltage VRST3 can be higher than the first reset voltage VRST1 (i.e., VRST1<VRST2, VRST1<VRST3, VRST2=VRST3).

In this case, a first wavelength of the first color light emitted from the first light emitting device ED1 can be longer than a second wavelength of the second color light emitted from the second light emitting device ED2 and a third wavelength of the third color light emitted from the third light emitting device ED3.

In addition, the second wavelength of the second color light emitted from the second light emitting device ED2 can be longer than the third wavelength of the third color light emitted from the third light emitting device ED3.

In the above, the dual reset circuit structure of the display device 100 according to the embodiments of the present disclosure has been described with reference to FIGS. 31 and 32. Hereinafter, the individual reset circuit structure of the display device 100 according to the embodiments of the present disclosure will be described with reference to FIGS. 33 and 34. In the following description, description of the same contents among the above-mentioned contents can be omitted.

FIG. 33 and FIG. 34 illustrate individual reset circuit structures of a display device 100 according to embodiments of the present disclosure and the corresponding reset voltages.

Referring to FIG. 33, the first driver DRV1 can receive three input reset voltages VRST_IN1, VRST_IN2 and VRST_IN3 to reset each of the first electrode Ecl1 of the first light emitting device ED1, the first electrode Ecl2 of the second light emitting device ED2, and the first electrode Ecl3 of the third light emitting device ED3. The three input reset voltages can include a first input reset voltage VRST_IN1, a second input reset voltage VRST_IN2, and a third input reset voltage VRST_IN3.

The first driver DRV1 can receive the first input reset voltage VRST_IN1 through the first signal line SL1, the second input reset voltage VRST_IN2 through the second signal line SL2, and the third input reset voltage VRST_IN3 through a third signal line SL3.

Referring to FIG. 33, the first driver DRV1 can receive the first input reset voltage VRST_IN1, the second input reset voltage VRST_IN2, and the third input reset voltage VRST_IN3, and can output a first reset voltage VRST1 corresponding to the first input reset voltage VRST_IN1, a second reset voltage VRST2 corresponding to the second input reset voltage VRST_IN2, and a third reset voltage VRST3 corresponding to the third input reset voltage VRST_IN3.

The first column driver C-DRV1 can output the first reset voltage VRST1 to the fourth node N4 based on the first input reset voltage VRST_IN1. The first reset voltage VRST1 output to the fourth node N4 of the first column driver C-DRV1 can be input to a first column line CL1 electrically connected with the fourth node N4 of the first column driver C-DRV1, and the first reset voltage VRST1 input to the first column line CL1 can be applied to the first electrode Ecl1 of the first light emitting device ED1 electrically connected to the first column line CL1.

The second column driver C-DRV2 can output the second reset voltage VRST2 to the fourth node N4 based on the second input reset voltage VRST_IN2. The second reset voltage VRST2 output to the fourth node N4 of the second column driver C-DRV2 can be input to a second column line CL2 electrically connected with the fourth node N4 of the second column driver C-DRV2, and the second reset voltage VRST2 input to the second column line CL2 can be applied to the first electrode Ecl2 of the second light emitting device ED2 electrically connected to the second column line CL2.

The third column driver C-DRV3 can output the third reset voltage VRST3 to the fourth node N4 based on the third input reset voltage VRST_IN3. The third reset voltage VRST3 output to the fourth node N4 of the third column driver C-DRV3 can be input to a third column line CL3 electrically connected with the fourth node N4 of the third column driver C-DRV3, and the third reset voltage VRST3 input to the third column line CL3 can be applied to the first electrode Ecl3 of the third light emitting device ED3 electrically connected to the third column line CL3.

Referring to FIGS. 33 and 34 together with FIG. 25, after the first emission period tEMa of the first light emitting device ED1, a first reset period tRSTa for resetting the first electrode Ecl1 of the first light emitting device ED1 can proceed. Accordingly, after the first light emitting device ED1 emits light, a first reset voltage VRST1 can be applied to the first electrode Ecl1 of the first light emitting device ED1.

After the second emission period tEMb of the second light emitting device ED2, a second reset period tRSTb for resetting the first electrode Ecl2 of the second light emitting device ED2 can proceed. Accordingly, after the second light emitting device ED2 emits light, a second reset voltage VRST2 can be applied to the first electrode Ecl2 of the second light emitting device ED2.

After the third emission period tEMc of the third light emitting device ED3, a third reset period tRSTc for resetting the first electrode Ecl3 of the third light emitting device ED3 can proceed. Accordingly, after the third light emitting device ED3 emits light, a third reset voltage VRST3 can be applied to the first electrode Ecl3 of the third light emitting device ED3.

According to the individual reset circuit structure of the display device 100 according to the embodiments of the present disclosure, the first input reset voltage VRST_IN1, the second input reset voltage VRST_IN2, and the third input reset voltage VRST_IN3 can all have different voltage values.

According to the individual reset circuit structure of the display device 100 according to the embodiments of the present disclosure, the first reset voltage VRST1, the second reset voltage VRST2, and the third reset voltage VRST3 can all be different from each other.

Referring to FIG. 34, for example, the second input reset voltage VRST_IN2 can be higher than the first input reset voltage VRST_IN1, and the first input reset voltage VRST_IN1 can be higher than the third input reset voltage VRST_IN3. This voltage magnitude relationship is only an example, and is not limited thereto.

Accordingly, the second reset voltage VRST2 can be higher than the first reset voltage VRST1, and the first reset voltage VRST1 can be higher than the third reset voltage VRST3. This voltage magnitude relationship is only an example, and is not limited thereto.

For example, the first wavelength of the first color light can be longer than the second wavelength of the second color light, and the second wavelength of the second color light can be longer than the third wavelength of the third color light. For example, the first color light can be red light, the second color light can be green light, and the third color light can be blue light.

As described above, each of the plurality of unit driving areas UDA included in the display area DA of the display panel 110 can include one driver DRV among the plurality of drivers, a plurality of light emitting devices ED, a plurality of row lines RL, and a plurality of column lines CL.

The first to third light emitting devices ED1, ED2 and ED3, the first to third column lines CL1, CL2 and CL3, the first and second row lines RL1 and RL2, and the first driver DRV1 shown in FIG. 29 can be included in one first unit driving area UDA among a plurality of unit driving areas UDA included in the display area DA of the display panel 110.

In the first unit driving area UDA, the first to third column lines CL1, CL2 and CL3 and the first and second row lines RL1 and RL2 can intersect each other.

As described above, the driving period of at least one of the first row line RL1 and the second row line RL2 can include a first period (e.g., a display-on driving period) in which a first voltage (e.g., a first low-potential voltage VSS1) is applied, a second period (e.g., a display-off driving period) in which a second voltage (e.g., a second low-potential voltage VSS2) higher than the first voltage is applied, and a third period (e.g., a touch driving period) in which a signal having a variable voltage level (e.g., a touch driving signal TDS) is applied. Here, the lowest voltage of the signal having a variable voltage level in the third period can be higher than the first voltage. Accordingly, it is possible to prevent unwanted light emission of the light emitting device ED during the third period (e.g., the touch driving period).

Hereinafter, it will be briefly described again the dual reset circuit structure (FIG. 31) according to the embodiments of the present disclosure described above and the individual reset circuit structure (FIG. 33) according to the embodiments of the present disclosure.

A display device 100 according to embodiments of the present disclosure can include a first light emitting device ED1 emitting a first color light, a second light emitting device ED2 emitting a second color light, a third light emitting device ED3 emitting a third color light, a first column line CL1 electrically connected to a first electrode Ecl1 of the first light emitting device ED1, a second column line CL2 electrically connected to a first electrode Ecl2 of the second light emitting device ED2, a third column line CL3 electrically connected to a first electrode Ecl3 of the third light emitting device ED3, and a first row line RL1 electrically connected in common with a second electrode Erl1 of the first light emitting device ED1, a second electrode Erl2 of the second light emitting device ED2 and a second electrode Erl3 of the third light emitting device ED3.

After the first light emitting device ED1 emits light, a first reset voltage VRST1 can be applied to the first column line CL1. After the second light emitting device ED2 emits light, a second reset voltage VRST2 can be applied to the second column line CL2. After the third light emitting device ED3 emits light, a third reset voltage VRST3 can be applied to the third column line CL3.

According to the dual reset circuit structure (FIG. 31) according to the embodiments of the present disclosure or the individual reset circuit structure (FIG. 33) according to the embodiments of the present disclosure, two or more of the first reset voltage VRST1, the second reset voltage VRST2, and the third reset voltage VRST3 can be different from each other.

For example, among the first reset voltage VRST1, the second reset voltage VRST2, and the third reset voltage VRST3, the second reset voltage VRST2 and the third reset voltage VRST3 can be the same or substantially the same, and the first reset voltage VRST1 can be different from the second reset voltage VRST2 and the third reset voltage VRST3. For example, each of the second reset voltage VRST2 and the third reset voltage VRST3 can be higher than the first reset voltage VRST1.

In another example, the first reset voltage VRST1, the second reset voltage VRST2, and the third reset voltage VRST3 can all be different from each other.

For example, the first wavelength of the first color light can be longer than the second wavelength of the second color light, and the second wavelength of the second color light can be longer than the third wavelength of the third color light. For example, the second reset voltage VRST2 can be higher than the first reset voltage VRST1, and the first reset voltage VRST1 can be higher than the third reset voltage VRST3.

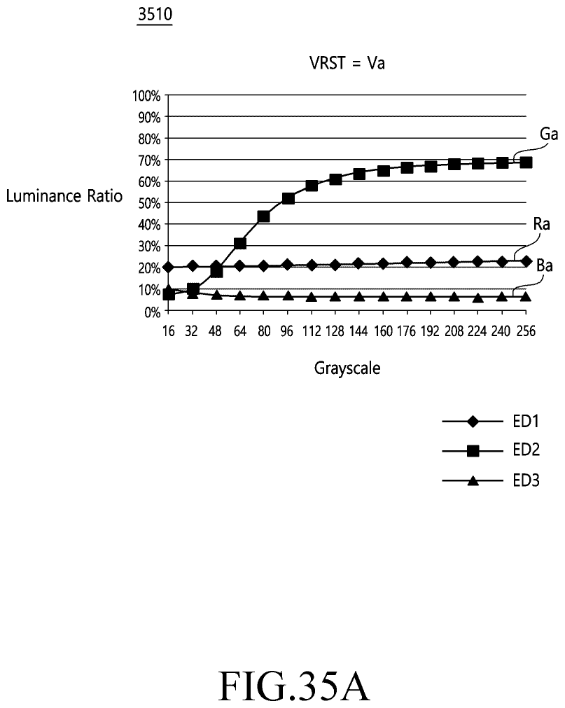

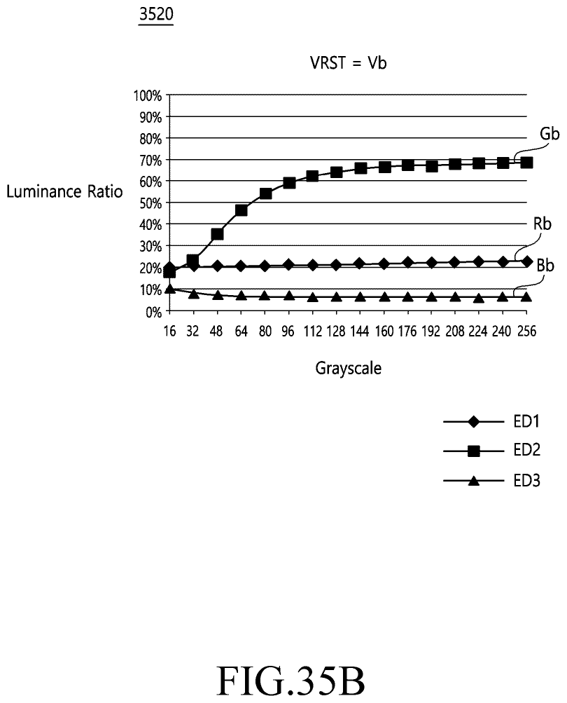

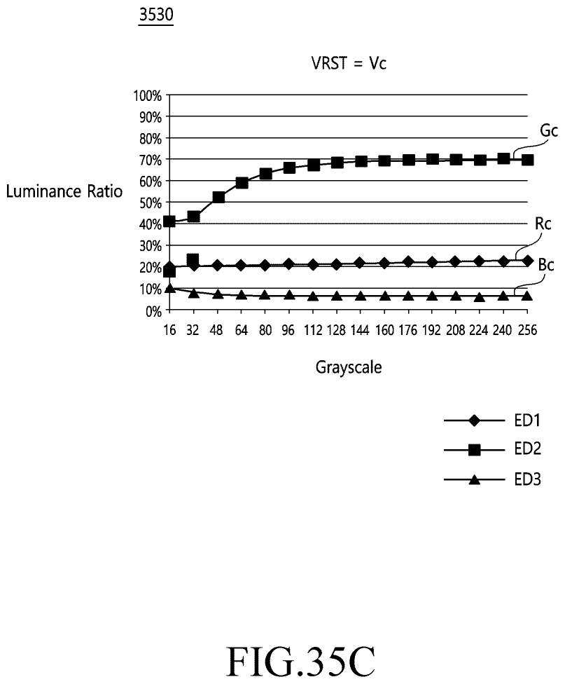

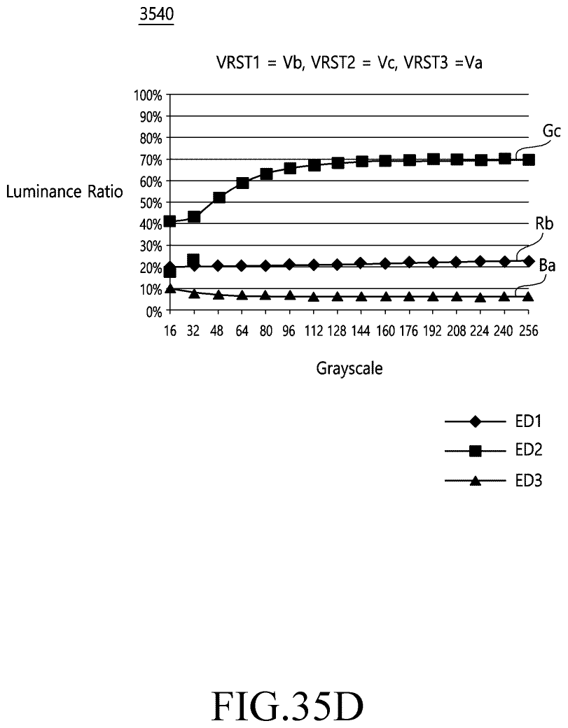

FIGS. 35A, 35B, 35C, and 35D illustrate first to fourth graphs 3510, 3520, 3530 and 3540 related to setting of optimal values of the first to third reset voltages VRST1, VRST2 and VRST3 corresponding to the first to third light emitting devices, respectively, in a display device according to embodiments of the present disclosure.

In FIG. 35A, the first graph 3510 shows a luminance ratio according to the change in grayscale (e.g., 256-step grayscale change) for each of the first to third light emitting devices ED1, ED2 and ED3 in the case that the first electrodes Ecl1, Ecl2 and Ecl3 of the first to third light emitting devices ED1, ED2 and ED3 are reset and driven using a reset voltage VRST having a first voltage value Va.

For example, the first light emitting device ED1 can emit red light, the second light emitting device ED2 can emit green light, and the third light emitting device ED3 can emit blue light. White light can be expressed through the light emission from the first to third light emitting devices ED1, ED2 and ED3. If a luminance of white light at the brightest grayscale is 100%, a luminance or a brightness of each of the first to third light emitting devices ED1, ED2 and ED3 can be expressed as a value between 0 and 100%, and this value can be referred to as a luminance ratio (or brightness ratio). For example, the luminance ratio can be a ratio of a luminance of each of the first to third light emitting devices ED1, ED2 and ED3 to a luminance of white light at the brightest grayscale (e.g., 100%).

In FIG. 35B, the second graph 3520 shows a luminance ratio according to the change in grayscale (e.g., 256-step grayscale change) for each of the first to third light emitting devices ED1, ED2 and ED3 when the first electrodes Ecl1, Ecl2 and Ecl3 of the first to third light emitting devices ED1, ED2 and ED3 are reset and driven using a reset voltage VRST having a second voltage value Vb. Here, the second voltage value Vb can be a higher voltage value than the first voltage value Va.

In FIG. 35C, the third graph 3530 shows the luminance ratio according to the grayscale change (e.g., 256-step grayscale change) for each of the first to third light emitting devices ED1, ED2 and ED3 when the first electrodes Ecl1, Ecl2 and Ecl3 of the first to third light emitting devices ED1, ED2 and ED3 are reset and driven using a reset voltage VRST having a third voltage value Vc. Here, the third voltage value Ve can be a higher voltage value than the second voltage value Vb.

In FIG. 35D, the fourth graph 3540 shows the luminance ratio according to the grayscale change (e.g., 256-step grayscale change) for each of the first to third light emitting devices ED1, ED2 and ED3 in the case that the first to third reset voltages VRST1, VRST2 and VRST3 are set according to the individual reset structure circuit.

Referring to the first graph 3510 of FIG. 35A, a luminance ratio Ra according to the change in grayscale of the first light emitting device ED1 can vary in a range (e.g., luminance ratio range) between 20% and 23%, the luminance ratio Ga according to the change in grayscale of the second light emitting device ED2 can vary in a range (e.g., luminance ratio range) between 8% and 69%, and the luminance ratio Ba according to the change in grayscale of the third light emitting device ED3 can vary in a range (e.g., luminance ratio range) between 6% and 10%.

Referring to the first graph 3510 of FIG. 35A, an amount of the change in the luminance ratio of the first light emitting device ED1 can be 3% p (e.g., 23%-20%), an amount of the change in the luminance ratio of the second light emitting device ED2 can be 61% p (e.g., 69%-8%), and an amount of the change in the luminance ratio of the third light emitting device ED3 can be 4% p (e.g., 10%-6%). Here, a unit of the luminance ratio change amount can be a percentage point (% p) representing the arithmetic difference between two percentages.

Referring to the second graph 3520 of FIG. 35B, the luminance ratio Rb according to the change in grayscale of the first light emitting device ED1 can vary in a range (e.g., luminance ratio range) between 23% and 24%, the luminance ratio Gb according to the change in grayscale of the second light emitting device ED2 can vary in a range (e.g., luminance ratio range) between 18% and 69%, and the luminance ratio Bb according to the change in grayscale of the third light emitting device ED3 can vary in a range (e.g., luminance ratio range) between 6% and 12%.

Referring to the second graph 3520 of FIG. 35B, an amount of the change in the luminance ratio of the first light emitting device ED1 can be 1% p (e.g., 24%-23%), an amount of the change in the luminance ratio of the second light emitting device ED2 can be 51% p (e.g., 69%-18%), and an amount of the change in the luminance ratio of the third light emitting device ED3 can be 6% p (e.g., 12%-6%).

Referring to the third graph 3530 of FIG. 35C, the luminance ratio Rc according to the change in grayscale of the first light emitting device ED1 can vary in a range (e.g., luminance ratio range) between 22% and 23%, the luminance ratio Gc according to the change in grayscale of the second light emitting device ED2 can vary in a range (e.g., luminance ratio range) between 41% and 70%, and the luminance ratio Bc according to the change in grayscale of the third light emitting device ED3 can vary in a range (e.g., luminance ratio range) between 6% and 18%.

Referring to the third graph 3530 of FIG. 35C, an amount of the change in the luminance ratio of the first light emitting device ED1 can be 1% p (e.g., 23%-22%), an amount of the change in the luminance ratio of the second light emitting device ED2 can be 29% p (e.g., 70%-41%), and an amount of the change in the luminance ratio of the third light emitting device ED3 can be 12% p (e.g., 18%-6%).

Referring to FIGS. 35A, 35B, and 35C, in the case of the first light emitting device ED1, an amount of the change in the luminance ratio can be the smallest when driven using the reset voltage VRST of the second voltage value Vb. In the case of the second light emitting device ED2, an amount of the change in the luminance ratio can be the smallest when driven using the reset voltage VRST of the third voltage value Vc. In the case of the third light emitting device ED3, an amount of the change in the luminance ratio can be the smallest when driven using the reset voltage VRST of the first voltage value Va.

Referring to FIGS. 35A, 35B, and 35C, if the first to third reset voltages VRST1, VRST2 and VRST3 for resetting the first electrodes Ecl1, Ecl2 and Ecl3 of the first to third light emitting devices ED1, ED2 and ED3 are set to any one of the first to third voltage values Va, Vb and Vc, an amount of the change in the luminance ratio of at least one of the first to third light emitting devices ED1, ED2 and ED3 can be greater than an amount of the change in the luminance ratio when set to a different voltage value. This phenomenon can be referred to as a “luminance ratio collapse phenomenon.” The luminance ratio collapse phenomenon can cause a deterioration in image quality.

Referring to FIGS. 35A, 35B, and 35C, an amount of the change in the luminance ratio according to the grayscale change of the second light emitting device ED2 can be greater than an amount of the change in the luminance ratio according to the grayscale change of the first light emitting device ED1 and an amount of the change in the luminance ratio according to the grayscale change of the third light emitting device ED3. Therefore, according to the common reset circuit structure, the luminance ratio collapse phenomenon of at least one of the first to third light emitting devices ED1, ED2 and ED3 emitting different color lights can be further increased.

However, according to the individual reset circuit structure according to the embodiments of the present disclosure, referring to FIG. 35D, the first reset voltage VRST1 for resetting the first electrode Ecl1 of the first light emitting device ED1 can be set to a second voltage value Vb that minimizes an amount of the change in the luminance ratio of the first light emitting device ED1, the second reset voltage VRST2 for resetting the first electrode Ec12 of the second light emitting device ED2 can be set to a third voltage value Vc that minimizes an amount of the change in the luminance ratio of the second light emitting device ED2, and the third reset voltage VRST3 for resetting the first electrode Ecl3 of the third light emitting device ED3 can be set to a first voltage value Va that minimizes the amount of the change in the luminance ratio of the third light emitting device ED3.

Therefore, it is possible to reduce the luminance ratio collapse phenomenon of each of the first to third light emitting devices ED1, ED2 and ED3 emitting different color light, thereby improving image quality.

The display device 100 according to the embodiments of the present disclosure described above can be applied to various types of devices. Hereinafter, various devices to which the display device 100 according to the embodiments of the present disclosure is applied will be described.

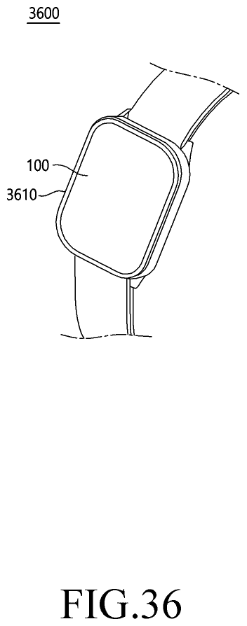

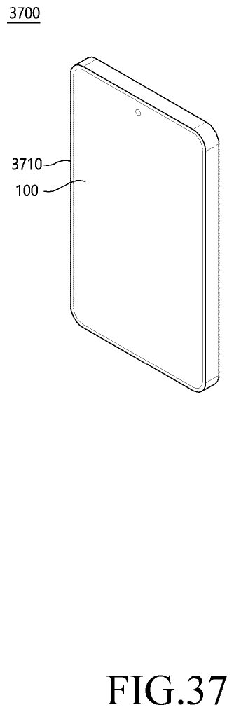

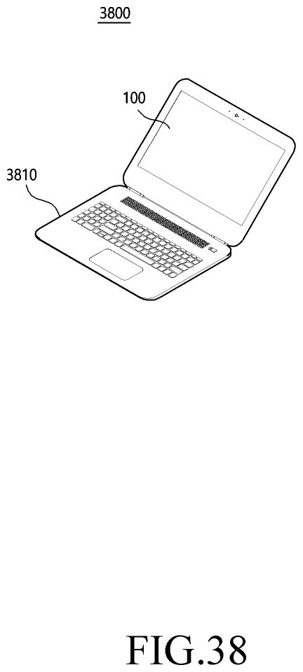

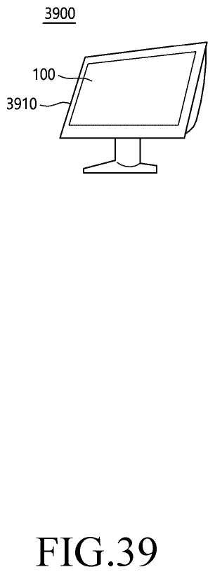

FIGS. 36 to 39 illustrate various devices 3600, 3700, 3800 and 3900 to which the display device 100 according to the embodiments of the present disclosure is applied.

Referring to FIGS. 36 to 39, the display device 100 according to the embodiments of the present disclosure can be included in various devices or electronic devices. For example, referring to FIGS. 36 to 39, the various electronic devices can include a wearable device 3600, a mobile device 3700, a notebook 3800, and a monitor or television (TV) 3900, but the embodiments of the present disclosure are not limited thereto.

Each of the wearable device 3600, the mobile device 3700, the notebook 3800, and the monitor or TV 3900 can include the display device 100 according to the embodiments of the present disclosure described with reference to FIGS. 1 to 35D, and a case unit 3610, 3710, 3810 and 3910.

For example, the display device 100 according to the embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a notebook, a monitor, a camera, a camcorder, and home appliances.

A display device according to embodiments of the present disclosure can be described as follows.

A display device according to embodiments of the present disclosure can include a first light emitting device arranged in a display area and emitting a first color light, a second light emitting device arranged in the display area and emitting a second color light, a third light emitting device arranged in the display area and emitting a third color light, and a first driver configured to drive the first light emitting device, the second light emitting device, and the third light emitting device.

According to aspects of the present disclosure, the first driver can receive two or more input reset voltages for resetting each of a first electrode of the first light emitting device, a first electrode of the second light emitting device, and a first electrode of the third light emitting device. The two or more input reset voltages can have different voltage values.

According to aspects of the present disclosure, a first display driving period for driving the first light emitting device can include a first emission period in which the first light emitting device emits light and a first reset period in which the first electrode of the first light emitting device is reset to a first reset voltage. A second display driving period for driving the second light emitting device can include a second emission period in which the second light emitting device emits light and a second reset period in which the first electrode of the second light emitting device is reset to a second reset voltage. A third display driving period for driving the third light emitting device can include a third emission period in which the third light emitting device emits light and a third reset period in which the first electrode of the third light emitting device is reset to a third reset voltage.

According to aspects of the present disclosure, the first reset period can follow the first emission period, the second reset period can follow the second emission period, and the third reset period can follow the third emission period. Among a starting time of the first reset period, a starting time of the second reset period, and a starting time of the third reset period, at least one can be different from the rest.

According to aspects of the present disclosure, among a starting time of the first emission period, a starting time of the second emission period, and a starting time of the third emission period, at least one can be different from the rest. Among a length of the first emission period, a length of the second emission period, and a length of the third emission period, at least one can be different from the rest.

According to aspects of the present disclosure, a first reset voltage can be applied to the first electrode of the first light emitting device after the first light emitting device emits light, a second reset voltage can be applied to the first electrode of the second light emitting device after the second light emitting device emits light, and a third reset voltage can be applied to the first electrode of the third light emitting device after the third light emitting device emits light. At least two of the first reset voltage, the second reset voltage, and the third reset voltage can be different from each other.

For example, the first driver can receive a first input reset voltage and a second input reset voltage different from the first input reset voltage, output the first reset voltage corresponding to the first input reset voltage, and output the second reset voltage and the third reset voltage each corresponding to the second input reset voltage.

In this case, the second input reset voltage can be higher than the first input reset voltage. A first wavelength of the first color light can be longer than a second wavelength of the second color light and a third wavelength of the third color light.

For another example, the first driver can receive a first input reset voltage, a second input reset voltage, and a third input reset voltage different from each other, output the first reset voltage corresponding to the first input reset voltage, output the second reset voltage corresponding to the second input reset voltage, and output the third reset voltage corresponding to the third input reset voltage.

In this case, the second input reset voltage can be higher than the first input reset voltage, and the first input reset voltage can be higher than the third input reset voltage. The first wavelength of the first color light can be longer than a second wavelength of the second color light, and the second wavelength of the second color light can be longer than a third wavelength of the third color light.

According to aspects of the present disclosure, an amount of change in luminance ratio according to a change in grayscale of the second light emitting device can be greater than an amount of change in luminance ratio according to the change in grayscale of the first light emitting device and an amount of change in luminance ratio according to the change in grayscale of the third light emitting device.

According to aspects of the present disclosure, the first driver can include a first column driver configured to drive the first electrode of the first light emitting device, a second column driver configured to drive the first electrode of the second light emitting device, and a third column driver configured to drive the first electrode of the third light emitting device. The first driver can be disposed in the display area.

According to aspects of the present disclosure, each of the first column driver, the second column driver and the third column driver can include a first node, a second node, a third node, and a fourth node, a driving transistor controlled by a voltage of the first node and connected between the second node and the third node, and a first emission control transistor turned on or off by a first emission control signal and connected between the third node and the fourth node.

According to aspects of the present disclosure, a fourth node of the first column driver can be electrically connected to the first electrode of the first light emitting device, a fourth node of the second column driver can be electrically connected to the first electrode of the second light emitting device, and a fourth node of the third column driver can be electrically connected to the first electrode of the third light emitting device.

The display device according to embodiments of the present disclosure can further include a first column line connecting the first electrode of the first light emitting device and the first driver, a second column line connecting the first electrode of the second light emitting device and the first driver, and a third column line connecting the first electrode of the third light emitting device and the first driver.

The display device according to embodiments of the present disclosure can further include a fourth light emitting device arranged in the same column as the first light emitting device, a fifth light emitting device arranged in the same column as the second light emitting device, a sixth light emitting device arranged in the same column as the third light emitting device, a first row line electrically connecting a second electrode of the first light emitting device, a second electrode of the second light emitting device, and a second electrode of the third light emitting device to the first driver, and a second row line electrically connecting a second electrode of the fourth light emitting device, a second electrode of the fifth light emitting device, and a second electrode of the sixth light emitting device to the first driver.

According to aspects of the present disclosure, the first column line can be electrically connected in common with the first electrode of the first light emitting device and the first electrode of the fourth light emitting device. The second column line can be electrically connected in common with the first electrode of the second light emitting device and the first electrode of the fifth light emitting device. The third column line can be electrically connected in common with the first electrode of the third light emitting device and the first electrode of the sixth light emitting device.

During a first period, the first row line can have a first low-potential voltage, and the second row line can have a second low-potential voltage higher than the first low-potential voltage. During the first period, at least one of the first light emitting device, the second light emitting device, and the third light emitting device can emit light.

During a second period different from the first period, the first row line can have the second low-potential voltage, and the second row line can have the first low-potential voltage. During the second period, at least one of the fourth light emitting device, the fifth light emitting device, and the sixth light emitting device can emit light.

According to aspects of the present disclosure, the display area can include a plurality of drivers, and a plurality of unit driving areas corresponding to the plurality of drivers. Each of the plurality of unit driving areas can include one driver among the plurality of drivers, a plurality of light emitting devices, a plurality of row lines, and a plurality of column lines. The plurality of unit driving areas can include a first unit driving area including the first driver, the first to sixth light emitting devices, the first to third column lines, and the first and second row lines. In the first unit driving area, the first to third column lines and the first and second row lines intersect each other.

A driving period of at least one of the first row line and the second row line can include a first period in which a first voltage is applied, a second period in which a second voltage higher than the first voltage is applied, and a third period in which a signal having a variable voltage level is applied. The lowest voltage of the signal having a variable voltage level can be higher than the first voltage.

The display device according to embodiments of the present disclosure can further include a plurality of pixels arranged in the display area. The plurality of column lines can include a plurality of main column lines and a plurality of redundancy column lines.

Each of the plurality of pixels can include k main light emitting devices connected to k main column lines among the plurality of main column lines, and k redundancy light emitting devices connected to k redundancy column lines among the plurality of redundancy column lines. The k can be a natural number greater than or equal to 2.

The display device according to embodiments of the present disclosure can further include a substrate, a layer stack on the plurality of drivers arranged on the substrate, and an optical layer disposed between the plurality of light emitting devices on the layer stack. The plurality of column lines can be disposed between the layer stack and the plurality of light emitting devices. The plurality of row lines can be disposed on the plurality of light emitting devices and the optical layer.

The layer stack can include a side protection layer disposed on each side of the plurality of drivers, an upper protection layers disposed on the plurality of drivers and the side protection layer, a plurality of insulating layers disposed on the upper protection layers, and a bank disposed on the plurality of insulating layers.

The side protection layer can include at least one organic layer.

Each of the plurality of light emitting devices can be disposed on the bank, and can be positioned in an opening of the optical layer. At least a portion of each of the plurality of column lines can extend onto the bank on the plurality of insulating layers. Each of the plurality of row lines can be disposed on the optical layer and the plurality of light emitting devices.

A first electrode of each of the plurality of light emitting devices can be electrically connected to at least a portion of one column line extending onto the bank among the plurality of column lines. A second electrode of each of the plurality of light emitting devices can be electrically connected to one of the plurality of row lines.

The plurality of insulating layers can include a first insulating layer on the upper protection layer and a second insulating layer on the first insulating layer.

The layer stack can further include a plurality of line connection patterns connecting each of a plurality of lines including the plurality of row lines and the plurality of column lines to the plurality of drivers.

The plurality of line connection patterns can include a first line connection pattern disposed on the side protection layer, a second line connection pattern disposed on the upper protection layer and electrically connected to the first line connection pattern through a hole in the upper protection layer, a third line connection pattern disposed on the first insulating layer and electrically connected to the second line connection pattern through a hole in the first insulating layer, and a fourth line connection pattern disposed on the second insulating layer and electrically connected to the third line connection pattern through a hole in the second insulating layer.

The first line connection pattern can be electrically connected to one of the plurality of drivers. The fourth line connection pattern can be electrically connected to the second electrode of at least one of the plurality of light emitting devices, or can be electrically connected to the first electrode of at least one of the plurality of light emitting devices.

A display device according to embodiments of the present disclosure can include a first light emitting device emitting a first color light, a second light emitting device emitting a second color light, a third light emitting device emitting a third color light, a first column line electrically connected to a first electrode of the first light emitting device, a second column line electrically connected to a first electrode of the second light emitting device, a third column line electrically connected to a first electrode of the third light emitting device, and a first row line electrically connected in common with a second electrode of the first light emitting device, a second electrode of the second light emitting device, and a second electrode of the third light emitting device.

A first reset voltage can be applied to the first column line after the first light emitting device emits light. A second reset voltage can be applied to the second column line after the second light emitting device emits light. A third reset voltage can be applied to the third column line after the third light emitting device emits light. At least two of the first reset voltage, the second reset voltage, and the third reset voltage can be different from each other.

A first wavelength of the first color light can be longer than a second wavelength of the second color light, and the second wavelength of the second color light can be longer than a third wavelength of the third color light.

For example, the second reset voltage and the third reset voltage are equal to each other, and each of the second reset voltage and the third reset voltage can be different from the first reset voltage. Each of the second reset voltage and the third reset voltage can be higher than the first reset voltage.

As another example, the first reset voltage, the second reset voltage, and the third reset voltage can all be different from each other. The second reset voltage can be higher than the first reset voltage, and the first reset voltage can be higher than the third reset voltage.

An amount of change in luminance ratio according to a change in grayscale of the second light emitting device can be greater than an amount of change in luminance ratio according to the change in grayscale of the first light emitting device and an amount of change in luminance ratio according to the change in grayscale of the third light emitting device.

During a first period, the first row line can have a first low-potential voltage, and during a second period different from the first period, the first row line can have a second low-potential voltage higher than the first low-potential voltage. During the first period, at least one of the first light emitting device, the second light emitting device, and the third light emitting device emits light.

A driving period of the first row line can include a first period in which a first voltage is applied, a second period in which a second voltage higher than the first voltage is applied, and a third period in which a signal having a variable voltage level is applied. The lowest voltage of the signal having a variable voltage level can be higher than the first voltage.

An electronic device according to embodiments of the present disclosure can include the display device according to embodiments of the present disclosure described above.

The electronic device according to embodiments of the present disclosure can be implemented as a wearable device, a mobile device, a notebook or a monitor.

According to embodiments of the present disclosure, it is possible to provide a display device having a wiring structure arranged in a matrix form to effectively drive a plurality of light emitting devices.

According to embodiments of the present disclosure, it is possible to provide a display device capable of effectively driving a plurality of light emitting devices by using a plurality of column lines connecting first electrodes of two or more light emitting devices arranged in a column direction and a plurality of row lines connecting second electrodes of two or more light emitting devices arranged in a row direction.

According to embodiments of the present disclosure, it is possible to provide a display device that controls a reset voltage for resetting the voltage state of a first electrodes of light emitting devices emitting light of different colors to match the light emitting devices emitting light of different colors.

According to embodiments of the present disclosure, it is possible to provide a display device capable of enhancing image quality by improving a luminance ratio of light emitting devices emitting different color light in a balanced manner.

According to embodiments of the present disclosure, it is possible to provide a display device capable of reducing the number of driving components (e.g. drivers) connected to the outside of a display panel, thereby reducing the number of assembly processes in the manufacturing process and providing a structure capable of process optimization.

Although the embodiments of the present disclosure are described in more detail with reference to the attached drawings, the present disclosure is not necessarily limited to these embodiments, and various modifications can be made without departing from the technical spirit of the present disclosure. Accordingly, the embodiments disclosed in the present disclosure are not intended to limit the technical spirit of the present disclosure, but to explain, and the scope of the technical spirit of the present disclosure is not limited by these embodiments. Therefore, the embodiments described above should be understood as illustrative and not restrictive in all respects.

What is claimed is:

1. A display device comprising:
a first light emitting device arranged in a display area and configured to emit a first color light;
a second light emitting device arranged in the display area and configured to emit a second color light;
a third light emitting device arranged in the display area and configured to emit a third color light; and
a first driver configured to drive the first light emitting device, the second light emitting device, and the third light emitting device,
wherein the first driver is configured to receive two or more input reset voltages for resetting each of a first electrode of the first light emitting device, a first electrode of the second light emitting device, and a first electrode of the third light emitting device, and
wherein the two or more input reset voltages have different voltage values.

2. The display device of claim 1, wherein a first display driving period for driving the first light emitting device includes a first emission period in which the first light emitting device emits light and a first reset period in which the first electrode of the first light emitting device is reset to a first reset voltage,
wherein a second display driving period for driving the second light emitting device includes a second emission period in which the second light emitting device emits light and a second reset period in which the first electrode of the second light emitting device is reset to a second reset voltage,
wherein a third display driving period for driving the third light emitting device includes a third emission period in which the third light emitting device emits light and a third reset period in which the first electrode of the third light emitting device is reset to a third reset voltage,
wherein the first reset period follows the first emission period, the second reset period follows the second emission period, and the third reset period follows the third emission period, and
wherein among a starting time of the first reset period, a starting time of the second reset period, and a starting time of the third reset period, at least one is different from the rest.

3. The display device of claim 2, wherein among a starting time of the first emission period, a starting time of the second emission period, and a starting time of the third emission period, at least one is different from the rest, and
wherein among a length of the first emission period, a length of the second emission period, and a length of the third emission period, at least one is different from the rest.

4. The display device of claim 1, wherein a first reset voltage is applied to the first electrode of the first light emitting device after the first light emitting device emits light,
wherein a second reset voltage is applied to the first electrode of the second light emitting device after the second light emitting device emits light,
wherein a third reset voltage is applied to the first electrode of the third light emitting device after the third light emitting device emits light, and
wherein at least two of the first reset voltage, the second reset voltage, and the third reset voltage are different from each other.

5. The display device of claim 4, wherein the first driver is configured to:
receive a first input reset voltage and a second input reset voltage different from the first input reset voltage,
output the first reset voltage corresponding to the first input reset voltage, and
output the second reset voltage and the third reset voltage each corresponding to the second input reset voltage.

6. The display device of claim 5, wherein the second input reset voltage is higher than the first input reset voltage.

7. The display device of claim 6, wherein a first wavelength of the first color light is longer than a second wavelength of the second color light and a third wavelength of the third color light.

8. The display device of claim 4, wherein the first driver is configured to:
receive a first input reset voltage, a second input reset voltage, and a third input reset voltage different from each other,
output the first reset voltage corresponding to the first input reset voltage,
output the second reset voltage corresponding to the second input reset voltage, and
output the third reset voltage corresponding to the third input reset voltage.

9. The display device of claim 8, wherein the second input reset voltage is higher than the first input reset voltage, and the first input reset voltage is higher than the third input reset voltage.

10. The display device of claim 8, wherein a first wavelength of the first color light is longer than a second wavelength of the second color light, and the second wavelength of the second color light is longer than a third wavelength of the third color light.

11. The display device of claim 1, wherein an amount of change in a luminance ratio according to a change in grayscale of the second light emitting device is greater than an amount of change in a luminance ratio according to the change in grayscale of the first light emitting device and an amount of change in a luminance ratio according to the change in grayscale of the third light emitting device.

12. The display device of claim 1, wherein the first driver includes:
a first column driver configured to drive the first electrode of the first light emitting device;
a second column driver configured to drive the first electrode of the second light emitting device; and
a third column driver configured to drive the first electrode of the third light emitting device,
wherein the first driver is disposed in the display area.

13. The display device of claim 12, wherein each of the first column driver, the second column driver and the third column driver includes:
a first node, a second node, a third node, and a fourth node;
a driving transistor controlled by a voltage of the first node and connected between the second node and the third node; and
a first emission control transistor configured to be turned on or off by a first emission control signal and connected between the third node and the fourth node,
wherein a fourth node of the first column driver is electrically connected to the first electrode of the first light emitting device,
wherein a fourth node of the second column driver is electrically connected to the first electrode of the second light emitting device, and
wherein a fourth node of the third column driver is electrically connected to the first electrode of the third light emitting device.

14. The display device of claim 1, further comprising:
a first column line connecting the first electrode of the first light emitting device and the first driver;
a second column line connecting the first electrode of the second light emitting device and the first driver; and
a third column line connecting the first electrode of the third light emitting device and the first driver.

15. The display device of claim 14, further comprising:
a fourth light emitting device arranged in a same column as the first light emitting device;
a fifth light emitting device arranged in a same column as the second light emitting device;
a sixth light emitting device arranged in a same column as the third light emitting device;
a first row line electrically connecting a second electrode of the first light emitting device, a second electrode of the second light emitting device, and a second electrode of the third light emitting device to the first driver; and
a second row line electrically connecting a second electrode of the fourth light emitting device, a second electrode of the fifth light emitting device, and a second electrode of the sixth light emitting device to the first driver,
wherein the first column line is electrically connected in common with the first electrode of the first light emitting device and the first electrode of the fourth light emitting device,
wherein the second column line is electrically connected in common with the first electrode of the second light emitting device and the first electrode of the fifth light emitting device, and
wherein the third column line is electrically connected in common with the first electrode of the third light emitting device and the first electrode of the sixth light emitting device.

16. The display device of claim 15, wherein, during a first period, the first row line has a first low-potential voltage, and the second row line has a second low-potential voltage higher than the first low-potential voltage,
wherein, during a second period different from the first period, the first row line has the second low-potential voltage, and the second row line has the first low-potential voltage,
wherein, during the first period, at least one of the first light emitting device, the second light emitting device, and the third light emitting device emits light, and
wherein, during the second period, at least one of the fourth light emitting device, the fifth light emitting device, and the sixth light emitting device emits light.

17. The display device of claim 15, wherein the display area includes a plurality of drivers, and a plurality of unit driving areas corresponding to the plurality of drivers,
wherein each of the plurality of unit driving areas includes one driver among the plurality of drivers, a plurality of light emitting devices, a plurality of row lines, and a plurality of column lines,
wherein the plurality of unit driving areas include a first unit driving area including the first driver, the first to sixth light emitting devices, the first to third column lines, and the first and second row lines, and
wherein the first to third column lines and the first and second row lines intersect each other.

18. The display device of claim 17, wherein a driving period of at least one of the first row line and the second row line includes,
a first period in which a first voltage is applied,
a second period in which a second voltage higher than the first voltage is applied, and
a third period in which a signal having a variable voltage level is applied.

19. The display device of claim 18, wherein a lowest voltage of the signal having the variable voltage level is higher than the first voltage.

20. The display device of claim 17, further comprising a plurality of pixels arranged in the display area,
wherein the plurality of column lines include a plurality of main column lines and a plurality of redundancy column lines,
wherein each of the plurality of pixels includes k main light emitting devices connected to k main column lines among the plurality of main column lines, and k redundancy light emitting devices connected to k redundancy column lines among the plurality of redundancy column lines, and
wherein k is a natural number greater than or equal to 2.

21. The display device of claim 17, further comprising:
a layer stack on the plurality of drivers arranged on a substrate; and
an optical layer disposed between the plurality of light emitting devices on the layer stack,
wherein the plurality of column lines are disposed between the layer stack and the plurality of light emitting devices, and
wherein the plurality of row lines are disposed on the plurality of light emitting devices and the optical layer.

22. The display device of claim 21, wherein the layer stack includes:
a side protection layer disposed on each side of the plurality of drivers;
an upper protection layers disposed on the plurality of drivers and the side protection layer;
a plurality of insulating layers disposed on the upper protection layers; and
a bank disposed on the plurality of insulating layers,
wherein each of the plurality of light emitting devices is disposed on the bank and positioned in an opening of the optical layer,
wherein at least a portion of each of the plurality of column lines extends onto the bank on the plurality of insulating layers,
wherein each of the plurality of row lines is disposed on the optical layer and the plurality of light emitting devices,
wherein a first electrode of each of the plurality of light emitting devices is electrically connected to at least a portion of one column line extending onto the bank among the plurality of column lines, and
wherein a second electrode of each of the plurality of light emitting devices is electrically connected to one of the plurality of row lines.

23. The display device of claim 22, wherein the plurality of insulating layers include a first insulating layer on the upper protection layer and a second insulating layer on the first insulating layer,
wherein the layer stack further includes a plurality of line connection patterns connecting a plurality of lines including the plurality of row lines and the plurality of column lines to the plurality of drivers,
wherein the plurality of line connection patterns include:
a first line connection pattern disposed on the side protection layer;
a second line connection pattern disposed on the upper protection layer and electrically connected to the first line connection pattern through a hole in the upper protection layer;
a third line connection pattern disposed on the first insulating layer and electrically connected to the second line connection pattern through a hole in the first insulating layer; and
a fourth line connection pattern disposed on the second insulating layer and electrically connected to the third line connection pattern through a hole in the second insulating layer,
wherein the first line connection pattern is electrically connected to one of the plurality of drivers, and
wherein the fourth line connection pattern is electrically connected to the second electrode of at least one of the plurality of light emitting devices, or is electrically connected to the first electrode of at least one of the plurality of light emitting devices.

24. The display device of claim 22, wherein the side protection layer includes at least one organic layer.

25. A display device comprising:
a first light emitting device configured to emit a first color light;
a second light emitting device configured to emit a second color light;
a third light emitting device configured to emit a third color light;
a first column line electrically connected to a first electrode of the first light emitting device;
a second column line electrically connected to a first electrode of the second light emitting device;
a third column line electrically connected to a first electrode of the third light emitting device; and
a first row line electrically connected in common with a second electrode of the first light emitting device, a second electrode of the second light emitting device, and a second electrode of the third light emitting device,
wherein a first reset voltage is applied to the first column line after the first light emitting device emits light, a second reset voltage is applied to the second column line after the second light emitting device emits light, and a third reset voltage is applied to the third column line after the third light emitting device emits light, and
wherein at least two of the first reset voltage, the second reset voltage, and the third reset voltage are different from each other.

26. The display device of claim 25, wherein a first wavelength of the first color light is longer than a second wavelength of the second color light, and the second wavelength of the second color light is longer than a third wavelength of the third color light.

27. The display device of claim 26, wherein the second reset voltage and the third reset voltage are equal to each other, and
wherein each of the second reset voltage and the third reset voltage is different from the first reset voltage.

28. The display device of claim 27, wherein each of the second reset voltage and the third reset voltage is higher than the first reset voltage.

29. The display device of claim 26, wherein the first reset voltage, the second reset voltage, and the third reset voltage are all different from each other.

30. The display device of claim 29, wherein the second reset voltage is higher than the first reset voltage, and
wherein the first reset voltage is higher than the third reset voltage.
